(19) United States
(12) Patent Application Publication
(10) Pub. No.: US 2015/0253662 A1
(43) Pub. Date: Sep. 10, 2015

(54) ACTINIC RAY-SENSITIVE OR RADIATION-SENSITIVE RESIN COMPOSITION, METHOD FOR FORMING PATTERN, RESIST FILM, METHOD FOR MANUFACTURING ELECTRONIC DEVICE, AND ELECTRONIC DEVICE

(71) Applicant: FUJIFILM Corporation, Tokyo (JP)

(72) Inventors: Keita KATO, Haibara-gun (JP); Michihiro SHIRAKAWA, Haibara-gun (JP); Hidenori TAKAHASHI, Haibara-gun (JP); Shoichi SAITOH, Haibara-gun (JP); Fumihiro YOSHINO, Haibara-gun (JP)

(73) Assignee: FUJIFILM CORPORATION, Tokyo (JP)

(21) Appl. No.: 14/721,249

(22) Filed: May 26, 2015

Related U.S. Application Data
(63) Continuation of application No. PCT/JP2013/080926, filed on Nov. 15, 2013.

(30) Foreign Application Priority Data
Nov. 26, 2012 (JP) 2012-257846

(51) Int. Cl. G03F 7/038; C08F 212/08; C08F 216/10; C08F 216/16; C08F 220/18; C08F 220/28

(52) U.S. Cl. CPC G03F 7/038; C08F 220/18; C08F 220/28; C08F 216/10; C08F 216/165; C08F 212/08; C08F 2220/1825; C08F 2220/285; C08F 2220/283

(57) ABSTRACT

According to an exemplary embodiment of the present invention, there is provided an actinic ray-sensitive or radiation-sensitive resin composition includes an aromatic group and a resin (A) that may include (i) a repeating unit having a group capable of decomposing by the action of an acid to generate a polar group and (ii) a repeating unit having a polar group other than a phenolic hydroxyl group, wherein the total content of the repeating units (i) and (ii) is 51 mol % or more based on the entire repeating units in the resin (A).

### CROSS REFERENCE TO RELATED APPLICATION

This is a continuation of International Application No. PCT/JP2013/080926 filed on Nov. 15, 2013, and claims priority from Japanese Patent Application No. 2012-257846 filed on Nov. 26, 2012, the entire disclosures of which are incorporated herein by reference.

### BACKGROUND

1. Technical Field

The present invention relates to an actinic ray-sensitive or radiation-sensitive resin composition suitably used in the manufacture of a semiconductor device, such as an IC, in the manufacture of a circuit board for a liquid crystal display, a thermal head and the like, and further in other lithography processes of photo-fabrication, a pattern forming method, a resist film, a method for manufacturing an electronic device, and an electronic device. In particular, the present invention relates to an actinic ray-sensitive or radiation-sensitive resin suitable for use in a lithography process using irradiation by a KrF excimer laser, a pattern forming method, a resist film, a method for manufacturing an electronic device, and an electronic device.

2. Background Art

Since the advent of a resist for a KrF excimer laser (248 nm), an image forming method called chemical amplification has been used as an image forming method for the resist to compensate for a decrease of sensitivity caused due to light absorption. For example, in a chemical amplification-type positive image forming method, exposure to excimer laser light, electron beam, EUV light, etc. results in the diffusion of an acid generator in an exposed area to generate an acid, and the generated acid is used as a catalyst in a post exposure bake (PEB) process to convert an alkali-insoluble group into an alkali-soluble group, thereby removing the exposed area in an alkali developer.

Although different types of alkali developer have been proposed for use in the above method, an aqueous alkali developer of 2.38 wt. % TMAH (tetramethylammonium hydroxide aqueous solution) is used for general purposes.

For example, Japanese Patent Application Laid-Open No. 2000-147772 discloses a positive resist composition using a resin having a p-hydroxystyrene-based repeating unit.

As well as by the positive image forming that is currently leading technology, fine pattern forming by negative imaging is being developed (see Japanese Patent Application Laid-Open Nos. 2010-40849, 2008-292975 and 2010-217884). This is to meet the need for formation of different pattern shapes, such as lines, trenches (recesses) and holes in the manufacture of semiconductor devices and the like. In addition, some patterns, such as a trench and a hole, are hardly formed on an existing positive resist.

In such a negative pattern forming method relying on organic solvent-based development, however, there is also room for improvement of roughness performance, such as line width roughness (LWR), exposure latitude (EL), and development defect reduction.

In semiconductor device manufacturing, it is also being discussed to replace part of a conventional ArF lithography process with KrF lithography in terms of the effective use of existing equipment as well as in terms of the need for ultramicrofabrication. Such replacement, however, runs counter to the historical progress of the development of ArF lithography technologies in overcoming the limit of KrF lithography, and further may involve different technical difficulties arisen from the need for improvement of materials used (resin or the like) and the difference in exposure mechanism, as well as the above-mentioned need for microfabrication.

In addition, as an application of the above resist technology, a use for microfabrication, such as ion implantation that uses a resist composition at an ion implanting (charge injection) step in logic device fabrication, is in progress.

Where a resist composition is used for ion implantation, it may be coated on a patterned substrate (hereinafter, a “stepped substrate”), exposed and developed. Thus, there is also a need for micro-machining on the stepped substrate.

However, as a result of standing waves generated by the reflection of expose light from a substrate or the diffused reflection of exposure light from a stepped portion of the stepped substrate, there has been a room for improvement, such as the collapse of negative patterns formed in an organic solvent-based developing process.

Further, the method for forming negative patterns by an organic solvent-based development requires a high dissolution contrast, unlike in the method for forming positive patterns by an alkali developer. This problem has been specific to the negative pattern forming method relying organic solvent-based development.

In consideration of the above-mentioned problems, an object of the present invention is to provide an actinic ray-sensitive or radiation-sensitive resin composition that is excellent in exposure latitude (EL), line width roughness (LWR) and space pattern collapse performance on a stepped substrate and is particularly suitable for use in those methods for forming negative patterns by organic solvent-based development, and among others in KrF lithography, a pattern forming method using the resin composition, a resist film, a method for fabrication of an electronic device, and an electronic device.

### SUMMARY

[1] An actinic ray-sensitive or radiation-sensitive resin composition comprising a resin (A) that has an aromatic group, (i) a repeating unit having a group capable of decomposing by an action of an acid to generate a polar group, and optionally (ii) a repeating unit having a polar group other than a phenolic hydroxyl group, wherein the total content of the repeating units (i) and (ii) is 51 mol % or more based on the entire repeating units in the resin (A).

[2] The composition described in [1], wherein the repeating unit (i) having a group capable of decomposing by an action of an acid to generate a polar group is a repeating unit having a group capable of generating a polar group other than a phenolic hydroxyl group.

[3] The composition described in [1] or [2], wherein the repeating unit (i) having a group capable of decomposing by an action of an acid to generate a polar group is a repeating unit represented by the following Formula (I) or a repeating unit represented by the following Formula (II):

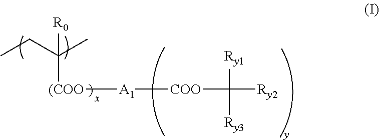

In Formula (I),

R₀ represents a hydrogen atom or an alkyl group.

Each of R_{y1} to R_{y3} independently represents an alkyl group or a cycloalkyl group and R_{y2} and R_{y3} may be combined to each other to form a monocyclic or polycyclic structure.

A₁ represents a single bond or a (y+1)-valent organic group,

x represents 0 or 1, y represents an integer of 1 to 3.

When y is 2 or 3, R_{y1}'s, R_{y2}'s and R_{y3}'s may be same as or different; and

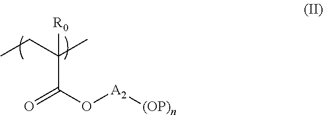

In Formula (II),

R₀ represents a hydrogen atom or an alkyl group.

A₂ represents an (n+1)-valent organic group.

OP represents a group capable of decomposing by the action of an acid to generate an alcoholic hydroxyl group, and when two or more OP's are present, OP's may be same as or different from each other and may be bonded to each other to form a ring.

n represents an integer of 1 to 3.

[4] The composition described in any of [1] to [3], further comprising a compound (B) that generates an acid upon irradiation with an actinic-ray or radiation, wherein the compound (B) is an ionic compound.

[5] The compound described in any of [1] to [4], for use in organic solvent-based development.

[6] The compound described in any of [1] to [5], for use in exposure by a KrF excimer laser.

[7] A resist film formed by the actinic ray-sensitive or radiation-sensitive resin composition described in any of [1] to [6].

[8] A pattern forming method comprising:

(a) a step of forming a film using the actinic ray-sensitive or radiation-sensitive resin composition described in any of [1] to [6];

(b) a step of exposing the film; and

(c) a step of developing the exposed film in an organic solvent-containing developer to form negative patterns.

[9] The method described in [8], wherein the repeating unit (i) having a group capable of decomposing by an action of an acid to generate a polar group is a repeating unit having a group capable of generating a polar group other than a phenolic hydroxyl group.

[10] The method described in [8] or [9], wherein the exposure at the step (b) is performed by a KrF excimer laser.

[11] The method described in any of [8] to [10], wherein the organic-solvent containing developer is a developer containing at least one kind of solvent selected from a ketone-based solvent, an ester-based solvent, an alcohol-based solvent, an amide-based solvent and an ether-based solvent.

[12] A method for manufacturing an electronic device, comprising the method described in any of [8] to [11].

[13] An electronic device manufactured by the method described in [12].

Also, the present invention may preferably be provided in the following aspects:

[14] An actinic ray-sensitive or radiation-sensitive resin composition described in any of [1] to [6], wherein in the repeating unit (ii) having a polar group other than a phenolic hydroxyl group, the polar group is a carboxylic acid group, an alcoholic hydroxyl group, an ester group, an amide group, an imide group, a sulfo group, a cyano group, a carbonyl group, a nitro group, a sulfonamide group, or an ether group (but the ester group and the carbonyl group as the polar group do not include an ester group directly bonded to a main chain of the resin (A) and a carbonyl group in the ester group).

[15] An actinic ray-sensitive or radiation-sensitive resin composition described in any of [1] to [6] and [14], further comprising a compound (D) having a naphthalene ring, a biphenyl ring or an anthracene ring.

[16] A pattern forming method as described in any of [8] to [11], wherein a film formed using the actinic ray-sensitive or radiation-sensitive resin composition is formed on a substrate on which an antireflection coating is not applied.

[17] A pattern forming method as described in [16], wherein the substrate on which the antireflection coating is not applied is a stepped substrate.

According to the present invention, it is possible to provide an actinic ray-sensitive or radiation-sensitive resin composition that is excellent in exposure latitude (EL), line width roughness (LWR) and space pattern collapse performance on a stepped substrate and particularly suitable for a negative pattern forming method relying on organic solvent development, more particularly for KrF lithography in that method, a pattern forming method using the resin composition, a resist film, a method for fabrication of an electronic device, and an electronic device.

### DETAILED DESCRIPTION OF EXEMPLARY EMBODIMENTS

Hereinafter, embodiments of the present invention will be described in detail.

In the notation of a group (atomic group) in the present specification, the representation which does not describe the substitution and unsubstitution includes a representation having a substituent along with a representation having no substituent. For example, “an alkyl group” includes not only an alkyl group having no substituent (an unsubstituted alkyl group) but also an alkyl group having a substituent (a substituted alkyl group).

The term “actinic ray” or “radiation” in the present specification refers to, for example, a bright line spectrum of a mercury lamp and the like, far-ultraviolet rays represented by an excimer laser, extreme ultraviolet rays (EUV light), X-rays, an electron beam (EB) and the like. Further, the term “light” in the present invention refers to an actinic ray or radiation.

In addition, unless otherwise specifically indicated, the term “exposure” in the present specification includes not only the exposure performed using a mercury lamp, far-ultraviolet rays represented by an excimer laser, extreme-ultraviolet rays, X-rays, EUV light and the like, but also drawing performed by a particle beam such as an electron beam, an ion beam and the like.

The actinic ray-sensitive or radiation-sensitive resin composition according to the present invention includes an aromatic group and a resin (A), wherein the resin (A) may include (i) a repeating unit having a group capable of decomposing by the action of an acid to generate a polar group and (ii) a repeating unit having a polar group other than a phenolic hydroxyl group, and the sum of the repeating units (i) and (ii) is 51 mol % or more based on the entire repeating units in the resin (A).

Although it is uncertain, the actinic ray-sensitive or radiation-sensitive resin composition according to the present invention is presumably excellent in exposure latitude (EL) and line width roughness (LWR) and in terms of space collapse performance on a stepped substrate particularly when forming a negative pattern using an organic solvent-containing developer for KrF lithography, for the following reason.

Although it is uncertain, a repeating unit having a phenolic hydroxyl group, which has been commonly used for alkali development in KrF lithography, exhibits a high solubility in an organic-based developer and may deteriorate a dissolution contrast between an exposed area and an unexposed area on a resist film.

Therefore, the actinic ray-sensitive or radiation-sensitive resin composition according to the present invention does not use a repeating unit having a phenolic hydroxyl group having such defects, and rather includes (i) a repeating unit having a group decomposing by the action of an acid to generate a polar group and (ii) a repeating unit having a polar group other than a phenolic hydroxyl group such that the sum of the repeating units is 51 mol % or more to fully reduce the solubility of the exposed area in an organic-based developer, and also includes an aromatic group to fully maintain the solubility of the unexposed area, thereby improving the dissolution contrast between the exposed area and the unexposed area on the resist film. Thus, the resin composition is presumed to be excellent in EL, LWR and space collapse performance on a stepped substrate.

The resist film according to the present invention is a film formed by the above actinic ray-sensitive or radiation-sensitive resin composition, for example, formed by coating an actinic ray-sensitive or radiation-sensitive resin composition on a substrate.

Hereinafter, an actinic ray-sensitive or radiation-sensitive resin composition that may be used in the present invention will be described.

Further, the present invention also relates to an actinic ray-sensitive or radiation-sensitive resin composition, which will be described below.

The actinic ray-sensitive or radiation-sensitive resin composition according to the present invention may be used in negative development (a process in which, when exposed, the solubility of an exposed area in a developer is reduced to keep the exposed area remain while removing the unexposed area). In other words, the actinic ray-sensitive or radiation-sensitive resin composition according to the present invention may be an actinic ray-sensitive or radiation-sensitive resin composition used for organic solvent-based development using an organic solvent-containing developer or may be an actinic ray-sensitive or radiation-sensitive resin composition used for alkali development using an alkali developer. Herein, the phrase “for organic solvent-based development” is used to mean a use provided at least in development using an organic solvent-containing developer, and the phrase “for alkali development” is used to mean a use provided at least in a development using an alkali developer.

The actinic ray-sensitive or radiation-sensitive resin composition according to the present invention is a typical resist composition and a negative resist composition (i.e., a resist composition for organic solvent development) and is preferable particularly in terms of achieving a great effect. Also, the composition according to the present invention is a typical chemical amplification resist composition.

[1] A resin (A) that has an aromatic group, (i) a repeating group having a group decomposing by the action of an acid to generate a polar group (hereinafter, also called a “an acid-decomposable group”), and optionally (ii) a repeating unit having a polar group other than a phenolic hydroxyl group [hereinafter, simply referred to as the resin (A)]

In the present invention, the sum of the repeating units (i) and (ii) is 51 mol % or more based on the entire repeating units in the resin (A) and preferably 55 mol % or more, more preferably 60 mol % or more and still more preferably 65 mol % in terms of EL, LWR and space collapse performance on a stepped substrate.

Although not being particularly limited, the total content of the repeating units in (i) and (ii) may be preferably 97 mol % or less, more preferably 95 mol % or less and still more preferably 90 mol % or less in terms of the balance with another repeating unit.

The resin (A) used in the actinic ray-sensitive or radiation-sensitive resin composition according to the present invention is a resin having an acid-decomposable group (hereinafter, an acid-decomposable resin) and exhibits a varying solubility in a developer by the action of an acid.

The resin (A) used in the actinic ray-sensitive or radiation-sensitive resin composition according to the present invention includes a resin having an acid-decomposable group in the main chain or side chain of the resin or on both of the main chain and the side chain.

[(i) Repeating Unit Having Acid-Decomposable Group]

An acid-decomposable group may preferably have a structure that protects a polar group by a group capable of decomposing and leaving by an action of an acid.

The polar group, although not specifically limited as long as it is sparingly soluble or insoluble in an organic solvent-containing developer, may include an acid group such as a carboxylic group and a sulfonic acid group (a group dissociated in a 2.38 wt. % TMAH aqueous solution used as a conventional resist developer) or an alcoholic hydroxyl group.

Also, the alcoholic hydroxyl group is a hydroxyl group bonded to a hydrocarbon group, that is, a hydroxyl group other than that directly bonded on an aromatic ring (a phenolic hydroxyl group), and excludes an aliphatic alcohol whose α-position is substituted by an electron-withdrawing group such as a fluorine atom (e.g., a fluorinated alcohol group [hexafluoroisopropanol group and the like]), as an acid group. The alcoholic hydroxyl group may preferably be a hydroxyl group with a pKa of 12 or more or 20 or less.

In the present invention, a repeating unit having an acid-decomposable group may preferably be a repeating unit having a group capable of generating a polar group other than a phenolic hydroxyl group.

A group that may preferably be used as an acid-decomposable group is a group in which a hydrogen atom of the above groups is substituted by a group capable of decomposing and leaving by the action of an acid.

Examples of the group capable of leaving by the action of an acid include —C(R₃₆)(R₃₇7)(R₃₈), —C(R₃₆)(R₃₇)(R₃₈), —C(R₀₁)(R₀₂)(OR₃₉), or the like.

In the above formulae, each of R₃₆ to R₃₉ independently represents an alkyl group, a cycloalkyl group, an aryl group, an aralkyl group or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having 1 to 8 carbon atoms, and examples thereof may include a methyl group, an ethyl group, a propyl group, an n-butyl group, a sec-butyl group, a hexyl group, and an octyl group.

The cycloalkyl group of R₃₆ to R₃₉, R₀₁ and R₀₂ may be a monocyclic or polycyclic cycloalkyl group. The monocyclic cycloalkyl group is preferably a cycloalkyl group having 3 to 8 carbon atoms, and examples thereof may include a cyclopropyl group, a cyclobutyl group, a cyclopentyl group, a cyclohexyl group and a cyclooctyl group. The polycyclic cycloalkyl group is preferably a cycloalkyl group having 6 to 20 carbon atoms, and examples thereof may include an adamantyl group, a norbornyl group, an isoboronyl group, a camphanyl group, a dicyclopentyl group, an α-pinel group, a tricyclodecanyl group, a tetracyclododecyl group, and an androstanyl group. Incidentally, at least one of the carbon atoms in the cycloalkyl group may be substituted by a heteroatom such as an oxygen atom.

The aryl group of R₃₆ to R₃₉, R₀₁ and R₀₂ is preferably an aryl group having 6 to 10 carbon atoms, and examples thereof may include a phenyl group, a naphthyl group, and an anthryl group.

The aralkyl of R₃₆ to R₃₉, R₀₁ and R₀₂ is preferably an aralkyl group having 7 to 12 carbon atoms, and examples thereof may include a benzyl group, a phenethyl group, and a naphthylmethyl group.

The alkenyl group of R₃₆ to R₃₉, R₀₁ and R₀₂ is preferably an alkenyl group having 2 to 8 carbon atoms, and examples thereof may include a vinyl group, an allyl group, a butenyl group, and a cyclohexenyl group.

The ring which is formed by R₃₆ and R₃₇ bonded to each other may preferably be a cycloalkyl group (monocyclic or polycyclic). The cycloalkyl group may preferably be a monocyclic cycloalkyl group, such as a cyclopentyl group and a cyclohexyl group, and a polycyclic cycloalkyl group, such as a norbornyl group, a tetracyclodecayl group, a tetracyclododecanyl group and an adamantly group. More preferably, the cycloalkyl group is a monocyclic cycloalkyl group having 5 to 6 carbon atoms, and still more preferably a monocyclic cycloalkyl group having 5 carbon atoms.

The repeating unit (i) having an acid-decomposable group is preferably a repeating unit represented by Formula (I) or (II) below. This repeating unit may further improve roughness performance, such as line width roughness, and exposure latitude.

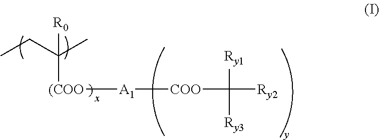

In Formula (I), R₀ represents a hydrogen atom or an alkyl group, each of R_{y1} to R_{y3} independently represents an alkyl group or a cycloalkyl group, and R_{y2} and R_{y3} may be bonded to each other to form a monocyclic or polycyclic structure.

A₁ represents a single bond or a (y+1)-valent organic group.

x is 0 or 1, and y represents an integer of 1 to 3.

When y is 2 or 3, R_{y1}'s, R_{y2}'s and R_{y3}'s each may be same or different.

The alkyl group of R₀ may have a substituent, and examples of the substituent may include a halogen atom (preferably a fluorine atom) and an alkoxy group.

The alkyl group of R₀ may preferably have 1 to 4 carbon atoms and may include a methyl group, an ethyl group, a propyl group or trifluoromethly group, and may preferably be a methyl group.

R₀ may preferably be a hydrogen atom or a methyl group.

The alkyl group of R_{y1} to R_{y3} may be chained or branched and may preferably be an alkyl group having 1 to 4 carbon atoms, such as a methyl group, an ethyl group, an n-propyl group, an isopropyl group, an n-butyl group, an isobutyl group and a t-butyl group.

The cycloalkyl group of R_{y1} to R_{y3} may preferably be a monocyclic cycloalkyl group, such as a cyclopentyl group and a cyclohexyl group, and a polycyclic cycloalkyl group, such as a norbornyl group, a tetracyclodecanyl group, a tetracyclododecanyl group and an adamantly group.

A monocyclic or polycyclic structure formed by R_{y2} and R_{y3} bonded to each other may preferably be a monocyclic hydrocarbon ring, such as a cyclopentane ring and cyclohexane ring, and a polycyclic hydrocarbon ring, such as a norbornane ring, a tetracyclodecane ring, a tetracyclododecane ring and an adamantyl ring, and more preferably a monocyclic hydrocarbon ring having 5 to 6 carbon atoms.

Preferably, each of R_{y1} to R_{y3} independently represents an alkyl group and more preferably a chained or branched alkyl group having 1 to 4 carbon atoms. The sum of the carbon numbers of the chained or branched alkyl group as R_{y1} to R_{y3} is preferably equal to 5 or less.

In a preferred mode, R_{y1} is a methyl group or an ethyl group, and there is also a mode wherein R_{y2} and R_{y3} are bonded to each other to form the above-described monocyclic or polycyclic structure.

R_{y1} to R_{y3} may further have a substituent, and examples of the substituent may include a hydroxyl group, an alkyl group (having 1 to 4 carbon atoms), a cycloalkyl group (having 3 to 8 carbon atoms), a halogen atom, an alkoxy group (having 1 to 4 carbon atoms), a carboxyl group and an alkoxycarbonyl group (having 2 to 6 carbon atoms). Preferably, the carbon number may be 8 or less. Among others, in terms of further improving the dissolution contrast between before and after acid decomposition in an organic solvent-containing developer, it is more preferable that the substituent does not have a heteroatom, such as an oxygen atom, a nitrogen atom and a sulfur atom (e.g., other than an alkyl group substituted by a hydroxyl group), still more preferably, the substituent may be a group consisting only of an hydrogen atom and a carbon atom, and particularly preferably a chained or branched alkyl group and a cycloalkyl group.

The (y+1)-valent organic group represented by A₁ may include a monocyclic or polycyclic hydrocarbon structure that may have a heteroatom as a ring member, an alkylene group (preferably having 1 to 6 carbon atoms), —CO—, —O—, —SO₂— or a combination of two or more of them, and is preferably a (y+1)-valent group having the total carbon number of 25 or less.

Examples of a monocyclic hydrocarbon structure that may have a heteroatom as a ring member constituting the organic group represented by A₁ may preferably include a cycloalkylene group having 3 to 10 carbon atoms and examples thereof may include a cyclopentyl group, a cyclobutylene group, a cyclopentylene group, a cyclohexylene group, and a cycloheptylene group.

Examples of a polycyclic hydrocarbon structure may include a ring-aggregated hydrocarbon ring group and a crosslinked cyclic hydrocarbon ring group.

Examples of the ring-aggregated hydrocarbon ring group include a bicyclohexane ring group and a perhydronaphthalene ring group. Examples of the cross-linked cyclic hydrocarbon ring group include a bicyclic hydrocarbon ring group such as a pinane ring group, a bornane ring group, a norpinane ring group, a norbornane ring group, and a bicyclooctane ring group (a bicyclo[2.2.2]octane ring group, a bicyclo[3.2.1]octane ring group and the like), a tricyclic hydrocarbon ring group such as a homobrendane ring group, an adamantane ring group, a tricyclo[5.2.1.0^{2,6}]decane ring group and a tricyclo[4.3.1.1^{2,5}]undecane ring group, a tetracyclic hydrocarbon ring group such as a tetracyclo[4.4.0.1^{2,5}0.1^{7,10}]dodecane ring group and a perhydro-1,4-methano-5,8-methanonaphthalene ring group, and the like. Furthermore, the cross-linked cyclic hydrocarbon ring group also includes a condensed cyclic hydrocarbon ring group, for example, a condensed ring group in which a plurality of 5 to 8-membered cycloalkane rings, such as a perhydronaphthalene (decalin) ring group, a perhydroanthracene ring group, a perhydrophenanthrene ring group, a perhydroacenaphthene ring group, a perhydrofluorene ring group, a perhydroindene ring group, and a perhydrophenalene ring group, are condensed.

Preferred examples of the crosslinked cyclic hydrocarbon ring group may include a norbornane ring group, an adamantane ring group, a bicyclooctane ring group, and a tricyclo[5.2.1.0^{2,6}]decane ring group. More preferred examples of the cross-linked cyclic hydrocarbon ring group may include a norbornane ring group and an adamantane ring group.

A monocyclic or polycyclic hydrocarbon structure that may have a heteroatom as a ring member may have a substituent. Examples of the substituent which may be possessed include an alkyl group, a hydroxyl group, a cyano group, a keto group (═O), an acyloxy group, —COR, —COOR, —CON(R)₂, —SO₂R, —SO₃R, and —SO₂N(R)₂ and the like, wherein R represents a hydrogen atom, an alkyl group, a cycloalkyl group or an aryl group.

The alkyl group, the aklylcarbonyl group, the asyloxyl group, —COR, —COOR, —CON(R)₂, SO₃R and SON₂N(R)₂ as the substituent which may be possessed may have a further substituent. Example of the further substituent may include a halogen atom (preferably a fluorine atom).

The carbon constituting the cyclic hydrocarbon structure (a carbon contributing to the formation of the ring) may be carbonyl carbon. Also, the cyclic hydrocarbon structure may have a heteroatom as a ring member, such as an oxygen atom and a sulfur atom, as described above.

The monocyclic or polycyclic hydrocarbon structure that may have a heteroatom as a ring member constituting the (y+1)-valent organic group represented by A1 may preferably be a polycyclic hydrocarbon structure that may have a heteroatom.

Examples of an alkylene group constituting the (y+1)-valent organic group represented by A1 (preferably having 1 to 6 carbon atoms) may include a methylene group, an ethylene group, a propylene group, a butylene group and the like.

Preferably, the (y+1)-valent organic group represented by A1 may preferably be a (y+1)-valent group in which two or more of a polycyclic hydrocarbon structure, an alkylene group, —CO— and —O— are combined or a (y+1)-valent group having a polycyclic cyclic hydrocarbon structure that may have a heteroatom as a ring member, and more preferably a (y+1)-valent group in which two or more of a polycyclic hydrocarbon structure, an alkylene group and —O— are combined, or a (y+1)-valent group having a polycyclic hydrocarbon structure that may have a heteroatom as a ring member.

A₁ is preferably a single bond or a (y+1)-valent group having a polycyclic hydrocarbon structure that may have a heteroatom as a ring member, and more preferably a single bond. Also, x preferably represents 0.

y preferably represents 1 or 2 and more preferably 1.

In a particularly preferred embodiment of the repeating unit represented by Formula (I), x represents 0, A₁ represents a single bond, and each of R_{y1} to R_{y3} independently represents a straight or branch alkyl group.

In this embodiment, examples of the straight or branch alkyl group represented by R_{y1} to R_{y3} may preferably include an alkyl group having 1 to 4 carbon atoms, and examples thereof may include a methyl group, an ethyl group, an n-propyl group, an isopropyl group, an n-butyl group, an isobutyl group and a tert-butyl group.

Examples of R_{y1} may preferably include a methyl group, an ethyl group, an n-propyl group, and an n-butyl group, more preferably a methyl group and an ethyl group, and still more preferably a methyl group.

Examples of R_{y2} may preferably include a methyl group, an ethyl group, an n-propyl group, an isopropyl group, and an n-butyl group, and more preferably a methyl group and an ethyl group and still more preferably a methyl group.

Examples of R_{y3} may preferably include a methyl group, an ethyl group, an n-propyl group, an isopropyl group, an n-butyl group, an isobutyl group and a tert-butyl group, more preferably a methyl group, an ethyl group, an isopropyl group and an isobutyl group, and still more preferably a methyl group, an ethyl group and an isopropyl group.

Specific examples of the repeating unit represented by Formula (I) in the present invention are provided below, but the present invention is not limited thereto.

In the following specific examples, Rx represents a hydrogen atom, CH₃ or CF₃. Each of Rxa and Rxb represents an alkyl group having 1 to 4 carbon atoms. Z represents a substituent, and when two or more are present, Z's may be same or different. p represents 0 or a positive integer. Specific examples and preferred examples of Z are the same as those listed for the substituent which may be possessed by each of R_{y1} to R_{y3} and the like.

In the specific examples, Xa represents a hydrogen atom or an alkyl group.

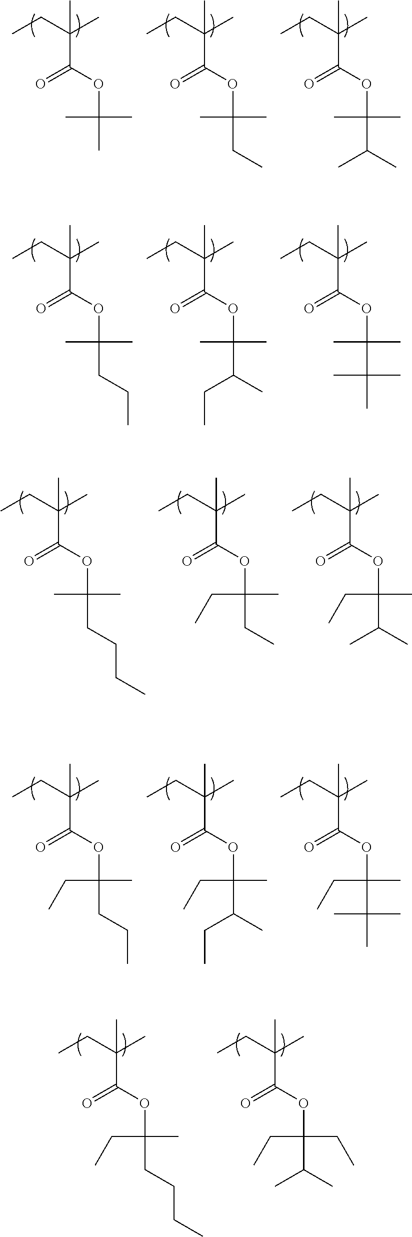

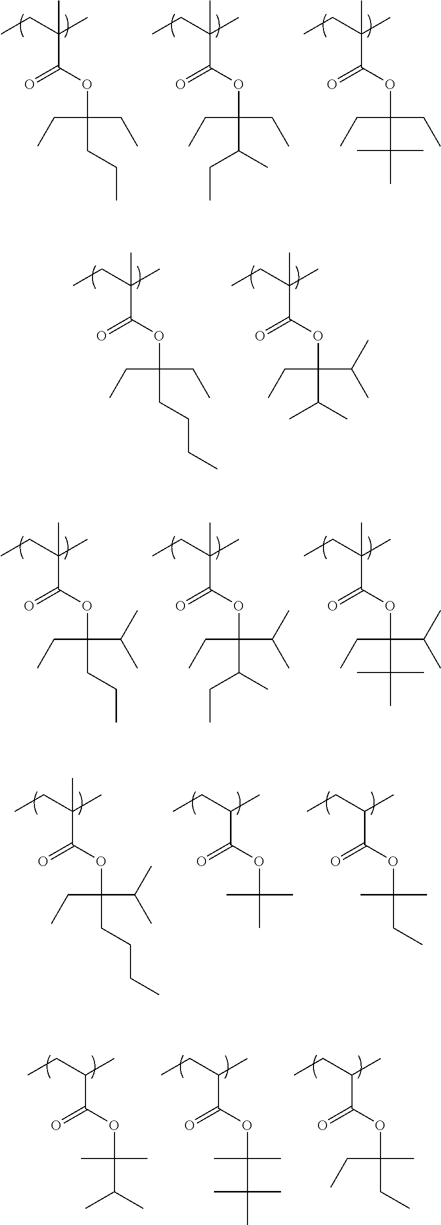

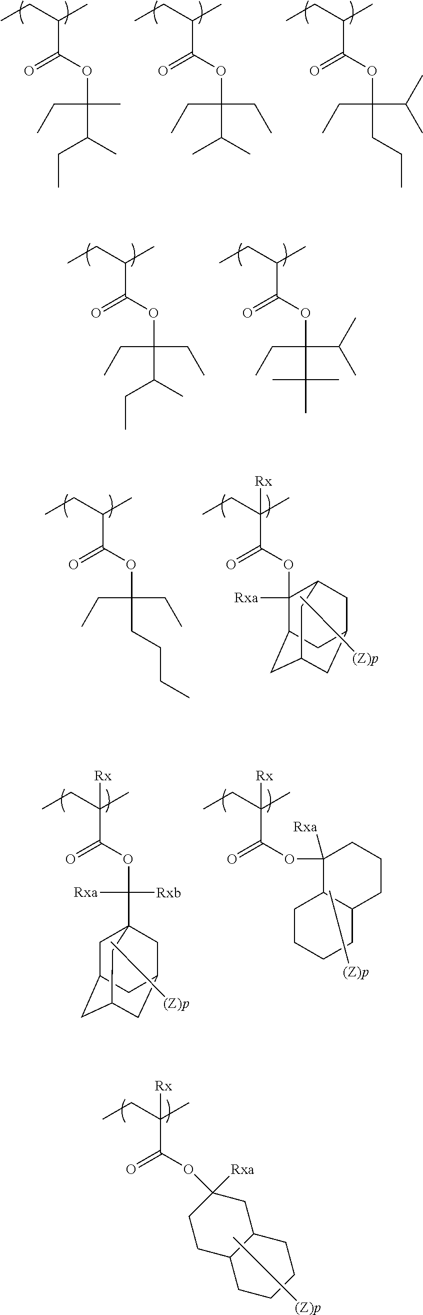

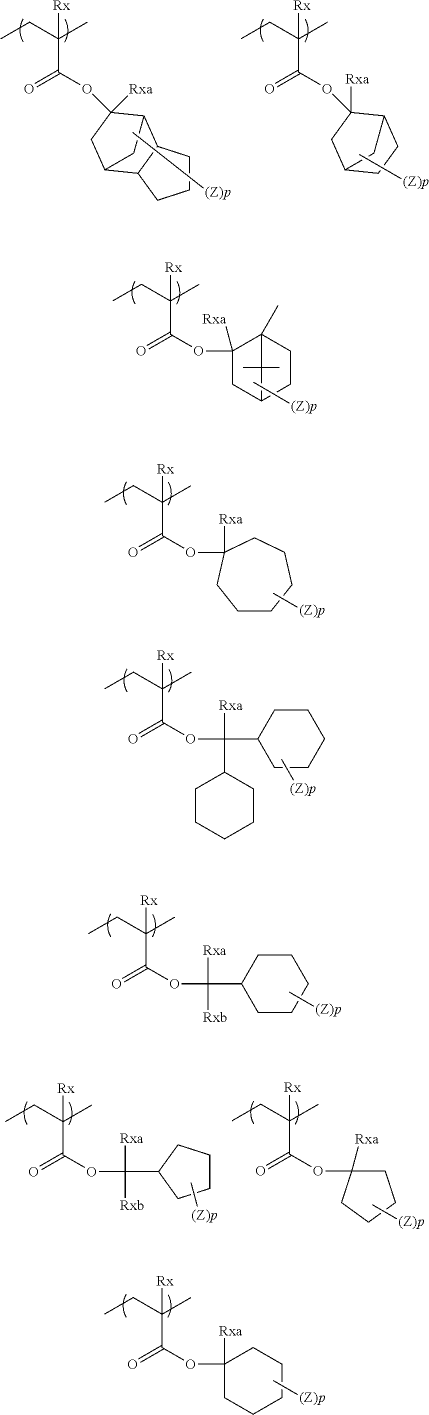

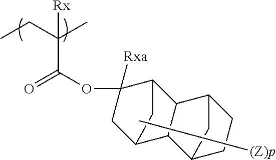

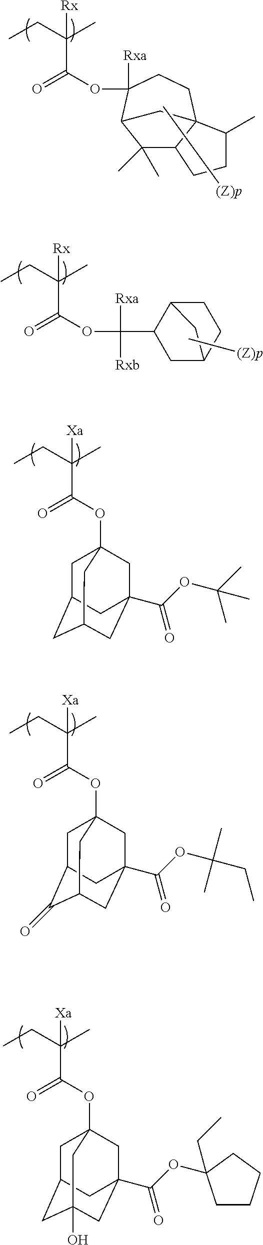

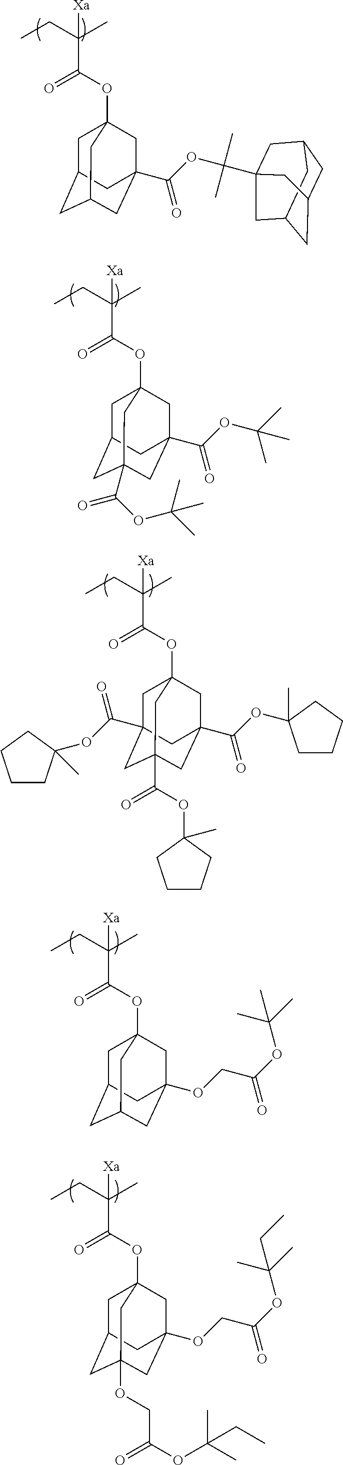

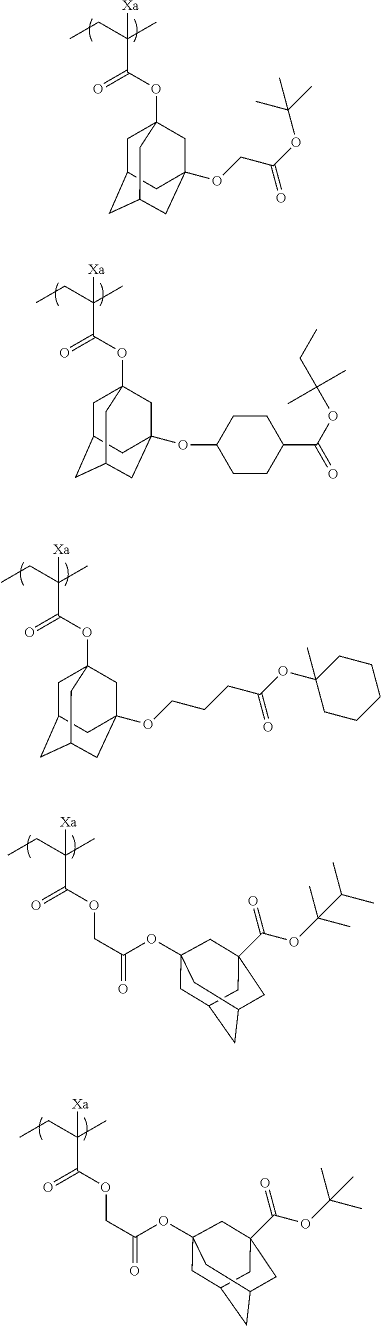

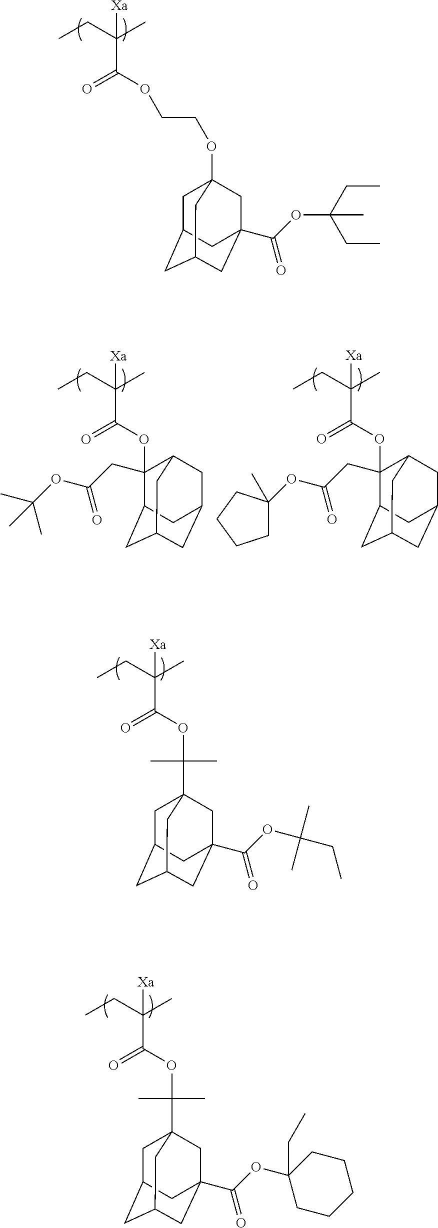

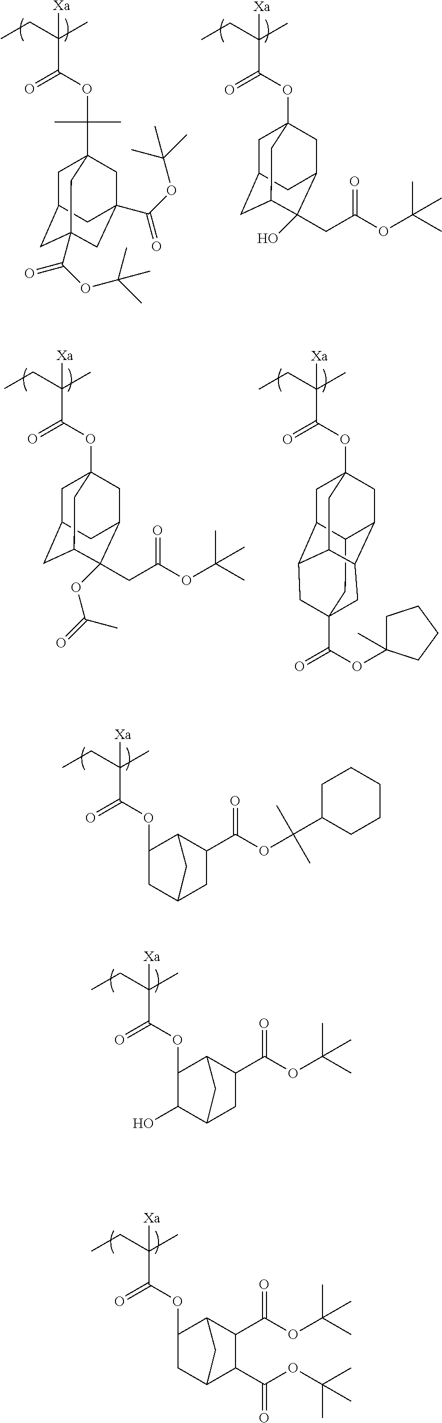

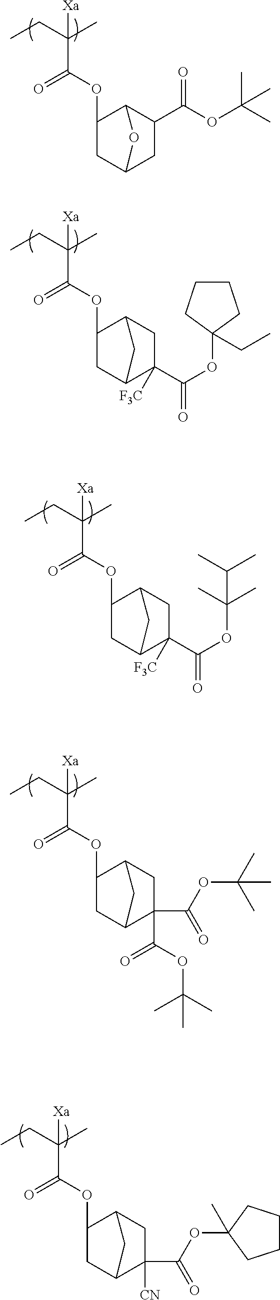

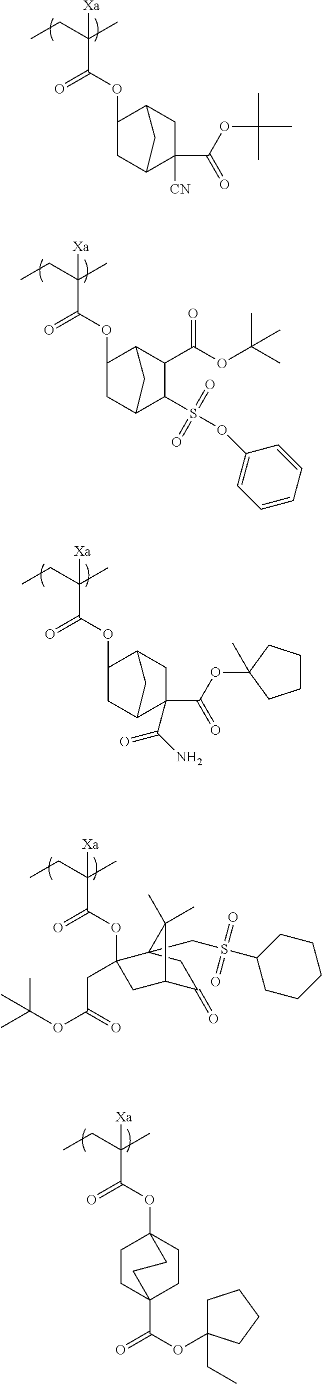

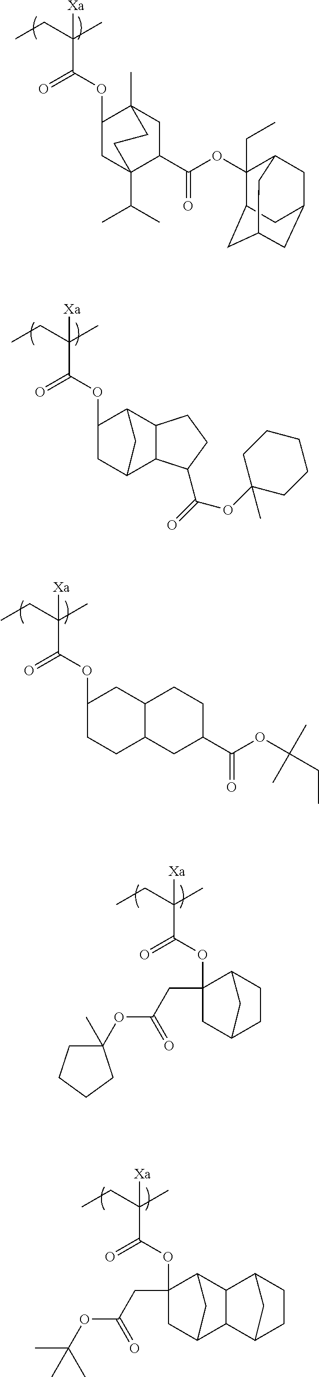

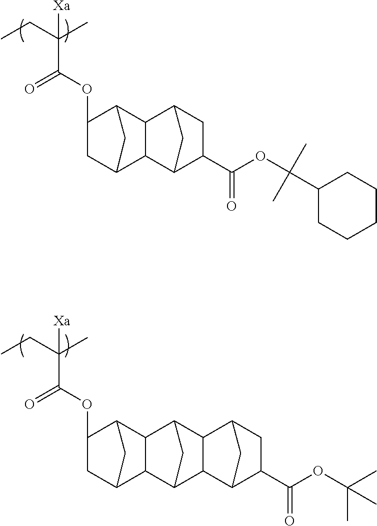

As stated above, the resin (A) may preferably include a repeating unit represented by Formula (II).

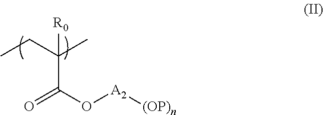

In Formula (II),

R₀ represents a hydrogen atom or an alkyl group, and A₂ represents an (n+1)-valent organic group.

OP represents a group capable of decomposing by the action of an acid to generate an alcoholic hydroxyl group, and when two or more OP's are present, OP's may be same or different and may be bonded to each other to form a ring.

n represents an integer of 1 to 3.

Specific examples and preferred examples of R₀ may be the same as those described above for R₀ in Formula (I).

Specific examples and preferred examples of the (n+1)-valent organic group represented by A₂ are the same as those listed above for the (y+1)-valent organic group represented by A₁ in Formula (I).

n preferably represents 1 or 2, and when n is 2 or more, it is possible to further improve the dissolution contrast in an organic solvent-containing developer. As a result, it is also possible to further improve the roughness characteristic.

Hereinafter, specific examples of a repeating unit having an acid decomposable acid that generates an alcoholic hydroxyl group will be illustrated. In the specific examples, Ra represents a hydrogen atom or an alkyl group, OP has the same meaning as OP in Formula (III). Also, two or more OP's may be bonded to each other to form a ring, and the structure of the resulting ring may be represented as “O—P—O” for the sake of convenience.

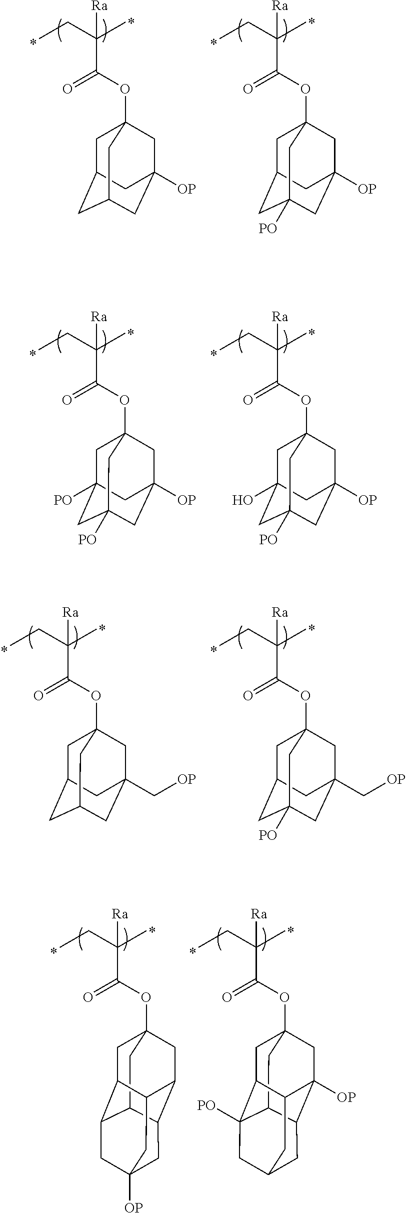

A group capable of decomposing by the action of an acid to generate an alcoholic hydroxyl group may preferably be represented by at least one selected from the group consisting of Formulas (OR-1) to (OR-4) below if the group is supposed to generate one alcoholic hydroxyl group.

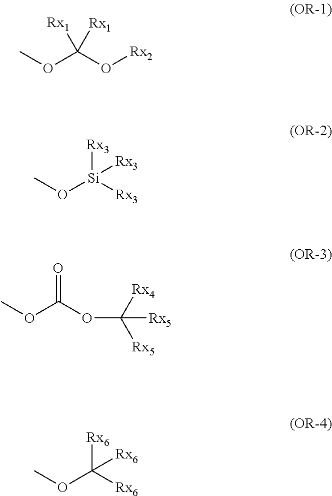

In Formula (OR-1), each Rx₁ independently represents a hydrogen atom or a monovalent organic group. Rx₁'s may be bonded to each other to form a ring.

Rx₂ represents a monovalent organic group. Rx₁ and Rx₂ may be bonded to each other to form a ring.

At least one of carbon atoms constituting a ring formed by Rx₁'s bonded to each other or a ring formed by Rx₁ and Rx₂ bonded to each other (a carbon atom contributing to the ring formation) may be substituted by an oxygen atom or a sulfinyl group.

In Formula (OR-2), each Rx₃ independently represents a monovalent organic group. Rx₃'s may be bonded to each other to form a ring.

In Formula (OR-3), Rx₄ represents a hydrogen atom or a monovalent organic group.

Each Rx₅ independently represents a monovalent organic group. Rx₅'s may be bonded to each other to form a ring. Rx₄ and Rx₅ may be bonded to each other to form a ring.

In Formula (OR-4), each Rx₆ independently represents a hydrogen atom, an alkyl group, a cycloalkyl group, an aryl group, an alkenyl group, or an alkynyl group. Rx₆'s may be bonded to each other to form a ring. However, if one or two of three Rx₆'s are hydrogen atoms, at least one of remaining Rx₆'s represents an aryl group, an alkenyl group or an alkynyl group.

A group capable of decomposing by the action of an acid to generate an alcoholic hydroxyl group, as a group generating two or three alcohol hydroxyl groups, is represented by at least one selected from the group consisting of the following Formulae (OR-5) to (OR-9).

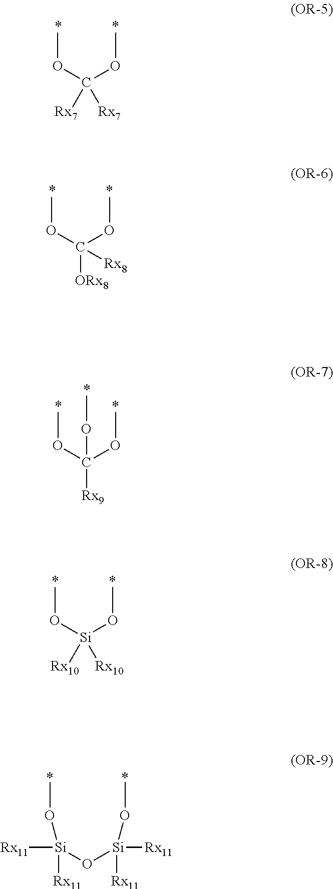

In Formula (OR-5) above, each Rx₇ independently represents a hydrogen atom or a monovalent organic group. Rx₇'s may be bonded to each other to form a ring.

In Formula (OR-6) above, each Rx₈ independently represents a hydrogen atom or a monovalent organic group. Rx₈'s may be bonded to each other to form a ring.

In Formula (OR-7) above, Rx₉ represents a monovalent organic group.

In Formula (OR-8) above, each Rx₁₀ independently represents a monovalent organic group. Rx₁₀'s may be bonded to each other to form a ring.

In Formula (OR-9) above, each Rx₁₁ independently represents a monovalent organic group. Rx₁₁'s may be bonded to each other to form a ring.

In Formulas (OR-5) to (OR-9), * represents a bonding hand for bonding to the main chain or side chain of the resin.

A group capable of decomposing by the action of an acid to generate an alcoholic hydroxyl group is more preferably represented by at least one selected from Formulas (OR-1) to (OR-3), and still more preferably represented by Formula (OR-1) or (OR-3).

Each of Rx₁ and Rx₄, as described above, independently represents a hydrogen atom or a monovalent organic group. Rx₁ and Rx₄ preferably represent a hydrogen atom, an alkyl group or a cycloalkyl group, and more preferably represent a hydrogen atom or an alkyl group.

In Rx₁ and Rx₄, the alkyl group may be straight or branched and may preferably have 1 to 10 carbon atoms and more preferably 1 to 3 carbon atoms. Examples of the alkyl group in Rx₃ may include a methyl group, an ethyl group, an n-propyl group, an isopropyl group and an n-butyl group.

In Rx₁ and Rx₄, the cycloalkyl group may be monocyclic or polycyclic, and may preferably have 3 to 10 carbon atoms and more preferably 4 to 8 carbon atoms. Examples of the cycloalkyl group in Rx₁ and Rx₄ may include a cyclopropyl group, a cyclobutyl group, a cyclopentyl group, a cyclohexyl group, a norbornyl group and an adamantly group.

Also, in Formula (OR-1), at least one Rx₁ is preferably a monovalent organic group. If this configuration is employed, a still higher sensitivity may be achieved.

Rx₁ and Rx₄ may have a substituent, and examples of such substituent may include an alkyl group (having 1 to 4 carbon atoms), a cycloalkyl group (having 3 to 10 carbon atoms), a halogen atom, a hydroxyl group, an alkoxy group (having 1 to 4 carbon atoms), a carboxyl group, an alkoxycarbonyl group (having 2 to 6 carbon atoms), and an aryl group (having 6 to 10 carbon atoms), which may preferably have 8 carbon atoms or less.

Rx₂ and Rx₅, as stated above, represent a monovalent organic group. Rx₂ and Rx₅ preferably represent an alkyl group or a cycloalkyl group and more preferably an alkyl group. The alkyl group and the cycloalkyl group may further have a substituent. Examples of such substituent may be the same as those described for the substituent which may be possessed by Rx₁ and Rx₄.

The alkyl group in Rx₂ and Rx₅ may not have a substituent or may preferably have at least one aryl group and/or at least one silyl group as a substituent. The unsubstituted alkyl group may preferably have 1 to 20 carbon atoms. In the alkyl group substituted by at least one aryl group, the alkyl group moiety may preferably have 1 to 25 carbon atoms.

Specific examples of Rx₂ and Rx₅ may include the same ones as described for the alkyl group in Rx₁ and Rx₄. Also, the aryl group in the alkyl group substituted by at least one aryl group may preferably have 6 to 10 carbon atoms, and specific examples of the aryl group may include a phenyl group and a naphthyl group.

The alkyl group moiety in the alkyl group substituted by at least one silyl group preferably has 1 to 30 carbon atoms. When the cycloalkyl group in Rx₂ and Rx₅ does not have a substituent, it preferably has 3 to 20 carbon atoms.

Specific examples of the cycloalkyl group in Rx₂ and Rx₅ may include the same those described for the cycloalkyl group in Rx₁ and Rx₄.

Preferably, each Rx₃ independently represents an alkyl group, a cycloalkyl group or an aryl group, more preferably an alkyl group or a cycloalkyl group, and still more preferably an alkyl group.

Specific examples and preferred examples of the alkyl group and the cycloalkyl group in Rx₃ may include the same as those listed for the alkyl group and the cycloalkyl group in Rx and Rx₄.

The aryl group in Rx₃ may include an aryl group having 6 to 10 carbon atoms, such as a phenyl group and a naphthyl group.

The alkyl group, the cycloalkyl group and the aryl group may further have a substituent and examples of such substituent may include the same as those listed for the substituent which may be possessed by Rx₁ and Rx₄.

Rx₆ represents a hydrogen atom, an alkyl group, a cycloalkyl group, an aryl group, an alkenyl group or an alkynyl group. However, when one or two of three Rx₆'s represents a hydrogen atom, at least one of remaining Rx₆'s represents an aryl group, an alkenyl group or an alkynyl group. Rx₆ preferably represents a hydrogen atom or an alkyl group. Further, the alkyl group, the cycloalkyl group, an aryl group, an alkenyl group and an alkynyl group represented by Rx₆ may have a substituent. Examples of such substituent may include the same as those listed for the substituent which may be possessed by Rx₁ and Rx₄.

Examples of the alkyl group and the cycloalkyl group represented by Rx₆ may include the same as those listed for the alkyl group and the cycloalkyl group in Rx₁ and Rx₄. In particular, if the alkyl group has no substituent, it preferably has 1 to 6 carbon atoms and more preferably 1 to 3 carbon atoms.

Examples of the aryl group in Rx₆ may include the same as those listed above for the aryl group of Rx₃.

Examples of the alkenyl group in Rx₆ may include an alkenyl group having 2 to 5 carbon atoms, such as a vinyl group, a propenyl group and an aryl group.

Examples of the alkynyl group in Rx₆ may include an alkynyl group having 2 to 5 carbon atoms, such as an ethynyl group, a propynyl group and a butynyl group.

Rx₇, as stated above, represents a hydrogen atom or a monovalent organic group. Rx₇ is preferably a hydrogen atom, an alkyl group or a cycloalkyl group, more preferably a hydrogen atom or an alkyl group. and still more preferably an alkyl group having no hydrogen atom or substitute. Rx₇ is preferably a hydrocarbon or an alkyl group having 1 to 10 carbon atoms, and more preferably a hydrogen atom or an alkyl group having 1 to 10 carbon atoms and having no substituent.

The alkyl group and the cycloalkyl group as Rx₇ may further have a substituent. Examples of such substituent may include the same as those listed for the substituent which may be possessed by Rx₁ and Rx₄.

Specific examples of the alkyl group and the cycloalkyl group in Rx₇ may include the same as those described above for Rx₁ and Rx₄.

Each Rx₈, as stated above, independently represents a hydrogen atom or a monovalent organic group. Preferably, each Rx₈ independently represents a hydrogen atom, alkyl group or a cycloalkyl group and more preferably a hydrogen atom or an alkyl group.

Examples of the alkyl group and the cycloalkyl group in Rx₈ may include the same as those listed above for the alkyl group and the cycloalkyl group in Rx₁ and Rx₄.

Each of Rx₉ to Rx₁₁, as stated above, independently represents a monovalent organic group. Preferably, each of Rx₉ to Rx₁₁ independently represents an alkyl group or a cycloalkyl group and more preferably an alkyl group.

Examples of the alkyl group and the cycle alkyl group in Rx₉ to Rx₁₁ may include the same as those listed for the alkyl group and the cycloalkyl group in Rx₁ and Rx₄.

Hereinafter, specific examples of a group capable of decomposing by the action of an acid to generate an alcoholic hydroxyl group will be illustrated.

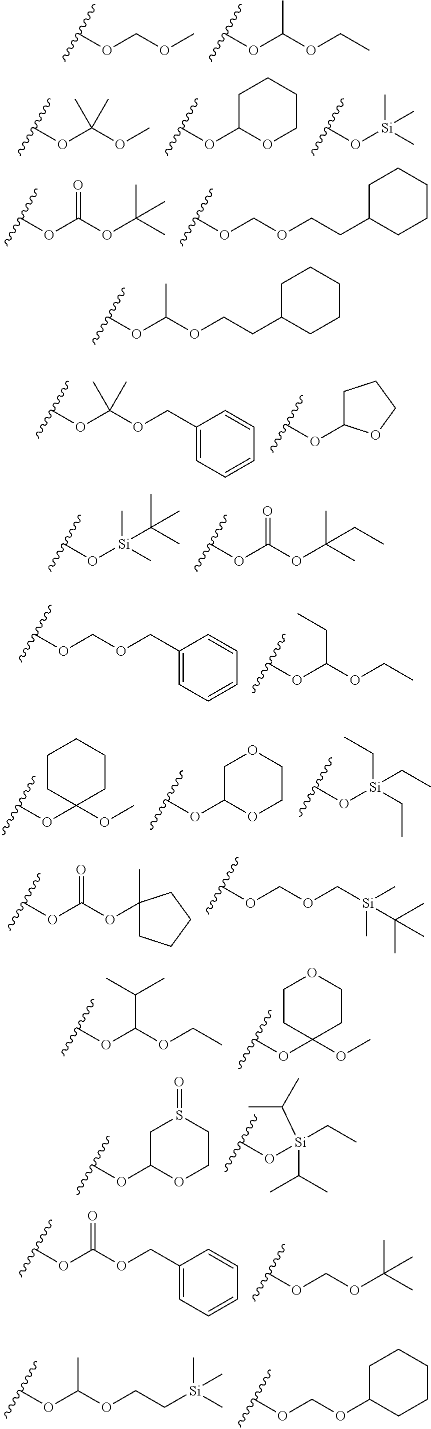

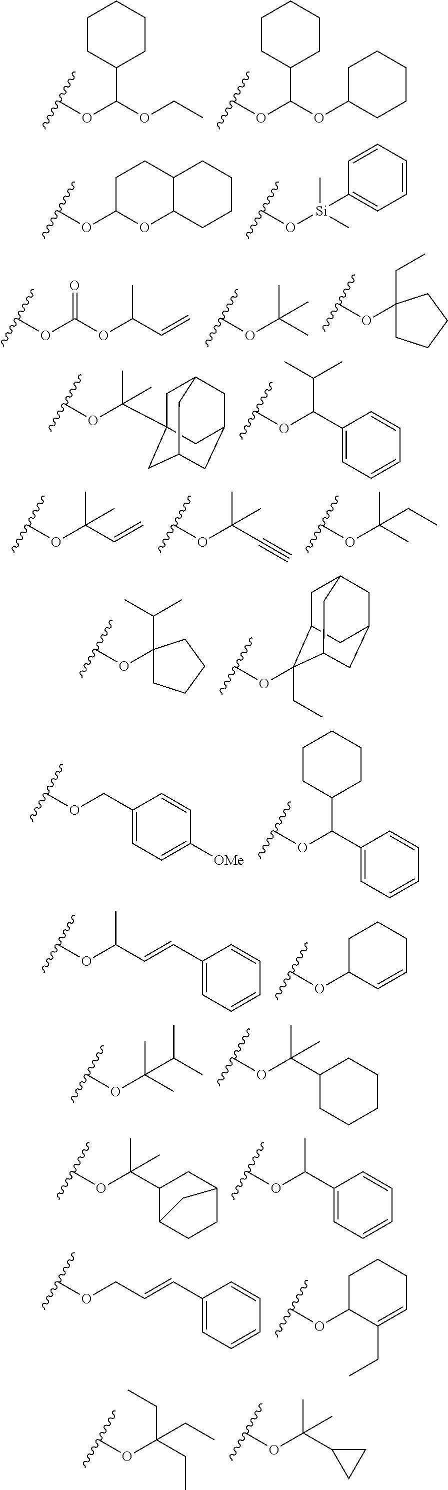

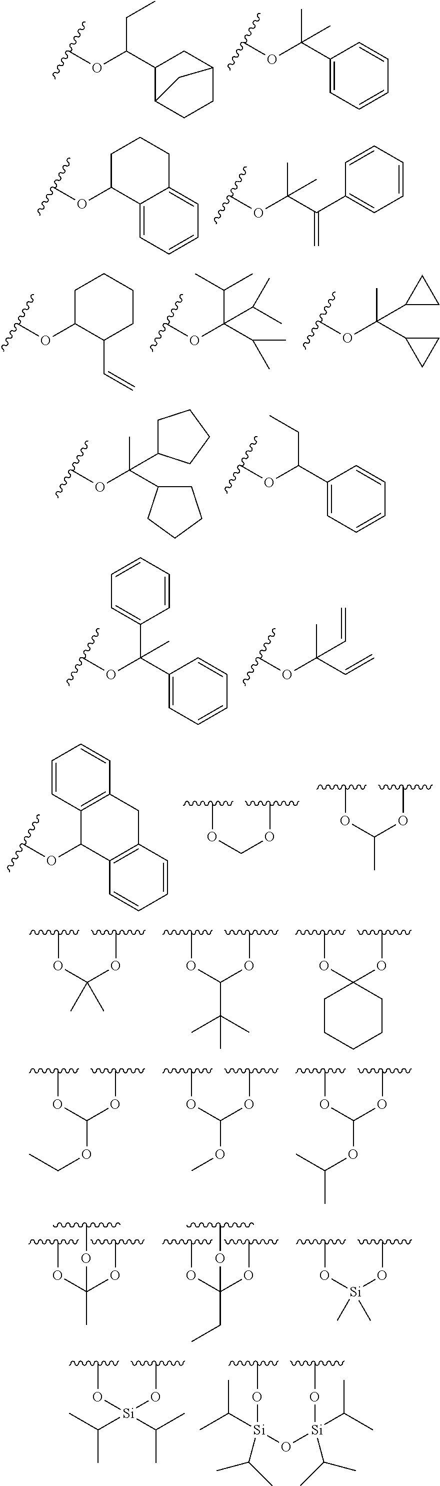

A group capable of decomposing by the action of acid to generate an alcoholic hydroxyl group may preferably be represented by Formula (OR-1) above.

A repeating unit (i) having an acid-decomposable group in the resin (A) may be used either alone or in combination of two or more thereof.

In the resin (A) according to the present invention, the content of the repeating unit (i) (or when two or more repeating units are contained, the total content of the repeating units) is preferably 30 to 90 mol %, more preferably 35 to 80 mol %, and still more preferably 40 to 70 mol %, based on the entire repeating units in the resin (A) in terms of fully decreasing the solubility of an exposed area in an organic developer and fully maintaining the solubility of an unexposed area to thereby improve the dissolution contrast.

[(ii) Repeating Unit Having Polar Group Other than Phenolic hydroxylGroup]

The resin (A) may include a repeating unit (ii) having a polar group other than a phenolic hydroxyl group.

The containment of a repeating unit having a polar group other than a phenolic hydroxyl group may improve, for example, the sensitivity of a composition including the resin. The repeating unit having a polar group other than a phenolic hydroxyl group is preferably a non-acid-decomposable repeating unit (i.e., having no acid-decomposable group).

Examples of the polar group in which a repeating group having a polar group other than a phenolic hydroxyl group may be contained include those illustrated in (1) to (4) below. Further, the term “electronegativity” used herein below refers to Pauling's value of electronegativity.

(1) A functional group including a structure in which an oxygen atom and another atom having a difference of 1.1 or more in electronegativity from the oxygen atom are combined by a single bond.

This type of polar group, for example, may include a group that has a structure represented by O—H, such as an alcoholic hydroxyl group.

(2) A functional group including a structure in which a nitrogen atom and another atom having a difference of 0.6 or more in electronegativity from the nitrogen atom are combined by a single bond.

This type of polar group, for example, may include a group that has a structure represented by N—H, such as an amino group.

(3) A functional group including a structure in which two atoms whose electronegativity differs by 0.5 or more from each other are bonded to each other by a double or triple bond.

This type of polar group, for example, may include a group that has a structure represented by C≡N, C═O, N═O, S═O or C═N.

(4) Functional Group Having Ionic Moiety

This type of polar group may include a group that has a moiety represented by N⁺ or S⁺.

Hereinafter, specific examples of a moiety which may be possessed by the polar group will be illustrated.

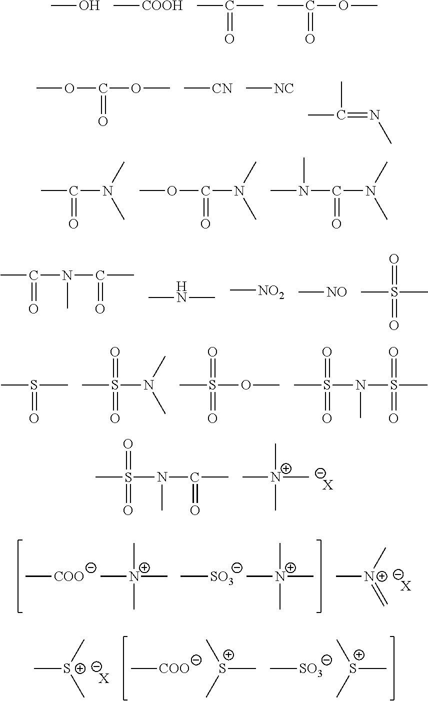

Examples of a polar group which may be possessed by the repeating unit (ii) having a polar group other than a phenolic hydroxyl group preferably include a carboxylic acid group, an alcoholic hydroxyl group, an ester group (including a lactone group), an amide group, an imide group, an sulfonic group, a cyano group, a carbonyl group, a nitro group, a sulfonamide group, and an ether group, and more preferably includes a carboxylic acid group, an alcoholic hydroxyl group and an ester group (including a lactone group).

However, the ester group and the carbonyl group as a polar group which may be possessed by the repeating unit (ii) do not include an ester group directly bonded to the main chain of the resin (A) and a carbonyl group in the ester group (e.g., an ester group and a carbonyl group derived from acrylate ester and methacrylate ester).

Example of this polar group may also preferably include an alcoholic hydroxyl group, a cyano group, a lactone group or a cyanolactone structure.

When a repeating unit having an alcoholic hydroxyl group is further contained in the resin, the exposure latitude (EL) of a composition including the resin may be further improved.

When a repeating unit having a cyano group is further contained in the resin, the sensitivity of a composition including the resin may be further improved.

When a repeating unit having a lactone group is further contained in the resin, the dissolution contrast in an organic-containing developer may be further improved. In addition, it is also possible to further improve the composition including the resin in terms of dry etching resistance, coating property and adhesion to a substrate.

When a repeating unit including a lactone structure having a cyano group is further contained in the resin, the dissolution contrast in an organic solvent-containing developer may be further improved. In this way, it is also possible to improve the composition including the resin in terms of sensitivity, dry etching resistance, coatability and adhesion to a substrate. In addition, it is possible to make each single repeating unit to perform the respective function stemming from the cyano group and the lactone group and further improve the degree of design freedom for the resin.

An acidic group, such as a carboxylic group and a sulfonic amide group which may be possessed by a repeating unit having a polar group other than a phenolic hydroxyl group may or may not include an aromatic ring. In case of having an aromatic ring, the acidic group is selected from an acidic group other than a phenolic hydroxyl group.

Preferred examples of the acidic group include a carboxylic acid group, a sufonic acid group, a fluorinated alcohol group (e.g., a hexafluoroisopropanol group), a sulfonamide group, a sulfonylimide group, a (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and more preferably include a repeating unit having a carboxyl group. Examples of the repeating unit having an acidic group may preferably include any of a repeating unit in which an acidic group is directly bonded to the main chain of the resin, such as a repeating unit by an acrylic acid or a methacrylic acid, a repeating unit in which an acidic group is bonded to the main chain of the resin through a linking group, and a repeating unit in which by using a polymerization initiator or a chain transfer agent each having an acid group at the time of polymerization, the acid group is introduced into the end of the polymer chain.

Although specific examples of a repeating unit having an acidic group such as a carboxylic group and a sulfonic amide group, illustrated below, the present invention is not limit thereto.

In the specific examples, Rx represents H, CH₃ or CF₃, and a represents an integer of 1 or 2.

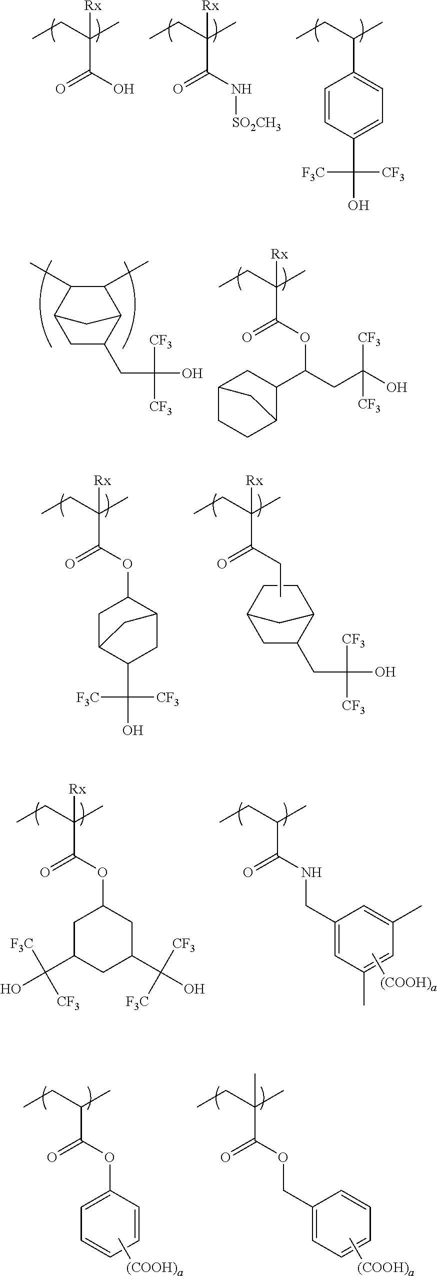

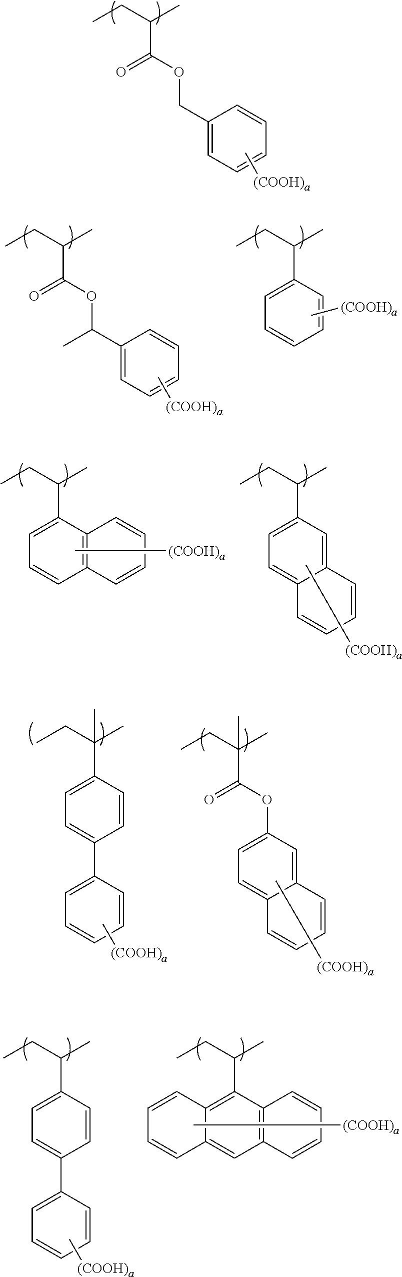

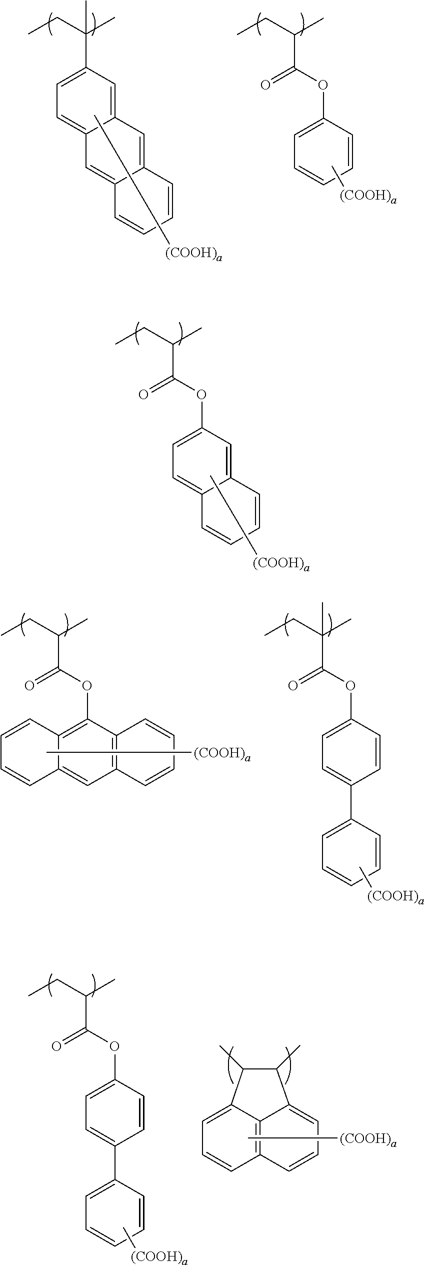

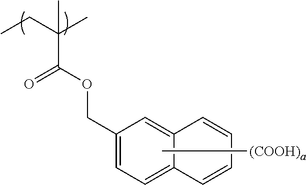

A repeating unit having a polar group may be a repeating unit having a lactone structure as a polar group.

A repeating unit having a lactone structure is more preferably a repeating unit represented by Formula (AII) illustrated below.

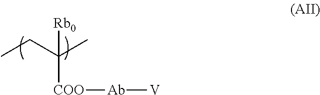

In Formula (AII), Rb₀ represents a hydrogen atom, a halogen atom or an alkyl group that may have a substituent (preferably having 1 to 4 carbon atoms).

The substituent which may be possessed by the alkyl group represented by Rb₀ preferably includes a halogen atom. The halogen atom represented by Rb₀ includes a fluorine atom, a chlorine atom, a bromine atom and an iodine atom. Examples of Rb₀ preferably include a hydrogen atom, a methyl group and a trifluoromethyl group, and more preferably a hydrogen atom and a methyl group.

Ab represents a single bond, an alkaline group and a divalent linking group having a monocyclic or polycyclic cycloalkyl structure, an ether bond, an ester bond, a carbonyl group and a divalent linking group combining them.

Ab preferably represents a single bond or a divalent linking group represented by -Ab₁-CO₂—.

Ab₁ represents a straight or branched alkylene group or a monocyclic or polycyclic cycloalkylene group and preferably a methylene group, an ethylene group, a cyclohexylene group, an adamantylene group or a norbornylene group.

V represents a group having a lactone structure.

Any group may be used as the group having a lactone structure as long as it has a lactone structure, while the lactone structure is preferably a 5- to 7-membered ring lactone structure. Preferably, another ring structure is fused to the 5- to 7-membered ring structure to form a bicyclo or Spiro structure. More preferably, the group having a lactone structure preferably has a lactone structure represented by any one of the following formulae (LC1-1) to (LC1-17). The lactone structure may be bonded directly to the main chain. Preferred lactone structures are (LC1-1), (LC1-4), (LC1-5), (LC1-6), (LC1-8), (LC1-13) and (LC1-14).

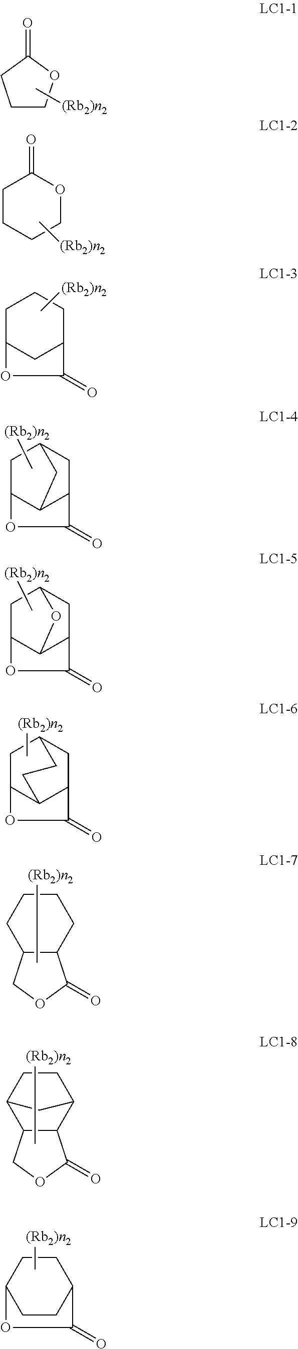

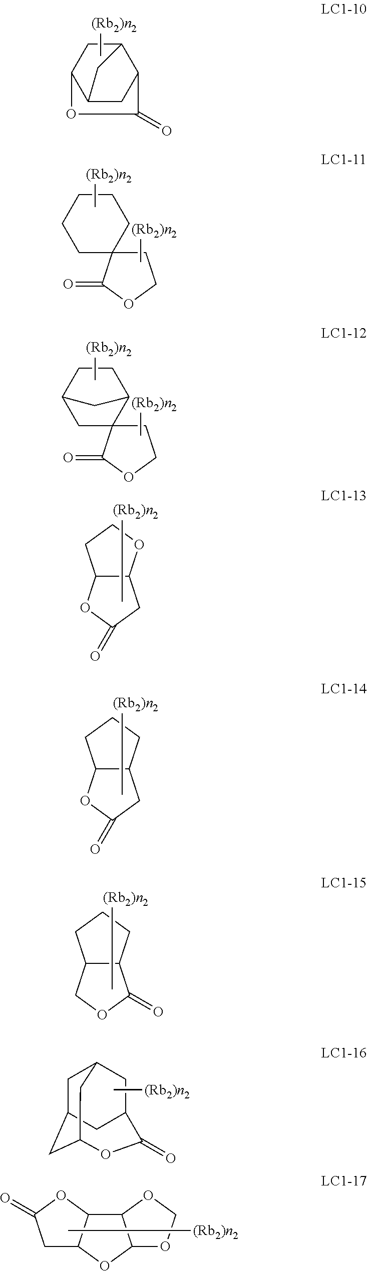

The lactone structure moiety may or may not have a substituent (Rb₂). Preferred examples of the substituent (Rb₂) may include an alkyl group having 1 to 8 carbon atoms, a monovalent cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group and an acid-decomposable group and more preferred examples may include an alkyl group having 1 to 4 carbon atoms, a cyano group and an acid-decomposable group. n₂ represents an integer of 0 to 4. When n₂ is 2 or more, two or more substituents (Rb₂) may be same or different and may be bonded to each other to form a ring.

The repeating unit having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more and more preferably 95% or more.

Specific examples of the lactone structure-containing repeating unit in the resin (A) are illustrated below, but the present invention is not limited thereto. In the formulae, Rx represents H, CH₃, or CF₃.

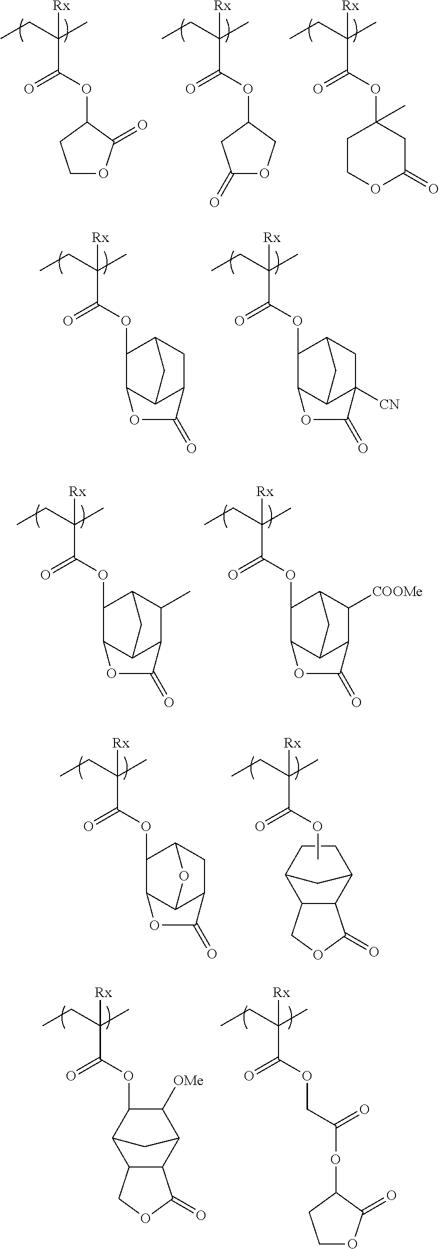

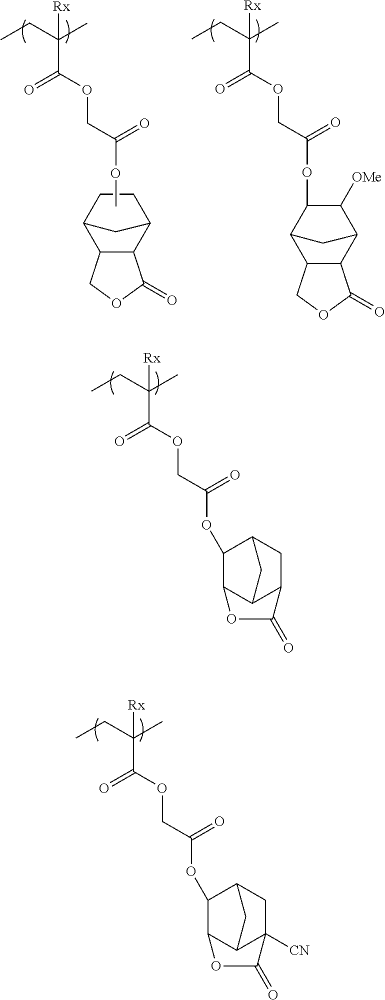

When a polar group that a repeating unit having a polar group has is an alcoholic hydroxyl group or a cyano group, a preferred aspect of the repeating unit includes a repeating unit having an alicyclic hydrocarbon structure substituted by a hydroxyl group or a cyano group. It is preferred that the repeating unit has no acid-decomposable group. In the alicyclic hydrocarbon structure substituted by a hydroxyl group or a cyano group, the alicyclic hydrocarbon structure preferably includes an adamantyl group, a diamantyl group or a norbornane group. The alicyclic hydrocarbon structure substituted by the preferred hydroxyl group or cyano group is preferably a partial structure represented by Formulae (VIIa) to (Vile) illustrated below. Accordingly, adhesion to a substrate and affinity with a developer are enhanced.

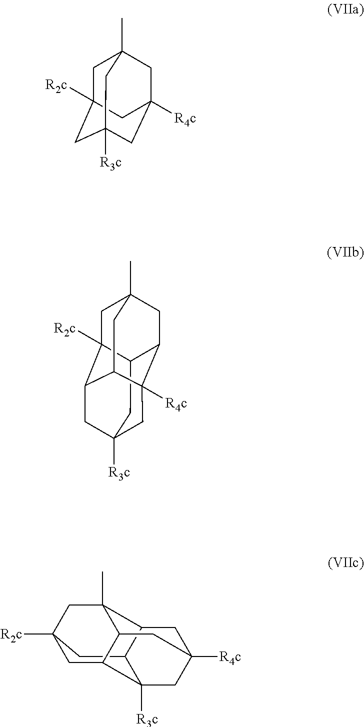

In Formulae (VIIa) to (VIIc), each of R₂c to R₄c independently represents a hydrogen atom or a hydroxyl group or a cyano group. However, at least one of R₂c to R₄c represents a hydroxyl group. Preferably, one or two of R₂c to R₄c are a hydroxyl group and the other(s) is a hydrogen atom. In Formula (VIIa), it is more preferred that two of R₂c to R₀c are a hydroxyl group and the other is a hydrogen atom.

The repeating unit having a partial structure represented by Formulae (VIIa) to (Vile) includes repeating units represented by Formulae (AIIa) to (AIIc) illustrated below.

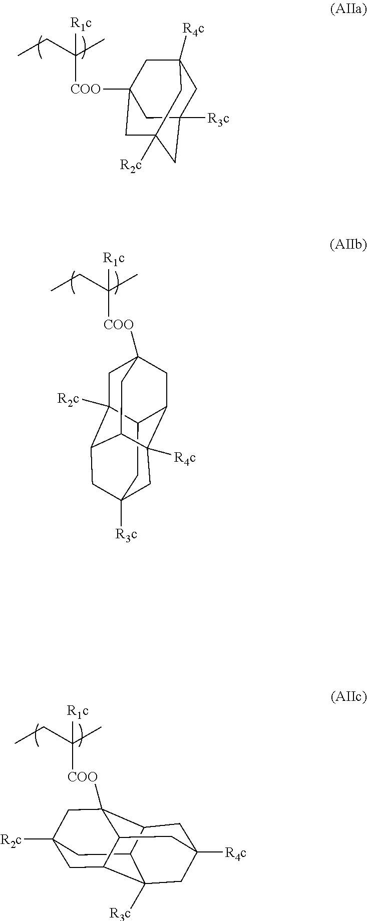

In Formulae (AIIa) to (AIIc), R₁c represents a hydrogen atom, a methyl group, or a trifluoromethyl group.

R₂c to R₄c have the same meaning as R₂c to R₄c in Formulae (VIIa) to (VIIc).

Specific examples of the repeating unit having a hydroxyl group or a cyano group are illustrated below, but the present invention is not limited thereto.

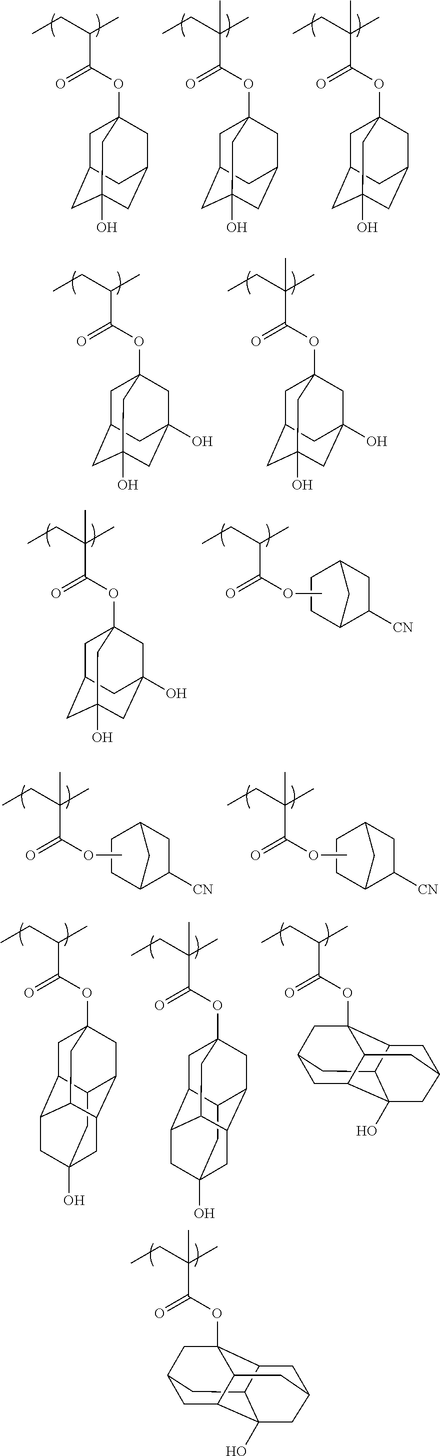

Where the resin (A) includes a repeating unit (ii) having a polar group other than a phenolic hydroxyl group, the upper limit of the content of the repeating unit (ii) having a polar group other than a phenolic hydroxyl group is preferably 75 mol % or less, more preferably 65 mol % or less, still more preferably 40 mol %, and particularly preferably 25 mol % based on the entire repeating units in the resin (A) in terms of fully exhibiting an effect in improving the dissolution contrast between an exposed area and ann unexposed area in the resist film and improving EL, LWR and space collapse performance on a stepped substrate.

Where the resin (A) includes a repeating unit (ii) having a polar group other than a phenolic hydroxyl group, the upper limit of the content of the repeating unit (ii) having a polar group other than a phenolic hydroxyl group is preferably 1 mol % or more and more preferably 3 mol % or more, based on the entire repeating units in the resin (A) in terms of fully exhibiting the effect above.

(Repeating Unit Having Aromatic Group)

According to the present invention, the resin (A) includes an aromatic group. The resin (A) may be preferred if the repeating unit (i) having an acid-decomposable group as stated above and the repeating unit (ii) having a polar group other than a phenolic hydroxyl group have an aromatic group, but, separate from these repeating units, the resin (A) may also preferably include a repeating unit having an aromatic group.

The aromatic group may have a substituent and is preferably an aryl group having 6 to 20 carbon atoms. Examples of the aromatic group may include a phenyl group, a naphthyl group, a biphenyl group and an anthryl group and may preferably include a phenyl group.

However, if the aromatic group is a naphthyl group, a biphenyl group or an anthryl group, exposure light from a KrF excimer laser may be absorbed. Thus, it is possible to reduce an effect of standing waves caused due to light reflection by a substrate or reduce diffused light reflection by a stepped portion of a stepped substrate, thereby forming patterns with a high rectangularity.

Although not specifically limited, examples of the substituent may include a straight or branched alkyl group having 1 to 4 carbon atoms, a cycloalkyl group having 3 to 10 carbon atoms, an aryl group having 6 to 10 carbon atoms, a halogen atom such as a fluorine atom, a cyano group, an amino group, a nitro group, and a carboxylic group. The straight or branched alkyl group having 1 to 4 carbon atoms, the cycloalkyl group having 3 to 10 carbon atoms, and the aryl group having 6 to 10 carbon atoms as the substituent may further have a substituent, and examples of such further substituent may include a halogen atom such as a fluorine atom.

Where the aromatic group is a phenyl group and the phenyl group has a substituent, the substituent is preferably substituted at the 4-position of the phenyl group.

The aromatic group is preferably a phenyl group that may have a substituent in terms of etching resistance.

According to the present invention, the repeating unit having the aromatic group above is preferably a repeating unit represented by Formula (P1) below.

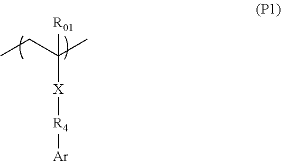

In Formula (P1), R₀₁ represents a hydrogen atom or a straight or branched alkyl group.

X represents a single bond or a divalent linking group.

Ar represents an aromatic group.

R₄ represents a single bond or an alkylene group.

Specific examples and preferred examples of the straight or branched alkyl group represented by R₀₁ may include the same as those listed above for the straight or branched alkyl group represented by R₀ in Formula (I).

X preferably represents a divalent linking group, and the divalent linking group preferably includes —COO— and —CONH—.

Specific examples and preferred examples of Ar may include the same as those listed above for the aromatic group.

An alkylene group represented by R₄ may have a substituent and is preferably an alkylene group having 1 to 4 carbon atoms, and examples thereof may include a methylene group, an ethylene group and a propylene group. A substituent which may be possessed by the alkylene group represented by R₄ includes an alkyl group having 4 carbon atoms and a halogen atom such as a fluorine atom.

The substituent which may be possessed by the alkylene group represented by R₄ and the substituent which may be possessed by the aromatic group Ar may be bonded to each other to form a ring, and the group forming the ring may include an alkylene group (e.g., an ethylene group and a propylene group).

R₄ is preferably a single bond or a methylene group that may be substituted by a substituent in terms of the glass transition temperature (Tg) suitable for a resin in pattern formation.

In the resin (A) according to the present invention, the content of a repeating unit having the aromatic group above [preferably a repeating unit represented by Formula (P1)] (when a plurality of repeating units are contained, their total content) is preferably 1 to 40 mol %, more preferably 3 to 30 mol % and still more preferably 5 to 20 mol %, based on the entire repeating units in the resin (A) in terms of fully reducing the solubility of an exposed area in an organic developer and fully maintaining the solubility of an unexposed area to thereby improve the dissolution contrast and giving resistance to etching.

Although the specific examples of the repeating unit having an aromatic group are illustrated herein, the present invention is not limited thereto. In the formula, a represents an integer of 1 or 2.

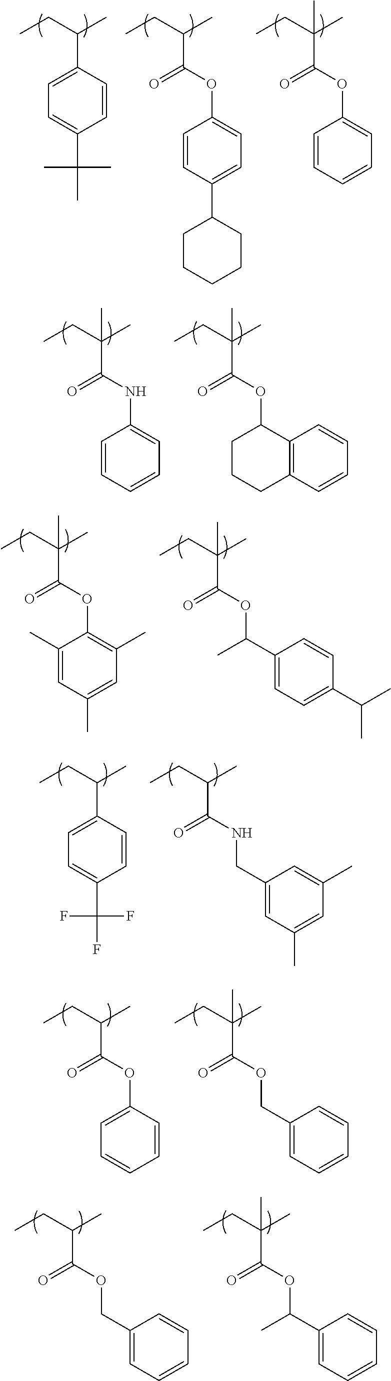

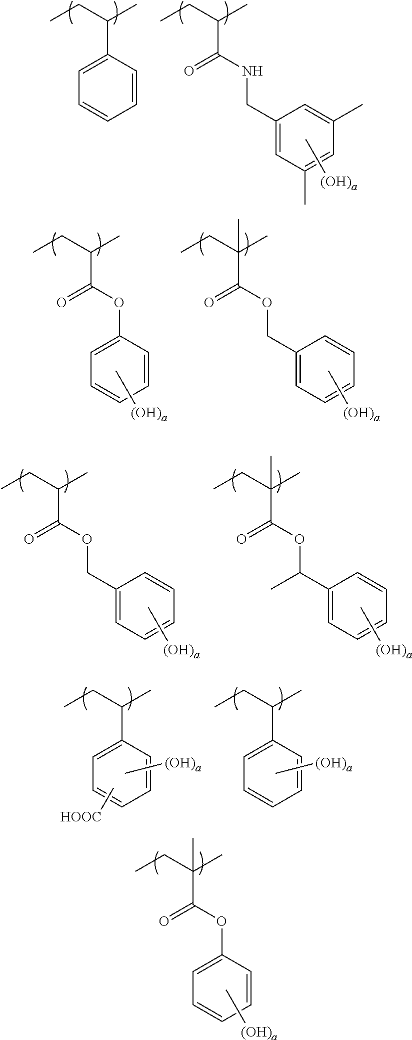

(In the above illustration, a is preferably 1. When a is 1, the substitution position of a hydroxyl group in the benzene ring is preferably a para-position with respect to a bond linked to the main chain of the resin.

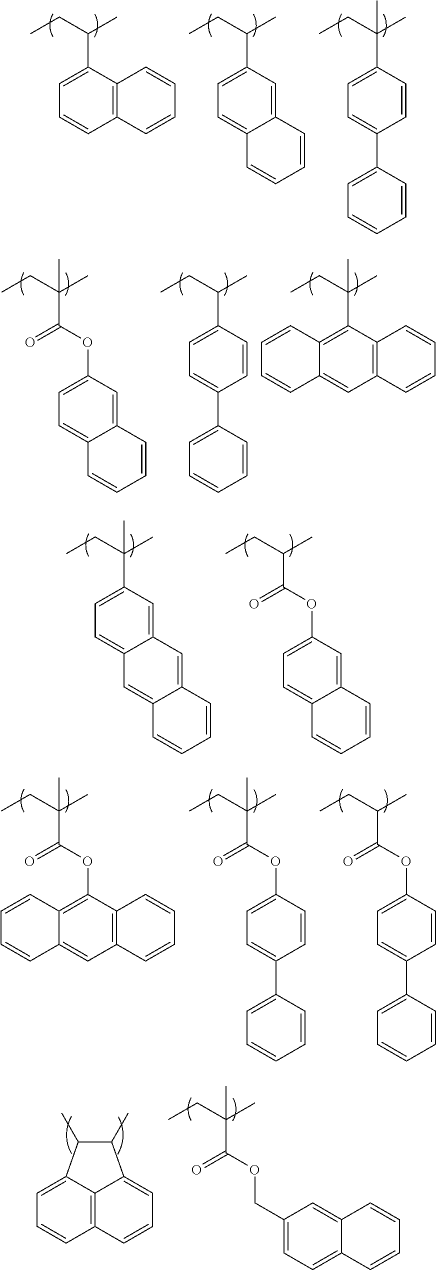

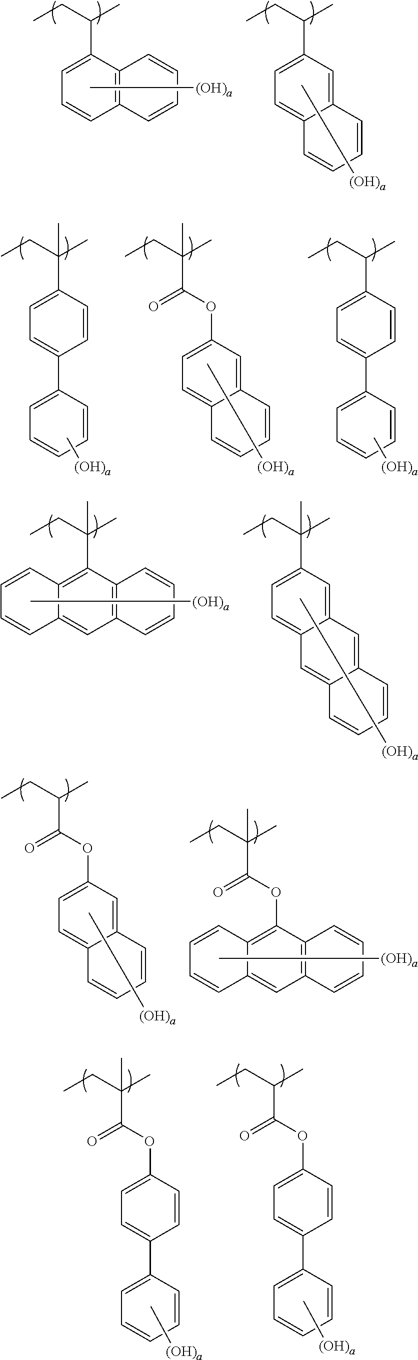

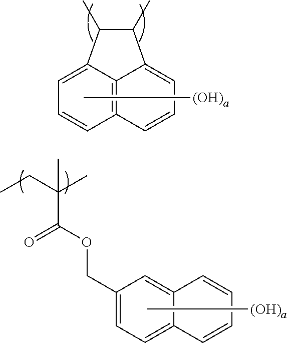

(In the above illustration, a is preferably 1.)

Also, although the type and content of the repeating unit having the above aromatic group are not specifically limited, the content of the repeating unit represented by Formula (q) below is preferably 20 mol % or less based on the entire repeating units in the resin (A) in terms of controlling solubility in a developer, or the like.

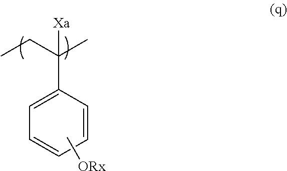

In Formula (q), Xa represents a hydrogen atom or a straight or branched alkyl group.

Rx represents a hydrogen atom or a group capable of decomposing and leaves by the action of an acid.

Specific examples and preferred examples of the straight or branched alkyl group represented by Xa may include the same as those listed above for the straight or branched alkyl group represented by R₀ in Formula (I).

Specific examples and preferred examples of the group capable of decomposing and leaving by the action of acid, as represented by Rx, may include the same as those listed above for the group capable of decomposing and leaving by the action of the acid protecting a polar group constituting an acid-decomposable group in the resin (A).

In the resin (A) according to the present invention, the content of a repeating unit represented by Formula (q) (when a plurality of repeating units are contained, their total content) is preferably 10 mol % or less, more preferably 5 mol % or less and ideally 0 mol %, i.e., no content of repeating units, based on the entire repeating units in the resin (A) in terms of fully reducing the solubility of an exposed area in an organic developer and fully maintaining the solubility of an unexposed area to thereby improve the dissolution contrast. The excessive content of a repeating unit represented by Formula (q) has a tendency to allow the exposed area to be overly dissolved in an organic solvent and result in no resolution and regularity of patterns.

The resin (A) according to the present invention may also have an alicyclic hydrocarbon structure that has no polar group (such as the acid group, the hydroxyl group and the cyano group above) and a repeating unit exhibiting no acid-decomposability. Thus, it is possible to appropriately control the solubility of the resin when developing using an organic solvent-containing developer. Such repeating unit may include a repeating unit represented by Formula (IV).

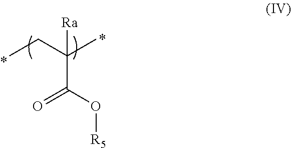

In Formula (IV), R₅ represents a hydrocarbon group that has at least one cyclic structure and has no polar group.

Ra represents a hydrogen atom, an alkyl group or a —CH₂—O-Ra₂ group. In the formula, Ra₂ represents a hydrogen atom, an alkyl group or an acyl group, and Ra is preferably a hydrogen atom, a methyl group and a trifluoromethyl group, and more preferably a hydrogen atom and a methyl group.

The cyclic structure contained in R₅ includes a monocyclic hydrocarbon group and a polycyclic hydrocarbon group. Examples of the monocyclic hydrocarbon group include a cycloalkyl group having 3 to 12 carbon atoms, such as cyclopentyl group, cyclohexyl group, cycloheptyl group and cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

Examples of the polycyclic hydrocarbon group include a ring-aggregated hydrocarbon group and a crosslinked cyclic hydrocarbon group. Examples of the ring-aggregated hydrocarbon group include a bicyclohexyl group and a perhydronaphthalenyl group. Examples of the crosslinked cyclic hydrocarbon ring include a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}0.1^{7,10}]dodecane ring and perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as a perhydronaphthalene (decalin) ring, a perhydroanthracene ring, a perhydrophenathrene ring, a perhydroacenaphthene ring, a perhydrofluorene ring, a perhydroindene ring and a perhydrophenalene ring.

Preferred examples of the crosslinked cyclic hydrocarbon ring may include a norbornyl group, an adamantyl group, a bicyclooctanyl group and a tricyclo[5,2,1,0^{2,6}]decanyl group. More preferred examples of the cross-linked cyclic hydrocarbon rings may include a norbornyl group and an adamantyl group.

These alicyclic hydrocarbon groups may have a substituent, and preferred examples of the substituent may include a halogen atom, an alkyl group, a hydroxyl group with a hydrogen atom being substituted, and an amino group with a hydrogen atom being substituted. Preferred examples of the halogen atom may include a bromine atom, a chlorine atom or a fluorine atom, and preferred examples of the alkyl group may include a methyl group, an ethyl group, a butyl group and a t-butyl group. This alkyl group may further have a substituent, and this further substituent includes a halogen atom, an alkyl group, a hydroxyl group with a hydrogen atom being substituted for, and an amino group with a hydrogen atom being substituted.

Examples of the substituent for the hydrogen atom include an alkyl group, a cycloalkyl group, an aralkyl group, a substituted methyl group, a substituted ethyl group, an alkoxycarbonyl group and an aralkyloxycarbonyl group. The alkyl group is preferably an alkyl group having 1 to 4 carbon atoms; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having 1 to 6 carbon atoms, such as a formyl group, an acetyl group, a propionyl group, a butyryl group, an isobutyryl group, a valeryl group and a pivaloyl group; and the alkoxycarbonyl group includes an alkoxycarbonyl group having 1 to 4 carbon atoms.

The resin (A) may or may not contain a repeating unit having a polar group-free alicyclic hydrocarbon structure and not exhibiting acid decomposability. If the resin (A) has such a repeating unit, the content thereof is preferably 1 to 40 mol % and more preferably 1 to 20 mol %, based on the entire repeating units in the resin (A).

Specific examples of the repeating unit having a polar group-free alicyclic hydrocarbon structure and not exhibiting acid decomposability are illustrated below, but the present invention is not limited thereto. In the formula, Ra represents H, CH₃, CH₂OH or CF₃.

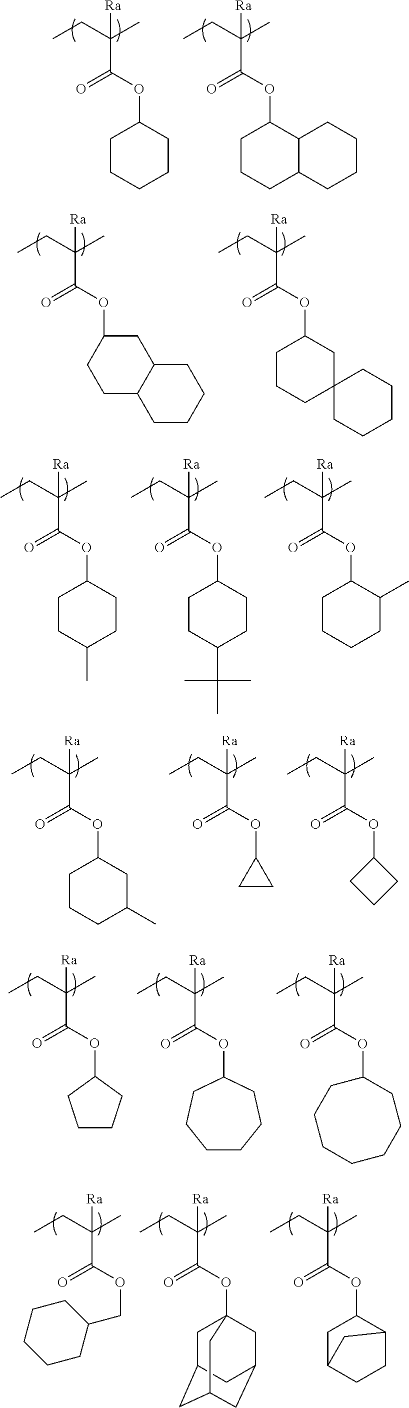

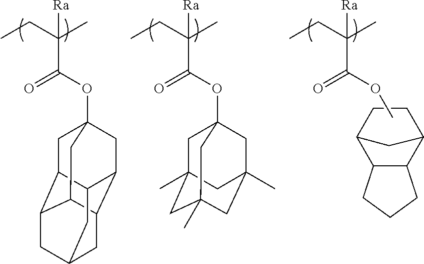

The resin (A) for use in the composition of the present invention may contain, in addition to the above-described repeating structural units, various repeating structural units for the purpose of controlling the dry etching resistance, suitability for a standard developer, adherence to a substrate, resist profile and also properties generally required for an actinic ray-sensitive or radiation-sensitive resin composition, such as resolution, heat resistance and sensitivity.

Examples of such a repeating structural unit include, but are not limited to, repeating structural units corresponding to the monomers described below.

As a result, it is possible to perform fine control over the performance required in the resin used in the composition of the present invention, and particularly the following performance:

(1) solubility in a coating solvent

(2) film-forming property (glass transition temperature)

(3) alkali developability

(4) film loss (selection of hydrophilic/hydrophobic alkali-soluble group),

(5) adherence of unexposed area to substrate

(6) dry etching resistance

Examples of the monomer include a compound having one addition-polymerizable unsaturated bond selected from acrylate esters, methacrylate esters, acrylamides, methacrylamides, allyl compounds, vinyl ethers, vinyl esters, styrenes, and crotonate esters.

Further, an addition-polymerizable unsaturated compound copolymerizable with the monomers corresponding to the above-described various repeating structural units may be copolymerized.

The resin (A) may have a repeating unit represented by Formula (0) below. However, the content of the repeating unit represented by Formula (0) is preferably 45 mol % or less, more preferably 40 mol %, and still more preferably 20 mol %, based on the entire repeating units in the resin (A) in terms of fully reducing the solubility in a developer and maintaining the sufficient dissolution contrast. Ideally, the repeating unit is 0 mol %, i.e., no content of repeating unit is present.

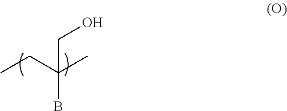

In Formula (0), B represents any side chain.

In the resin (A) according to the present invention, the molar content ratio of each repeating structural unit is appropriately determined to control the dry etching resistance, suitability for a standard developer, adherence to a substrate, resist profile and properties generally required for an actinic ray-sensitive or radiation-sensitive resin composition, such as resolution, heat resistance and sensitivity.

The form of the resin (A) in the present invention may be any of random type, block type, comb type and star type. For example, the resin (A) may be synthesized by polymerization of a radical, cation or anion of an unsaturated monomer corresponding to the respective structure. Also, after polymerization using an unsaturated monomer corresponding to a precursor of the respective structure, a polymer reaction is performed to obtain a desired resin.

The resin (A) according to the present invention can be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and a solvent capable of dissolving the composition of the present invention as described below, such as propylene glycol monomethyl ether acetate, propylene glycol monomethyl ether and cyclohexanone. The polymerization is more preferably performed using the same solvent as the solvent used in the actinic ray-sensitive or radiation-sensitive resin composition of the present invention. Accordingly, occurrence of particles during storage may be suppressed.

The polymerization reaction is preferably performed in an inert gas atmosphere such as nitrogen or argon. As for the polymerization initiator, a commercially available radical initiator (e.g., azo-based initiator, peroxide) is used to start the polymerization. The radical initiator is preferably an azo-based initiator, and an azo-based initiator having an ester group, a cyano group or a carboxyl group is preferred. Preferred examples of the initiator may include azobisisobutyronitrile, azobisdimethylvaleronitrile and dimethyl 2,2′-azobis(2-methylpropionate). The initiator is added additionally or in parts, if desired. After the completion of reaction, the reaction product is introduced into a solvent, and the desired polymer is collected by a powder or solid recovery method or the like. The reaction concentration is from 5 to 50% by mass, preferably from 10 to 30% by mass, and the reaction temperature is usually from 10 to 150° C., preferably from 30 to 120° C., and more preferably from 60 to 100° C.

After the completion of reaction, the reaction solution is allowed to cool to room temperature and purified. The purification may be performed by a conventional method, for example, a liquid-liquid extraction method of applying water washing or combining it with an appropriate solvent to remove residual monomers or oligomer components; a purification method in a solution sate, such as ultrafiltration of removing by extraction only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of the resin slurry with a poor solvent after separation by filtration. For example, the resin is precipitated as a solid by contacting the reaction solution with a solvent in which the resin is sparingly soluble or insoluble (poor solvent), in a volumetric amount of 10 times or less, preferably from 10 to 5 times the reaction solution.

The solvent used at the operation of precipitation or reprecipitation from the polymer solution (precipitation or reprecipitation solvent) may be sufficient if it is a poor solvent for the polymer, and may be appropriately selected from, for example, a hydrocarbon, a halogenated hydrocarbon, a nitro compound, an ether, a ketone, an ester, a carbonate, an alcohol, a carboxylic acid, water, and a mixture of such solvents according to the kind of the polymer.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, and more preferably from 300 to 1,000 parts by mass, based on 100 parts by mass of the polymer solution.

The temperature at the precipitation or reprecipitation may be appropriately selected by taking into consideration the efficiency or operability but is usually on the order of 0 to 50° C. and preferably in the vicinity of room temperature (for example, approximately from 20 to 35° C.). The precipitation or reprecipitation operation may be performed using a commonly employed mixing vessel such as a stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C. and preferably approximately from 30 to 50° C.

Meanwhile, after the resin is once precipitated and separated, the resin may be again dissolved in a solvent and then put into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

Also, for preventing the resin after preparation of the composition from aggregation or the like, as described, for example, in Japanese Patent Application Laid-Open No. 2009-037108, a step of dissolving the synthesized resin in a solvent to make a solution and heating the solution at a temperature of approximately from 30 to 90° C. for approximately from 30 minutes to 4 hours may be added.

The weight average molecular weight of the resin (A) for use in the composition of the present invention is preferably from 1,000 to 200,000, more preferably from 2,000 to 100,000, still more preferably from 3,000 to 70,000, yet still more preferably from 5,000 to 50,000 in terms of the polystyrene-reduced average molecular weight measured using GPC. When the weight average molecular weight is from 1,000 to 200,000, it is possible to prevent the heat resistance or dry etching resistance from deteriorating and prevent the film-forming property from deteriorating due to impaired developability or increased viscosity

The dispersity (molecular weight distribution) is usually from 1.0 to 3.0, preferably from 1.0 to 2.6, more preferably from 1.2 to 2.4, and still more preferably from 1.4 to 2.0. If the molecular weight distribution satisfies such numerical range, the resolution and resist profile are more excellent, the side wall of the resist pattern is smoother, and the roughness is more improved.

In the actinic ray-sensitive or radiation-sensitive resin composition of the present invention, the content of the resin (A) in the composition as a whole is preferably from 30 to 99% by mass and more preferably from 60 to 95% by mass, based on the total solid content.

For the resin (A) according to the present invention, the resin may be used either alone or in combination of two or more thereof.

The actinic ray-sensitive or radiation-sensitive resin composition according to the present invention may further include an acid-decomposable resin (increasing polarity by the action of acid and reducing the solubility in an organic solvent-containing developer) other than the resin (A) in addition to the resin (A). The acid-decomposable resin other than the resin (A) is an acid-decomposable resin including the same repeating unit as the repeating unit that may be contained in the resin (A). The preferred range of these repeating units or their content in the resin is the same as listed above in relation to the resin (A).

In a case where the acid-decomposable resin other than the resin (A) is contained, its content in the composition of the present invention will be enough if the total content of the resin (A) and the acid-decomposable resin other than the resin (A) falls within any of the above ranges. The mass ratio of the resin (A) to the acid-decomposable resin other than the resin (A) may be appropriately adjusted in a range that the effect of the present invention is properly exerted, but, the mass ratio of the resin (A) to the acid-decomposable resin other than the resin (A) is preferably 99.9/0.1 to 10/90, and more preferably 99.9/0.1 to 60/40.

The actinic ray-sensitive or radiation-sensitive resin composition according to the present invention preferably includes the resin (A) only as an acid-decomposable resin in order to ensure that the effect of the present invention is achieved.

[2] Compound (B) Capable of Generating Acid Upon Irradiation with an Actinic Ray-Sensitive or Radiation

The actinic ray-sensitive or radiation-sensitive resin composition of the present invention preferably includes a compound (B) capable of generating an acid upon irradiation with an actinic ray-sensitive or radiation [also referred to as an acid generator (B)]. The acid generator (B) which can be used may be appropriately selected from a photo-initiator for cationic photopolymerization, a photo-initiator for radical photopolymerization, a photo-decoloring agent for dyes, a photo-discoloring agent, a known compound capable of generating an acid upon irradiation with an actinic ray-sensitive or radiation, which is used for microresist or the like, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate. The acid generator (B) is preferably an ionic compound and more preferably a salt. The acid generator (B) preferably includes a sulfonium salt and an iodonium salt.

Also, a compound in which the group or compound capable of generating an acid upon irradiation with an actinic ray-sensitive or radiation is introduced into the main or side chain of polymer, for example those disclosed in U.S. Pat. No. 3,849,137, German Patent No. 3914407, Japanese Patent Application Laid-Open No. Sho 63-26653, Japanese Patent Application Laid-Open No. Sho 55-164824, Japanese Patent Application Laid-Open No. Sho 62-69263, Japanese Patent Application Laid-Open No. Sho 63-146038, Japanese Patent Application Laid-Open No. Sho 63-163452, Japanese Patent Application Laid-Open No. Sho 62-153853, Japanese Patent Application Laid-Open No. Sho 63-146029, etc., may be used.

Compounds capable of generating an acid by a light, as disclosed in U.S. Pat. No. 3,779,778 and European Patent No. 126,712 and the like, may also be used.

Preferred compounds for use as the acid generator (B), among the compounds capable of decomposing upon irradiation with a radiation to generate acid, may include the compounds represented by Formulae (ZI), (ZII) and (ZIII) below.

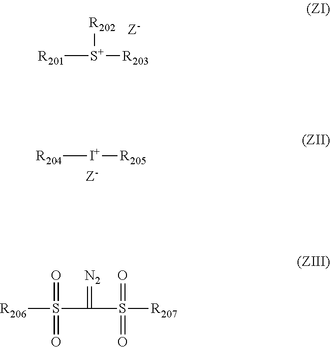

In formula (ZI), each of R₂₀₁, R₂₀₂ and R₂₀₃ independently represents an organic group.

Z⁻ represents a non-nucleophilic anion that preferably includes a sulfonic acid, anion, bis(alkylsufonyl)amid anion, tris(alkylsulfonyl)methyl anion, BF₄⁻, PF₄⁻, SbF₄⁻, etc., and preferably includes an organic anion including a carbon atom. Preferred organic anion includes organic anions represented by Formulae AN1 to AN3.

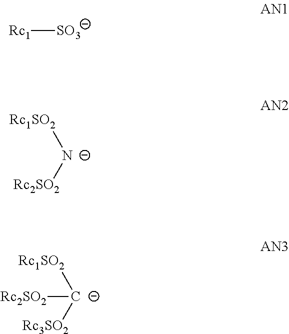

In Formula AN1-AN3, each of R_{c1} to R_{c3} independently represents an organic group. The organic group in R_{c1} to R_{c3} includes an organic group having 1 to 30 carbon atoms, and may preferably include an alkyl group that may be substituted, a monocyclic or polycyclic cycloalkyl group, a heteroatom-containing cyclic group, an aryl group or a group combining two or more of these groups that are linked to each other via a single bond or a linking group, such as —O—, —CO₂—, —S—, —SO₃—, and SO₂N(Rd₁), or may form a ring structure together with another alkyl group and an aryl group combined therewith.

Rd₁ represents a hydrogen atom and an alkyl group and may form a ring structure together with an alkyl group and an aryl group bonded thereto.

The organic group in R_{c1} to R_{c3} may include an alkyl group or a phenyl group whose 1 site is substituted by a fluorine atom or a fluoroalkyl with respect to SO₃⁻ or SO₂. As a result of the fluorine atom or the fluoroalkyl group, the acidity of acid generated upon light irradiation is increased and sensitivity is improved. In R_{c1} to R_{c3}, when there are 1 to 5 carbon atoms, at least one carbon atom is preferably substituted by a hydrogen atom, and more preferably the number of hydrogen numbers is more than that of fluorine atoms. As a result of not having a perfluoroalkyl group having 5 or more carbon atoms, toxicity to ecology is reduced.

In particular, in Formula AN1, an alkyl group represented by Rc₁ is preferably an alkyl group whose 2 position is not substituted by a fluoroalkyl group such as a trifluoromethyl group or an ester bond (—CO₂— or —OCO—) with respect to SO₃⁻, and preferably an alkyl group whose 2 position is substituted by a fluorine atom with respect to SO₃⁻ where the 2 position is substituted with respect to SO₃⁻.

An alkyl group represented by Rc₁ may be linked to a monocyclic or polycyclic cycloalkyl group, a heteroatom-containing cyclic group or an aryl group via an ester bond as a linking group (—CO₂— or —OCO—), and in terms of the diffusivity of generated acid, the group linked via an ester bond (—CO₂— or —OCO—) may preferably be a monocyclic or polycyclic cycloalkyl group or a heteroatom-containing cyclic group.

The organic group as R₂₀₁ to R₂₀₃ generally has 1 to 30 carbon atoms and preferably 1 to 20 carbon atoms.

Also, two of R₂₀₁ to R₂₀₃ may be bonded to form a ring structure and may contain an oxygen atom, a sulfur atom, an ester bond, an amide bond and a carbonyl group in the ring.

The group formed by two of R₂₀₁ to R₂₀₃ bonded to each other includes an alkylene group (e.g., a butylene group and a phentylene group).

Specific examples of the organic group as R₂₀₁ to R₂₀₃ may include the corresponding groups in Formula (ZI-1) and (ZI-2) described below.

The specific examples may also include two or more compounds having a structure represented by Formula (ZI). At least one of R₂₀₁ to R₂₀₃ of the compound represented by Formula (ZI) may be a compound having a structure bonded to at least one of R₂₀₁ to R₂₀₃ of another compound represented by Formula (ZI).

A more preferred (ZI) component may include compounds represented by Formulas (ZI-1) and (ZI-2).

The compound (ZI-1) is an arylsulfonium compound where at least one of R₂₀₁ to R₂₀₃ in Formula (ZI) is an aryl group, that is, a compound having an arylsulfonium as the cation.

In the arylsulfonium compound, all of R₂₀₁ to R₂₀₃ may be an aryl group or a part of R₂₀₁ to R₂₀₃ may be an aryl group, with the remaining being an alkyl group.

Examples of the arylsulfonium compound include a triarylsulfonium compound, a diarylalkylsulfonium compound, and an aryldialkylsulfonium compound.

The aryl group in the arylsulfonium compound is preferably an aryl group, such as a phenyl group, a naphthyl group and a fluorene group, and a heteroaryl group, such as an indole residue and a pyrrole residue, and more preferably a phenyl group and an indole residue. In the case where the arylsulfonium compound has two or more aryl groups, these two or more aryl groups may be same or different.

The alkyl group which is present, if desired, in the arylsulfonium compound is preferably a straight, branched or cyclic alkyl group having 1 to 15 carbon atoms and examples thereof may include a methyl group, an ethyl group, a propyl group, an n-butyl group, a sec-butyl group, a t-butyl group, a cyclopropyl group, a cyclobutyl group and a cyclohexyl group.

The aryl group and the alkyl group as R₂₀₁ to R₂₀₃ may have a substituent, such as an alkyl group (for example, having 1 to 15 carbon atoms), an aryl group (for example, having 6 to 14 carbon atoms), an alkoxy group (for example, having 1 to 15 carbon atoms), a halogen atom, a hydroxyl group and a phenylthio group. The substituent is preferably a straight, branched or cyclic alkyl group having 1 to 12 carbon atoms, a straight, branched or cyclic alkoxy group having 1 to 12 carbon atoms, and most preferably an alkyl group having 1 to 4 carbon atoms or an alkoxy group having 1 to 4 carbon atoms. The substituent may be substituted on any one of three members R₂₀₁ to R₂₀₃ or may be substituted on all of these three members. In the case where R₂₀₁ to R₂₀₃ are an aryl group, the substituent is preferably substituted at the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein includes an aromatic ring containing a heteroatom.

The aromatic ring-free organic group as R₂₀₁ to R₂₀₃ has generally 1 to 30 carbon atoms and preferably 1 to 20 carbon atoms.

Preferably, each of R₂₀₁ to R₂₀₃ independently represents an alkyl group, a cycloalkyl group, a 2-oxoalkyl group, a 2-oxocycloalkyl group, an alkoxycarbonylmethyl group, an aryl group and a vinyl group, more preferably a straight or branched 2-oxoalkyl group, a 2-oxocycloalkyl group and an alkoxycarbonylmethyl group, and most preferably a straight or branched 2-oxoalkyl group.

The alkyl group and the cycloalkyl group as R₂₀₁ to R₂₀₃ preferably includes a straight or branched alkyl group having 1 to 10 carbon atoms (e.g., a methyl group, an ethyl group, a propyl group, a butyl group and a pentyl group) and a cycloalkyl group having 3 to 10 carbon atoms (e.g., a cyclopentyl group, a cyclohexyl group and a norbornyl group).

The 2-oxoalkyl group as R₂₀₁ to R₂₀₃ may be either straight or branched and is preferably a group having >C═O at the 2-position of the alkyl group.

The 2-oxocycloalkyl group as R₂₀₁ to R₂₀₃ is preferably a group having >C═O at the 2-position of the above-described cycloalkyl group.

The alkoxy group in the alkoxycarbonylmethyl group as R₂₀₁ to R₂₀₃ is preferably an alkoxy group having 1 to 5 carbon atoms (e.g., a methoxy group, an ethoxy group, a propoxy group, a butoxy group and a pentoxy group).

R₂₀₁ to R₂₀₃ may be further substituted with a halogen atom, an alkoxy group (for example, having 1 to 5 carbon atoms), a hydroxyl group, a cyano group or a nitro group.

Two of R₂₀₁ to R₂₀₃ may be bonded to form a ring structure and may contain an oxygen atom, a sulfur atom, an ester bond, an amide bond and a carbonyl group in the ring. The group formed by the combination of two of R₂₀₁ to R₂₀₃ may include an alkylene group (e.g., a butylene group and a phentylene group).

Formulae [ZII] and [ZIII] are described below.

In Formulae [ZII] and [ZIII], each of R₂₀₄ to R₂₀₇ independently represents an aryl group that may have a substituent, an alkyl group that may have a substituent, or a cycloalkyl group that may have a substituent.

Specific and appropriate examples of the aryl group as R₂₀₄ to R₂₀₇ are the same as those listed for the aryl group as R₂₀₁ to R₂₀₃ in Formula (ZI-1).

Specific and appropriate examples of the alkyl group and the cycloalkyl group as R₂₀₄ to R₂₀₇ are the same as those listed for the straight, branched or cyclic alkyl group as R₂₀₁ to R₂₀₃.

Z has the same meaning as Z⁻ in Formula ZI.

The acid generator (B), as a compound capable of generating an acid upon irradiation with an actinic ray-sensitive or radiation, may include compounds represented by Formumlae (ZIV), (ZV) and (ZVI).

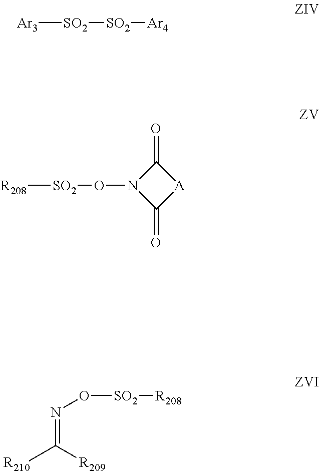

In Formulae ZIV to ZVI, each of Ar₃ and Ar₄ independently represents a substituted or unsubstituted aryl group.

R₂₀₈ in Formulae ZV and ZVI each independently represents a substituted or unsubstituted alkyl group, a substituted or unsubstituted cycloalkyl group or a substituted or unsubstituted aryl group. In terms of increasing the strength of generated acid, R₂₀₈ may be substituted by a fluorine atom.

Each of R₂₀₉ and R₂₁₀ independently represents a substituted or unsubstituted alkyl group, a substituted or unsubstituted cycloalkyl group, a substituted or unsubstituted aryl group, an alkylthio group or an electron-withdrawing group.

Also, R₂₀₉ and R₂₁₀ may be combined to form a ring. The structure of this ring may include an oxygen atom, a sulfur atom, an alkylene group, an alkenylene group, an arylene group, etc.

R₂₀₉ is preferably a substituted or unsubstituted aryl group, and R₂₁₀ is preferably an electron-withdrawing group and more preferably a cyano group or a fluoroalkyl group.

A represents a substituted or unsubstituted alkylene group, a substituted or unsubstituted cycloalkylene group, a substituted or unsubstituted alkenylene group or a substituted or unsubstituted aryelene group.

Specific examples of the aryl group of Ar₃, Ar₄, R₂₀₈, R₂₀₉ and R₂₁₀ are the same as those for the aryl group as R₂₀₁, R₂₀₂ and R₂₀₃ in Formula (ZI-1).

Specific examples of the alkyl group and cycloalkyl group of R₂₀₈, R₂₀₉ and R₂₁₀ are the same as those for the alkyl group and the cycloalkyl group of R₂₀₁, R₂₀₂ and R₂₀₃ in Formula (ZI-2).

Examples of the alkyl moiety of the alkylthio group of R₂₀₉ and R₂₁₀ may include the same as those for the alkyl group of R₂₀₁ to R₂₀₃.

The alkylene group of A includes an alkylene group having 1 to 12 carbon atoms (e.g., a methylene group, an ethylene group, a propylene group, an isopropylene group, a butylene group, and an isobutylene group); the cycloalkylene group of A includes a monocyclic or polycyclic cycloalkylene having 3 to 12 carbon atoms (e.g., a cyclohexylene group, a norbornylene group, and an adamantylene group); the alkenylene group of A includes an alkenylene group having 2 to 12 carbon atoms (e.g., an ethenylene group, a propenylene group, and a butenylene group); and the arylene group of A includes an arylene group having 6 to 10 carbon atoms (e.g., a phenylene group, a tolylene group, and a naphthylene group).

Also, any of R₂₀₉ and R₂₀₁ of a compound represented by Formula ZVI may be a compound having a structure bonded to any of R₂₀₉ and R₂₁₀ of another compound represented by Formula ZVI.

In addition, in terms of increasing the acid generation efficiency and the acid strength, the acid generator (B) preferably has a structure that generates a fluorine atom-containing acid. Specific examples of the acid generator (B) are illustrated below, but not limited thereto.

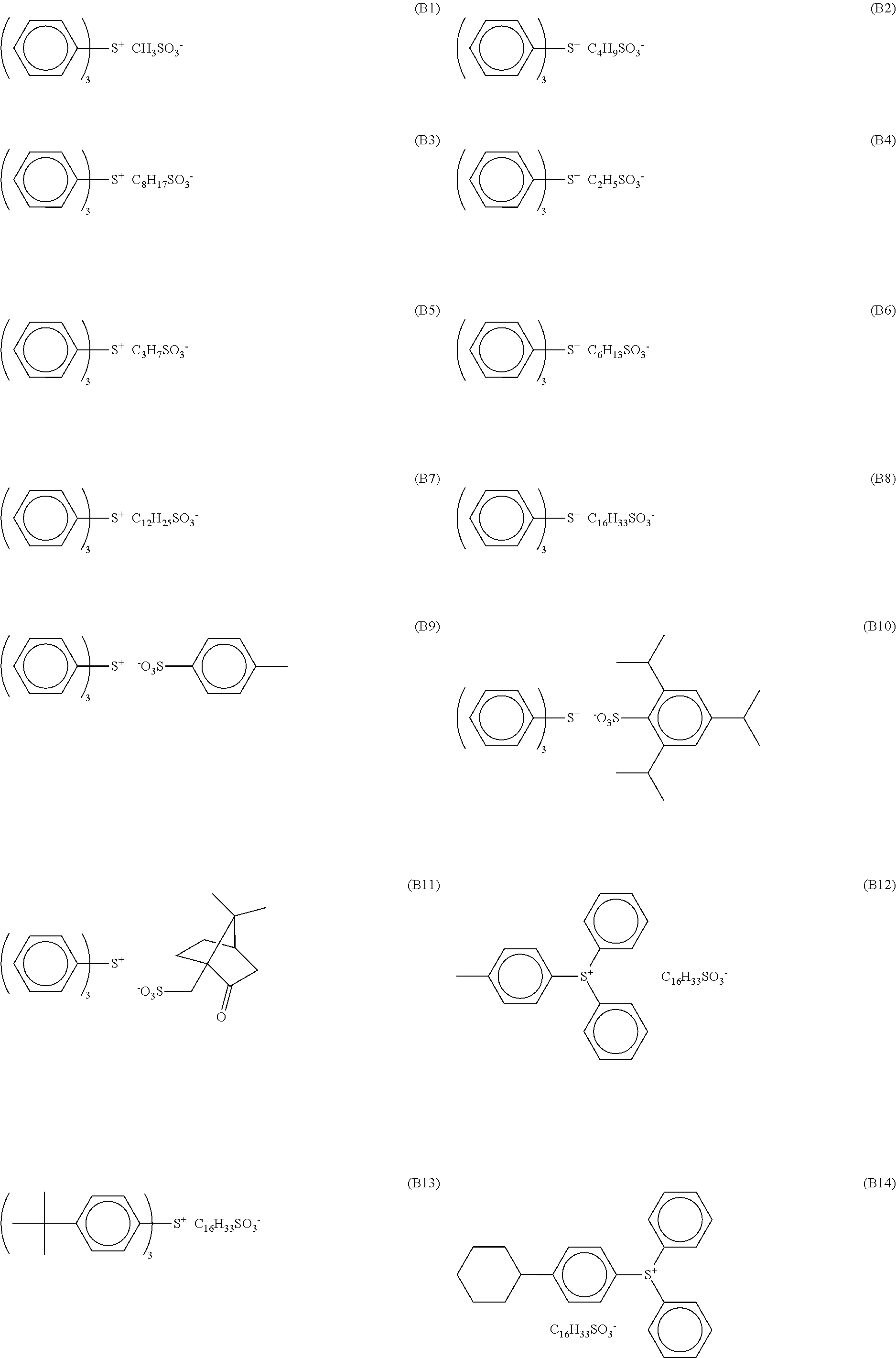

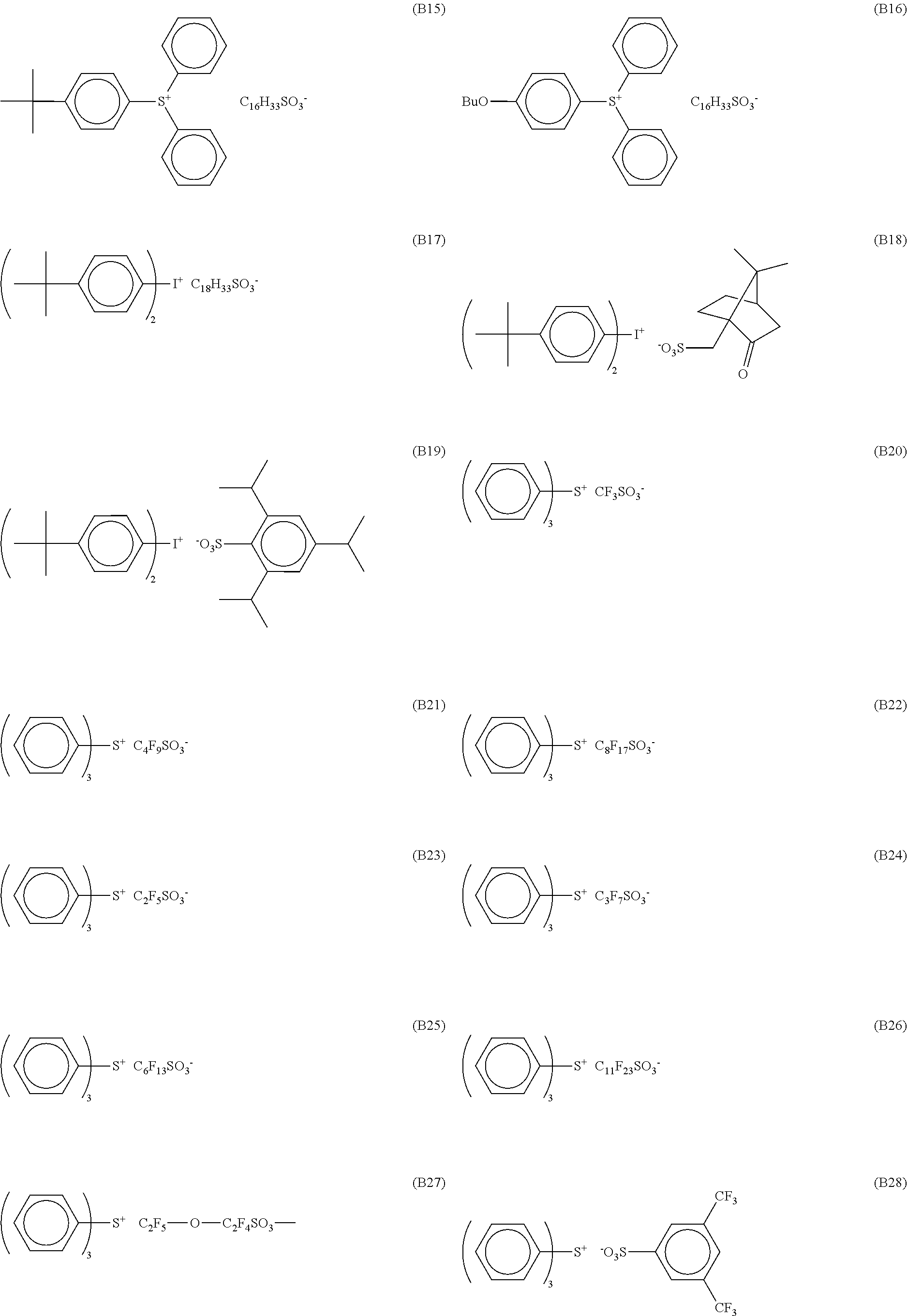

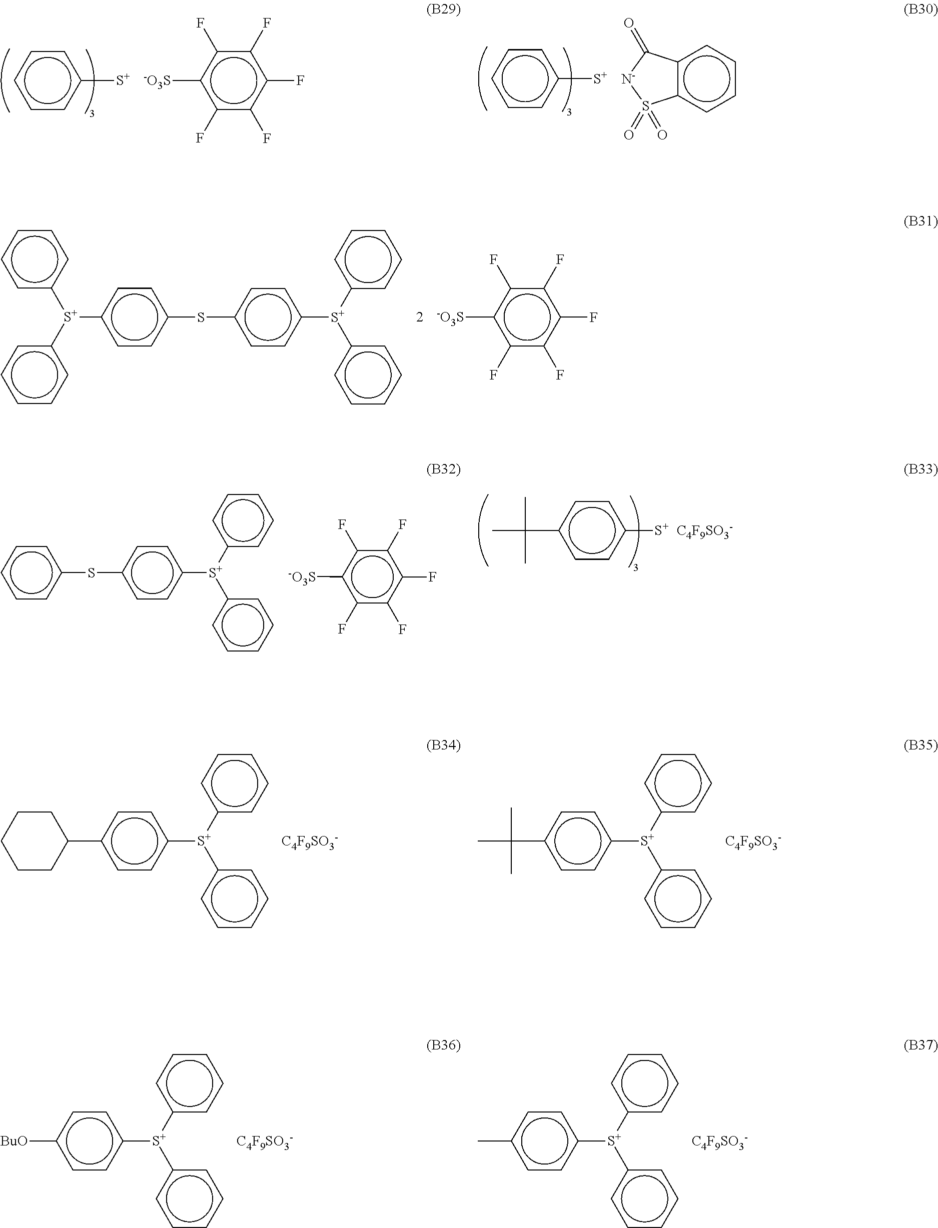

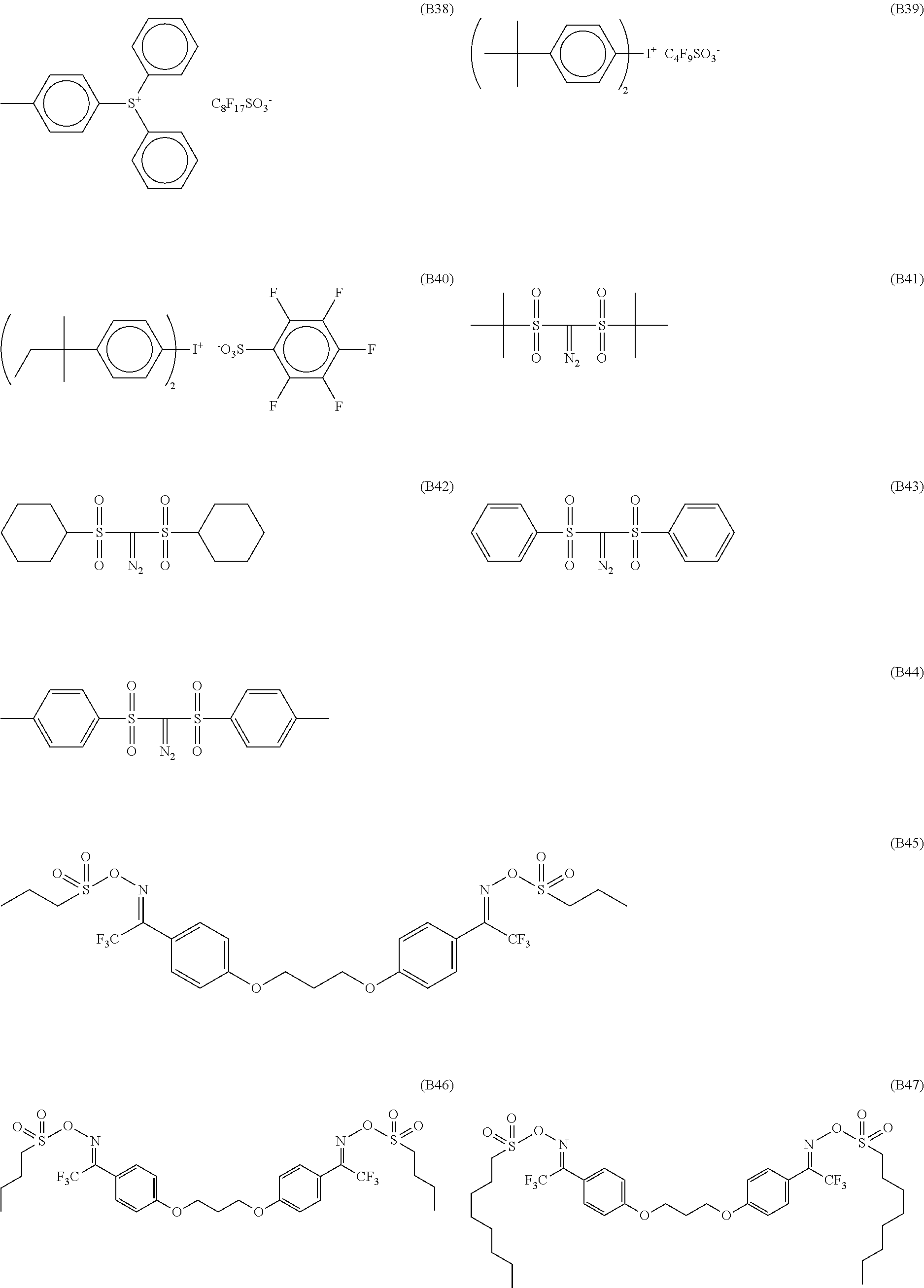

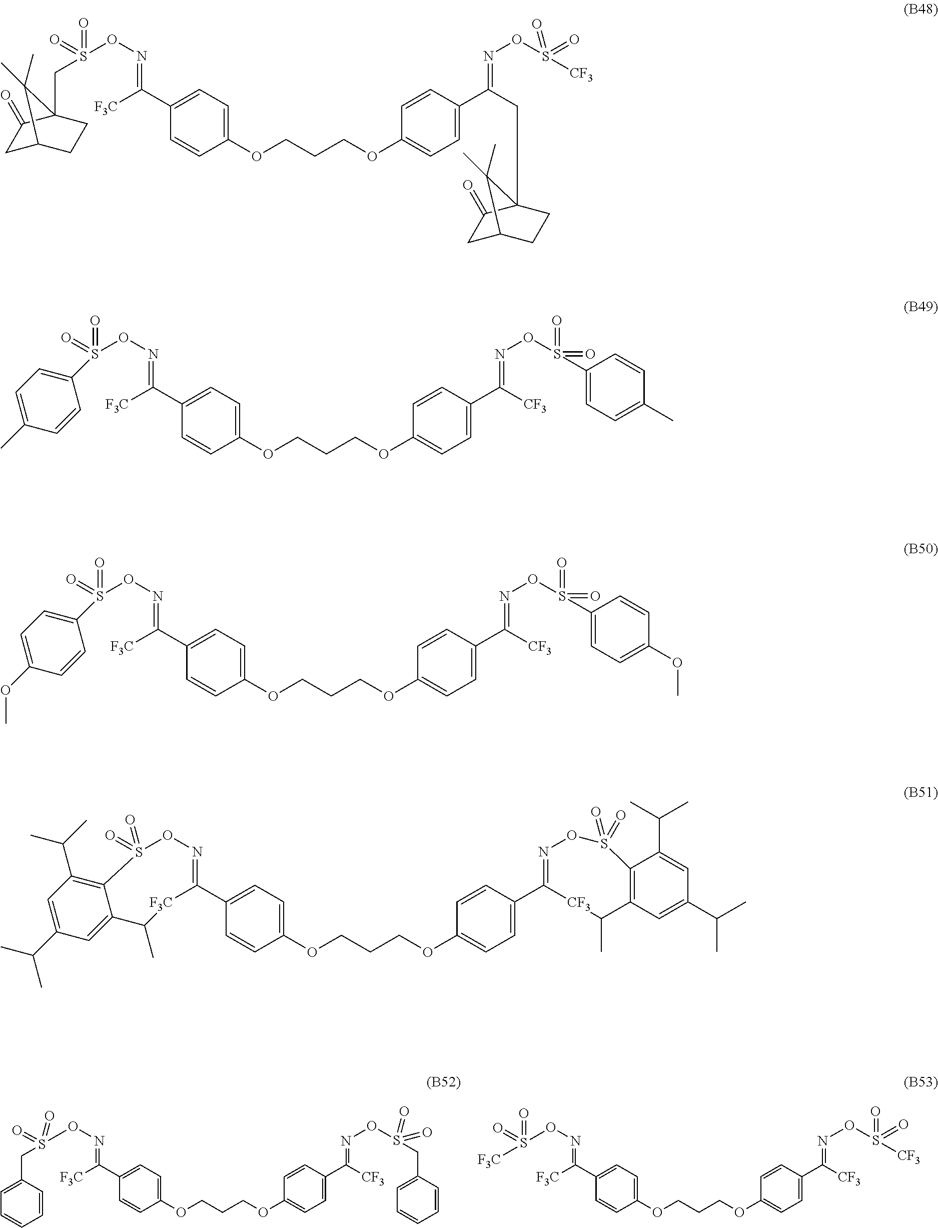

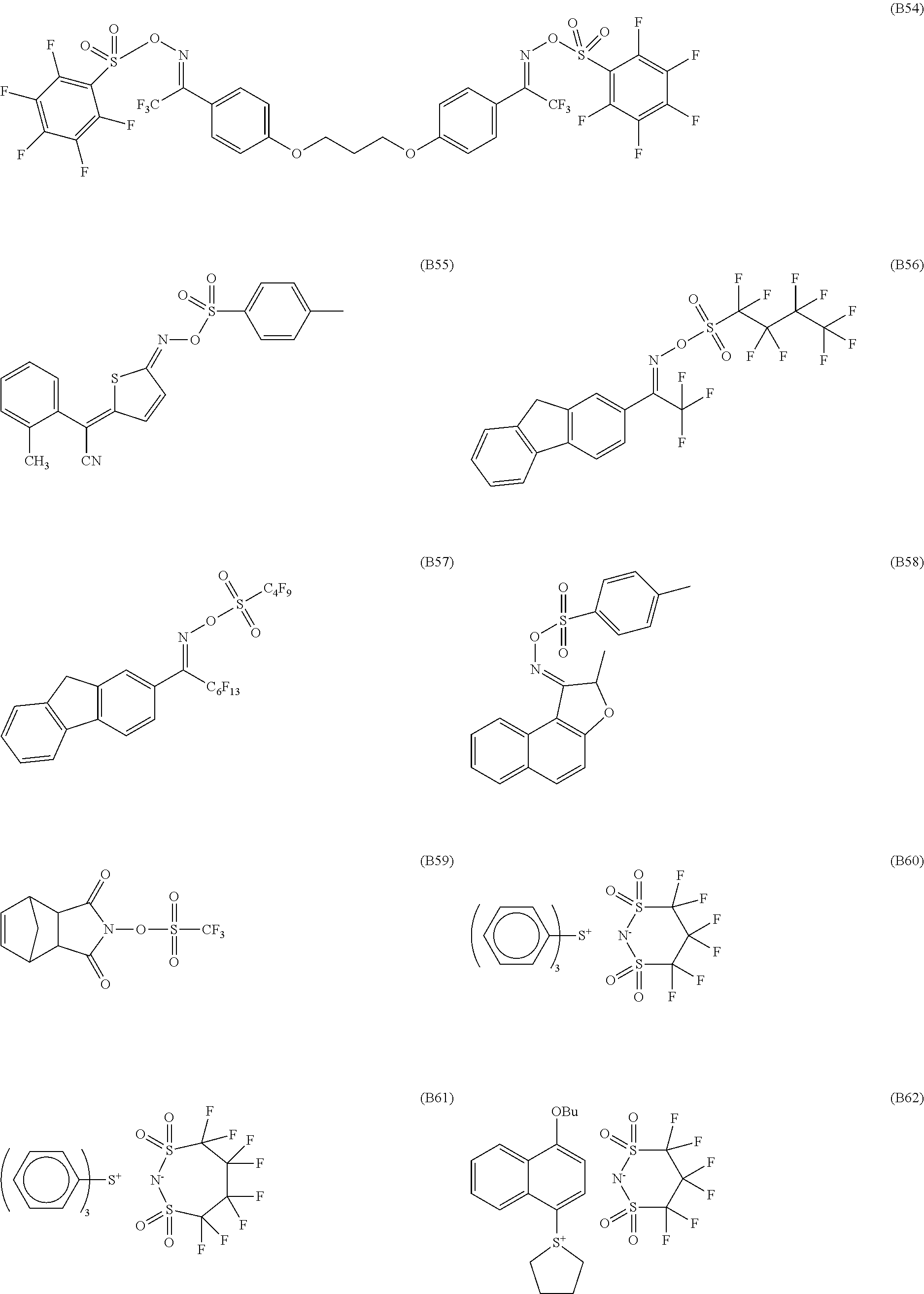

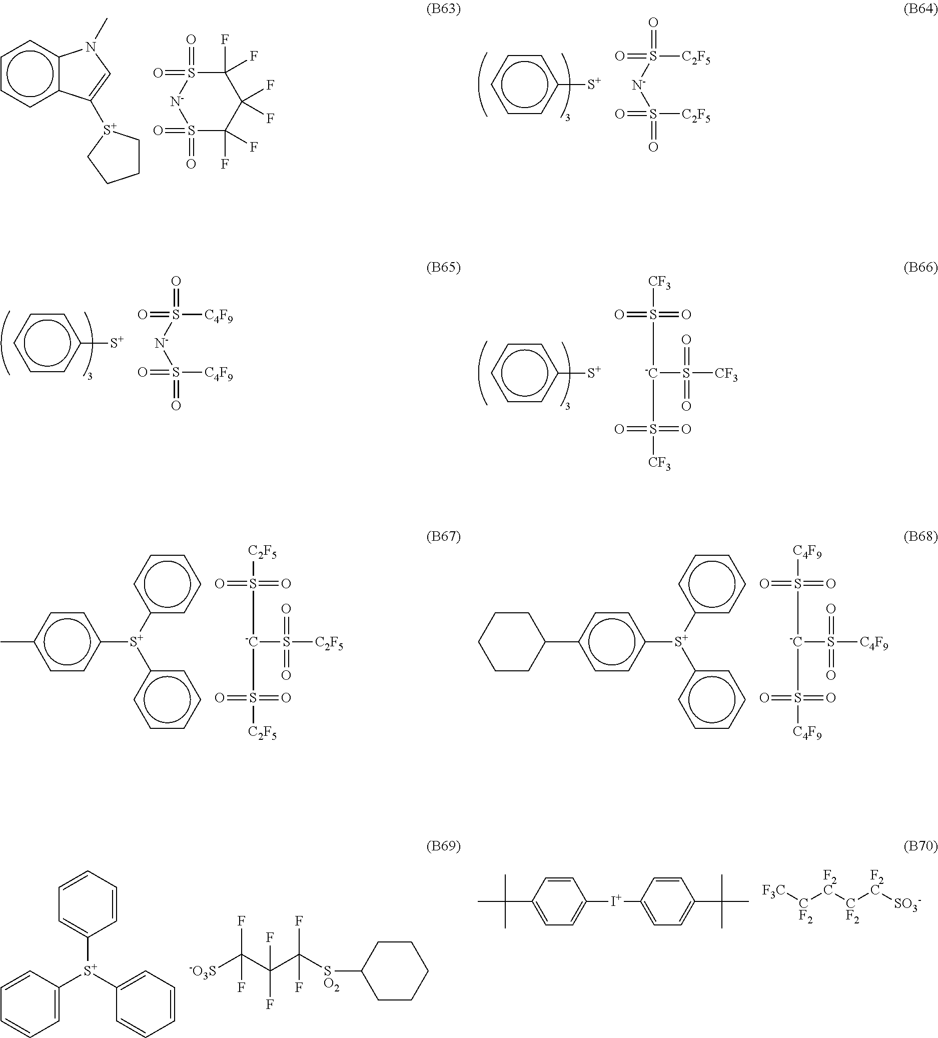

As the acid generator (B), one type of acid generator may be used alone or two or more types of acid generators may be used in combination. When using two or more types of acid generators in combination, it is preferable to combine compounds that generate two different types of organic acids which have a difference of 2 or more in the total number of atoms excluding hydrogen atoms.

For example, in terms of improving an acid generating efficiency and the acidic strength, there may be an aspect wherein a compound having a structure generating a fluorine atom-containing acid and a compound having no such structure are used together.

The content of the acid generator (B) in a composition is preferably 0.1 to 20% by mass, more preferably 0.5 to 15% by mass and still more preferably 1 to 10% by mass, based on the total solid content of an actinic ray-sensitive or radiation-sensitive resin composition.

[3] Solvent (C)

Examples of the solvent which can be used at the time of preparing the actinic ray-sensitive or radiation-sensitive resin composition for use in the present invention include an organic solvent such as alkylene glycol monoalkyl ether carboxylate, alkylene glycol monoalkyl ether, alkyl lactate ester, propionic acid alkyl alkoxy, cyclic lactone (preferably having 4 to 10 carbon atoms), a monoketone compound (preferably having 4 to 10 carbon atoms) which may have a ring, alkylene carbonate, alkyl alkoxyacetate and alkyl pyruvate.

Specific examples of these solvents may include those described in paragraphs [0441] to [0455] of U.S. Patent Application Publication No. 2008/0187860.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds exemplified above, but the solvent containing a hydroxyl group is preferably an alkylene glycol monoalkyl ether, an alkyl lactate or the like, more preferably propylene glycol monomethyl ether (PGME, another name: 1-methoxy-2-propanol) or an ethyl lactate. The solvent not containing a hydroxyl group is preferably an alkylene glycol monoalkyl ether acetate, an alkyl alkoxypropionate, a monoketone compound which may contain a ring, a cyclic lactone, an alkyl acetate or the like, still more preferably propylene glycol monomethyl ether acetate (PGMEA, another name: 1-methoxy-2-acetoxypropane), ethyl ethoxypropionate, 2-heptanone, γ-butyrolactone, cyclohexanone or butyl acetate, and most preferably propylene glycol monomethyl ether acetate, ethyl ethoxypropionate or 2-heptanone.

The mixing ratio (by mass) of the solvent containing a hydroxyl group to the solvent not containing a hydroxyl group is from 1/99 to 99/1, preferably from 10/90 to 90/10, and more preferably from 20/80 to 60/40. A mixed solvent in which the solvent not containing a hydroxyl group is contained in an amount of 50% by mass or more is particularly preferred in terms of coating uniformity.

The solvent preferably contains propylene glycol monomethyl ether acetate and is preferably a single containing propylene glycol monomethyl ether acetate solvent or a mixed solvent of two or more kinds of solvents containing propylene glycol monomethyl ether acetate.

[4] Compound (D) Having a Naphthalene Ring, Biphenyl Ring or an Anthracene Ring

The actinic ray-sensitive or radiation-sensitive resin composition according to the present invention may include a compound (D) having a naphthalene ring, a biphenyl ring or an anthracene ring.

The compound (D) having a naphthalene ring, biphenyl ring or an anthracene ring is different from a compound (B) capable of generating an acid upon irradiation with an actinic ray or radiation described hereinafter.

The molecular weight of the compound (D) having a naphthalene ring, a biphenyl ring or an anthracene ring is preferably 2,000 or less, more preferably 1,500 or less and still more preferably 900. Generally, the molecular weight is 100 or more.

The compound (D) having a naphthalene ring, a biphenyl ring, or an anthracene ring is preferably a compound represented any of Formulae (A1) to (A3) below.

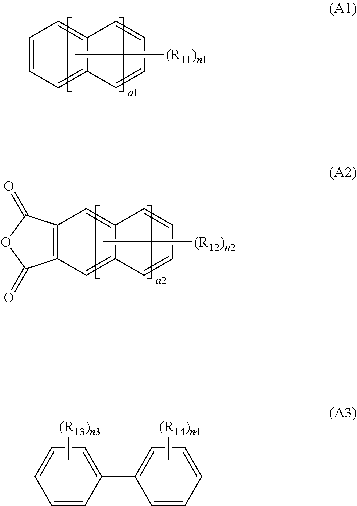

In Formulae (A1), (A2) and (A3), each of R₁₁ to R₁₄ independently represents a hydroxyl group, an alkyl group, an alkoxy group, an alkoxycarbonyl group, an alkyl carbonyl group or a lactonyloxycarbonyl group.

a1 represents 1 or 2.

n1 is an integer of from 0 to 10.

n2 is an integer of from 0 to 8.

n3 is an integer of from 0 to 5.

n4 is an integer of from 0 to 5.

In a case where n1 is an integer of 2 or more, R₁₁'s may be same or different and may be bonded to form a ring.

In a case where n2 is an integer of 2 or more, R₁₂'s may be same or different and may be bonded to form a ring.

In a case where n3 is an integer of 2 or more, R₁₃'s may be same or different and may be bonded to form a ring.

In a case where n4 is an integer of 2 or more, R₁₄'s may be same or different and may be bonded to form a ring.

The alkyl group of R₁₁ to R₁₄ is straight or branched, preferably has 1 to 10 carbon atoms and is preferably a methyl group, an ethyl group, an n-butyl group, a t-butyl group, and the like.

The alkyl group of R₁₁ to R₁₄ is straight or branched, preferably has 1 to 10 carbon atoms and is preferably a methoxy group, an ethoxy group, an n-propoxy group, an n-butoxy group, and the like.

The alkoxycarbonyl group of R₁₁ to R₁₄ is straight or branched, preferably has 2 to 11 carbon atoms and is preferably a methoxycarbonyl group, an ethoxycarbonyl group, an n-butoxycarbonyl group, and the like.

Specific examples of the alkyl group of the alkyl carbonyl group of R₁₁ to R₁₄ may include the same as those listed above for the alkyl group as R₁₁ to R₁₄.

The lactonyl group in the lactonyloxycarbonyl group of R₁₁ to R₁₄ is preferably a 5- to 7-membered ring lactonyl group and more preferably a 5 or 6-membered ring lactonyl group.

Each of a ring formed by a plurality of R₁₁'s bonded to each other, a ring formed by the combination of a plurality of R₁₂'s bonded to each other, a ring formed by a plurality of R₁₃'s bonded to each other, and a ring formed by a plurality of R₁₄'s bonded to each other is preferably a 5- or 6-membered ring.

Each group as R₁₁ to R₁₄, the ring formed by a plurality of R₁₁'s bonded to each other, the ring formed by a plurality of R₁₂'s bonded to each other, the ring formed by a plurality of R₁₃'s bonded to each other, and the ring formed by a plurality of R₁₄'s bonded to each other may further have a substitute, and examples of such substituent may include a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group include a straight, branched or cyclic alkoxy group having 1 to 20 carbon atoms, such as a methoxy group, an ethoxy group, an n-propoxy group, an i-propoxy group, an n-butoxy group, a 2-methypropoxy group, a 1-methylpropoxy group, a t-butoxy group, a cyclopentyloxy group and a cyclohexyloxy group.

Examples of the alkoxyalkyl group include a straight, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group and a 2-ethoxyethyl group.

Examples of the alkoxycarbonyl group include a straight, branched or cyclic alkoxycarbonyl group having 2 to 21 carbon atoms, such as a methoxycarbonyl group, ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the alkoxycarbonyloxy group include a straight, branched or cyclic alkoxycarbonyloxy group having 2 to 21 carbon atoms, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

n1 is preferably an integer of 0 to 5, more preferably an integer of 0 to 3, and preferably 0 or 1.

n2 is preferably an integer of 0 to 5, more preferably an integer of 0 to 3, and preferably 0 or 1.

n3 is more preferably an integer of 0 to 3, and preferably 0 or 1.

n4 is more preferably an integer of 0 to 3, and preferably 0 or 1.

The compound (D) having a naphthalene ring, a biphenyl ring or an anthracene ring may absorb the exposure light such as a KrF excimer laser and thus, it is possible to reduce an effect of standing waves caused by the reflection of light from a substrate or reduce the diffused reflection of light from a stepped portion of a stepped substrate, thereby forming a pattern with a high rectangularity.

According to the present invention, the content of the compound (D) having a naphthalene ring, a biphenyl ring or an anthracene ring is preferably 0.1 to 6.0% by mass, more preferably 0.5 to 5.0% by mass, and still more preferably 1.0 to 4.5% by mass, based on the total solid content in the actinic ray-sensitive or radiation-sensitive resin composition.

If the compound (D) having a naphthalene ring, a biphenyl ring or an anthracene ring is contained in an excessive amount, the transmissivity to exposure light by a KrF excimer laser or the like may be reduced, thereby deteriorating the pattern shape.

The compound (D) having a naphthalene ring, a biphenyl ring or an anthracene ring is commercially available or may be obtained by synthesis acceding to a conventional method.

Specific examples of the compound (D) having a naphthalene ring, a biphenyl ring or an anthracene ring are illustrated below, but the present invention is not limited thereto.

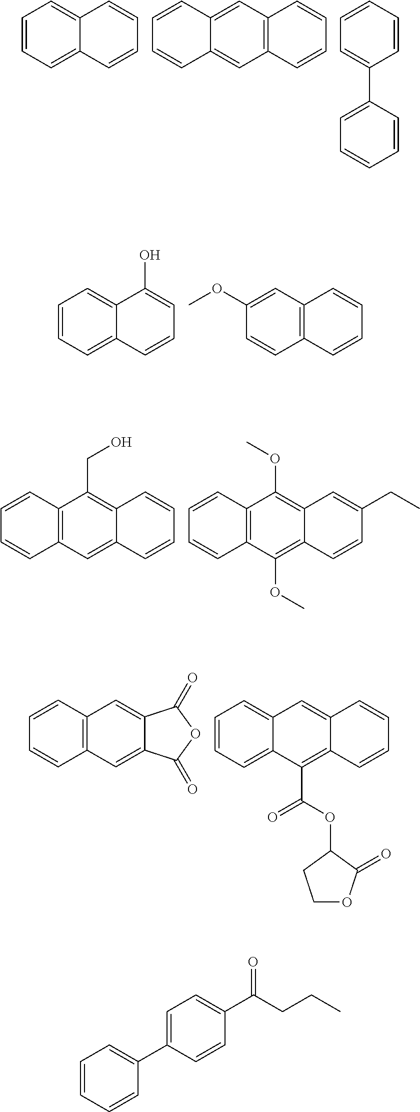

[5] Basic Compound (E)

The actinic ray-sensitive or radiation-sensitive resin composition according to the present invention may include a basic compound (D) to reduce a change in performance over time from exposure to heating.

The basic compound preferably includes a compound having a structure represented by Formula (A) to (E).

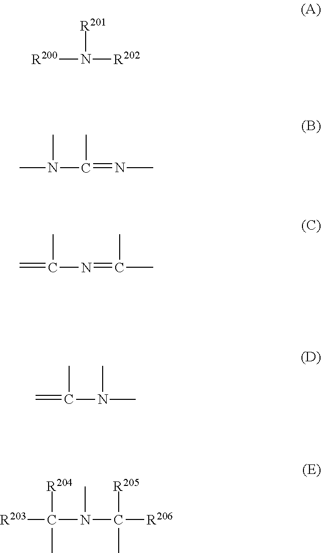

In Formulae (A) and (E), each of R²⁰⁰, R²⁰¹ and R²⁰² may be same or different and represents a hydrogen atom, an alkyl group (preferably having 1 to 20 carbon atoms), a cycloalkyl group (preferably having 3 to 20 carbon atoms) or an aryl group (having 6 to 20 carbon atoms), and R²⁰¹ and R²⁰² may be bonded to each other to form a ring. Each of R²⁰³, R²⁰⁴, R²⁰⁵ and R²⁰⁶, which may be same or different, represents an alkyl group having 1 to 20 carbon atoms.

As for the alkyl group, the alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in formulae (A) to (E) is more preferably unsubstituted.

Preferred examples of the compound may include guanidine, aminopyrrolidine, pyrazole, pyrazoline, piperazine, aminomorpholine, aminoalkylmorpholine and piperidine. More preferred examples of the compound may include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure may include imidazole, 2,4,5-triphenylimidazole and benzimidazole. Examples of the compound having a diazabicyclo structure include 1,4-diazabicyclo[2,2,2]octane, 1,5-diazabicyclo[4,3,0]nona-5-ene and 1,8-diazabicyclo[5,4,0]undeca-7-ene. Examples of the compound having an onium hydroxide structure may include triarylsulfonium hydroxide, phenacylsulfonium hydroxide and sulfonium hydroxide having a 2-oxoalkyl group, and specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound in which the anion moiety of the compound having an onium hydroxide structure becomes carboxylate, and examples thereof may include acetate, adamantane-1-carboxylate and perfluoroalkyl carboxylate. Examples of the compound having a trialkylamine structure may include tri(n-butyl)amine and tri(n-octyl)amine. Examples of the compound having an aniline structure may include 2,6-diisopropylaniline, N,N-dimethylaniline, N,N-dibutylaniline and N,N-dihexylaniline. Examples of the alkylamine derivative having a hydroxyl group and/or an ether bond include ethanolamine, diethanolamine, triethanolamine and tris(methoxyethoxyethyl)amine. Examples of the aniline derivative having a hydroxyl group and/or an ether bond include N,N-bis(hydroxyethyl)aniline

Preferred basic compounds include a phenoxy group-containing amine compound, a phenoxy group-containing ammonium salt compound, a sulfonate ester group-containing amine compound and a sulfonate ester group-containing ammonium salt compound.

In the phenoxy group-containing amine compound, phenoxy group-containing ammonium salt compound, sulfonate ester group-containing amine compound and sulfonate ester group-containing ammonium salt compound, at least one alkyl group is preferably bonded to the nitrogen atom. Further, the alkyl chain preferably contains an oxygen atom to form an oxyalkylene group. The number of oxyalkylene groups in the molecule is 1 or more, preferably from 3 to 9, more preferably from 4 to 6. Among oxyalkylene groups, those having a structure of —CH₂CH₂O—, —CH(CH₃)CH₂O— or —CH₂CH₂CH₂O— are preferred.

Specific examples of the phenoxy group-containing amine compound, phenoxy group-containing ammonium salt compound, sulfonate ester group-containing amine compound and sulfonate ester group-containing ammonium salt compound may include, but are not limited to, Compounds (C1-1) to (C3-3) illustrated in paragraph [0066] of U.S. Patent Application Publication No. 2007/0224539.

The actinic ray-sensitive or radiation-sensitive resin composition for use in the present invention may or may not contain a basic compound, but in the case of containing a basic compound, the amount used thereof is usually from 0.001 to 10% by mass and preferably from 0.01 to 5% by mass based on the solid content of the actinic ray-sensitive or radiation-sensitive resin composition.

The ratio of the acid generator to the basic compound in the composition is preferably the acid generator/basic compound (molar ratio)=2.5 to 300. That is, the molar ratio is preferably 2.5 or more in terms of sensitivity and resolution, and preferably 300 or less in terms of suppressing the reduction in resolution due to thickening of the resist pattern over time after exposure until heat treatment. The acid generator/basic compound (molar ratio) is more preferably from 5.0 to 200 and still more preferably from 7.0 to 150.

[6] Surfactant (F)

The actinic ray-sensitive or radiation-sensitive resin composition according to the present invention may or may not further contain a surfactant, but in the case of containing a surfactant, it is preferred to contain any one of fluorine-containing and/or silicon-containing surfactants (a fluorine-containing surfactant, a silicon-containing surfactant and a surfactant containing both of a fluorine atom and a silicon atom), or two or more thereof.

By containing the surfactant, the actinic ray-sensitive or radiation-sensitive resin composition according to the present invention can give a resist pattern that is improved in the sensitivity, resolution and adherence and reduced in the development defect when using an exposure light source with a wavelength of 250 nm or less, particularly 220 nm or less.

Examples of the fluorine-containing and/or silicon-containing surfactants include surfactants described in paragraph [0276] of U.S. Patent Application Publication No. 2008/0248425, such as EFtop EF301 and EF303 (manufactured by Shin-Akita Kasei K.K.); Florad FC430, 431 and 4430 (manufactured by Sumitomo 3M Inc.); Megaface F171, F173, F176, F189, F113, F110, F177, F120 and R08 (manufactured by DIC Corporation); Surflon S-382, SC101, 102, 103, 104, 105 and 106 and KH-20 (manufactured by Asahi Glass Co., Ltd.); Troysol S-366 (manufactured by Troy Chemical); GF-300 and GF-150 (manufactured by Toa Gosei Chemical Industry Co., Ltd.); Surflon S-393 (manufactured by Seimi Chemical Co., Ltd.); EFtop EF121, EF122A, EF122B, RF122C, EF125M, EF135M, EF351, EF352, EF801, EF802 and EF601 (manufactured by JEMCO Inc.); PF636, PF656, PF6320 and PF6520 (manufactured by OMNOVA); and FTX-204G, 208G, 218G, 230G, 204D, 208D, 212D, 218D and 222D (manufactured by NEOS Co., Ltd.). In addition, polysiloxane polymer KP-341 (manufactured by Shin-Etsu Chemical Co., Ltd.) may be also used as a silicon-containing surfactant.

In addition to the known surfactants as listed above, a surfactant using a polymer having a fluoro-aliphatic group derived from a fluoro-aliphatic compound which is manufactured by a telomerization process (also called a telomer process) or an oligomerization process (also called an oligomer process) may also be used. The fluoro-aliphatic compound can be synthesized by the method described in Japanese Patent Application Laid-Open No. 2002-90991.

Examples of the surfactant described above include Megaface F 178, F-470, F-473, F-475, F-476 and F-472 (manufactured by DIC Corporation); a copolymer of a C₆F₁₃ group-containing acrylate (or methacrylate) with a (poly(oxyalkylene)) acrylate (or methacrylate); and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactant, described in paragraph [0280] of U.S. Patent Application Publication No. 2008/0248425, may also be used.

One of these surfactants may be used either alone or in combination of two or more thereof.

Although the actinic ray-sensitive or radiation-sensitive resin composition according to the present invention may or may not contain a surfactant, in case of containing a surfactant, the amount of the surfactant used is preferably from 0.0001 to 2% by mass and more preferably from 0.0005 to 1% by mass based on the total content of the actinic ray-sensitive or radiation-sensitive resin composition (excluding the solvent).

[7] Other Additives (G)

The actinic ray-sensitive or radiation-sensitive resin composition according to the present invention may or may not contain an onium carboxylate. Examples of the onium carboxylate include those described in paragraphs [0605] to [0606] of U.S. Patent Application Publication No. 2008/0187860.

Such an onium carboxylate can be synthesized by reacting a sulfonium hydroxide, iodonium hydroxide, ammonium hydroxide and a carboxylic acid with silver oxide in an appropriate solvent.

In the case where the actinic ray-sensitive or radiation-sensitive resin composition contains an onium carboxylate, the content thereof is generally from 0.1 to 20% by mass, preferably from 0.5 to 10% by mass and more preferably from 1 to 7% by mass based on the total solid content of the composition.

The actinic ray-sensitive or radiation-sensitive resin composition according to the present invention may further contain, for example, a dye, a plasticizer, a photosensitizer, a light absorber, an alkali-soluble resin, a dissolution inhibitor, and a compound for accelerating dissolution in a developer (for example, a phenol compound having a molecular weight of 1,000 or less, or a carboxyl group-containing alicyclic or aliphatic compound), if desired.

The phenol compound having a molecular weight of 1,000 or less can be easily synthesized by one skilled in the art with reference to the method described, for example, in Japanese Patent Application Laid-Open No. Hei 4-122938, Japanese Patent Application Laid-Open No. Hei 2-28531, U.S. Pat. No. 4,916,210 or European Patent 219294.

Specific examples of the carboxyl group-containing alicyclic or aliphatic compound may include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid and a cyclohexanedicarboxylic acid.

In terms of enhancing the resolution, the actinic ray-sensitive or radiation-sensitive resin composition according to the present invention is preferably used in a film thickness of 30 to 250 nm and more preferably from 30 to 200 μm. Such a film thickness can be obtained by setting the solid content concentration in the composition to an appropriate range, thereby imparting an appropriate viscosity and enhancing the coatability and film-forming property.

The total solid content concentration in the actinic ray-sensitive or radiation-sensitive resin composition according to the present invention is usually from 1.0 to 15% by mass, preferably from 2.5 to 13% by mass and more preferably from 3.0 to 12% by mass. By setting the solid content concentration to the range above, the resist solution can be uniformly applied on a substrate to thereby provide a resist pattern having high resolution, rectangular profile and good etching resistance. The reason therefor is not clearly known, but it is considered that thanks to a solid content concentration of 10% by mass or less, preferably 5.7% by mass or less, aggregation of materials, particularly, a photoacid generator, in the resist solution is suppressed, and thus a uniform resist film can be formed.

The solid content concentration is a weight percentage of the weight of the other resist components than the solvent based on the total weight of the actinic ray-sensitive or radiation-sensitive resin composition.

The actinic ray-sensitive or radiation-sensitive resin composition according to the present invention is used by dissolving the components above in a predetermined organic solvent, preferably in the above-described mixed solvent, filtering the solution, and applying it on a predetermined support (substrate). The filter used for filtration is preferably a polytetrafluoroethylene-, polyethylene- or nylon-made filter having a pore size of 0.1 μm or less, more preferably 0.05 μm or less and still more preferably 0.03 μm or less. In the filtration through a filter, as described, for example, in Japanese Patent Application Laid-Open No. 2002-62667, circulating filtration may be performed, or the filtration may be performed by connecting a plurality of kinds of filters in series or in parallel. Also, the composition may be filtered a plurality of times. Furthermore, a deaeration treatment or the like may be applied to the composition before or after filtration through a filter.

<Pattern Forming Method>

In the following, a pattern forming method according to the present invention will be described.

The pattern forming method according to the present invention (negative pattern forming method) includes at least:

(a) a step of forming a film (resist film) including an actinic ray-sensitive or radiation-sensitive resin composition according to the present invention.

(b) a step of exposing the film, and

(c) a step of developing the exposed film in an organic solvent-containing developer to form negative patterns.

The exposure in the step (b) may be immersion exposure.

The pattern forming method of the present invention preferably includes (d) a heating step after the exposure step (b).

The pattern forming method of the present invention may further include (e) a step of developing the film by using an alkali developer.

In the pattern forming method of the present invention, the exposure step (b) may be performed a plurality of times.

In the pattern forming method of the present invention, the heating step (d) may be performed a plurality of times.

The resist film is formed from the above-described actinic ray-sensitive or radiation-sensitive resin composition according to the present invention and, more specifically, it is preferably formed by applying the actinic ray-sensitive or radiation-sensitive resin composition on a substrate material. In the pattern forming method according to the present invention, the step of forming a film by an actinic ray-sensitive or radiation-sensitive resin composition on a substrate, the step of exposing the film, and the developing step can be performed by generally known methods.

It is also preferred to contain, after film formation, a pre-baking step (PB) before entering the exposure step.

Furthermore, it is also preferred to contain a post-exposure baking step (PEB) after the exposure step but before the development step.

As for the heating temperature, both PB and PEB are preferably performed at 70 to 130° C. and more preferably at 80 to 120° C.

The heating time is preferably from 30 to 300 seconds, more preferably from 30 to 180 seconds and still more preferably from 30 to 90 seconds.

The heating can be performed using a device attached to an ordinary exposure/developing machine or may be performed using a hot plate or the like.

The reaction in the exposed area is accelerated by the baking, and the sensitivity and pattern profile are improved.

The light source wavelength of the exposure apparatus for use in the present invention includes KrF excimer laser (248 nm), EUV (13 nm) and electron beam. Preferably. KrF excimer laser is used.

Immersion lithography may also be used in the lithography process for the present invention.

The immersion lithography may be bonded to the super-resolution technology, such as phase shift method and modified illumination method.

In the present invention, the substrate on which the film is formed is not particularly limited, and an inorganic substrate such as silicon, SiN, SiO₂ and SiN, a coating-type inorganic substrate such as SOG, or a substrate generally used in the manufacturing of a semiconductor such as IC, manufacturing of a circuit board of a liquid crystal device or a thermal head and also in the lithography of photo-fabrication processes can be used. If desired, an organic antireflection coating may be applied between the resist film and the substrate. As an antireflection coating, a well-known organic or inorganic-based antireflection film may be appropriately used.

A stepped substrate is a substrate on which at least one stepped portion is formed.

The film thickness of layered films formed on the stepped substrate above means a height from the bottom of the stepped substrate to the top of the resist formed thereon.

The height from the bottom of the stepped substrate to the top of the resist film formed thereon is preferably less than the film thickness of the resist film, for example, less than 200 nm.

For example, when micro-machined for use in ion implantation, a stepped substrate formed by patterning pins or gates on a flat substrate may be used. On such stepped substrate having pins or gates patterned thereon, the actinic ray-sensitive or radiation sensitive resin composition is applied. The film thickness of the resist film formed on the substrate is not a height from the top of the pin or gate to the top of the resist film, but a height from the bottom of the stepped substrate to the top of the resist film formed thereon.

The size of the fin and gate (width, length, height, etc.), spacing, structures, configurations and the like may be appropriately applied, for example, with reference to Journal of IEICE. 91, No. 1, 2008, pp. 25-29, “Advanced FinFET Process Integration Technology” and, Jpn. J. Appl. Phys., Vol. 42 (2003), pp. 4142-4146, Part 1, No. 6B, June 2003 “Fin-Type Double-Gate Metal-Oxide-Semiconductor Field-Effect Transistors Fabricated by Orientation-Dependent Etching and Electron Beam Lithography.”

If the pattern forming method according to the present invention further includes a step of developing using an alkali developer, it is generally preferable to use an aqueous solution of 2.38% by mass tetramethyl-amonium-hydroxide, although not being limited to an available alkali developer. Also, an alkaline solution may be used by adding an alcohol or a surfactant in an appropriate amount.

The alkali concentration of the alkali developer is usually from 0.1 to 20% by mass.

The pH of the alkali developer is usually from 10.0 to 15.0.

As for the rinse liquid in the rinse processing performed after the alkali development, pure water is used, and the pure water may be also used after adding thereto an appropriate amount of a surfactant.

After the development processing or rinse processing, a processing of removing the developer or rinse liquid adhering on the pattern by a supercritical fluid may be performed.

As the developer in the step of performing development using an organic solvent-containing developer in the pattern forming method according to the present invention (hereinafter, referred to as an “organic developer”), a polar solvent such as a ketone-based solvent, an ester-based solvent, an alcohol-based solvent, an amide-based solvent and an ether-based solvent, or a hydrocarbon-based solvent can be used.

Examples of the ketone-based solvent include 1-octanone, 2-octanone, 1-nonanone, 2-nonanone, acetone, 2-heptanone(methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate and propyl lactate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol.

Examples of the ether-based solvent include, in addition to the glycol ether-based solvents above, dioxane and tetrahydrofuran.

Examples of the amide-based solvent which can be used include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include an aromatic hydrocarbon-based solvent such as toluene and xylene, and an aliphatic hydrocarbon-based solvent such as pentane, hexane, octane and decane.

A plurality of these solvents may be mixed, or the solvent may be used by mixing it with a solvent other than those described above or with water. However, in order to sufficiently bring out the effects of the present invention, the water content ratio of the total developer is preferably less than 10% by mass, and it is more preferred to contain substantially no water.

That is, the amount of the organic solvent used in the organic developer is preferably from 90 to 100% by mass, more preferably from 95 to 100% by mass, based on the total amount of the developer.

In particular, the organic developer is preferably a developer containing at least one kind of an organic solvent selected from a ketone-based solvent, an ester-based solvent, an alcohol-based solvent, an amide-based solvent and an ether-based solvent.

The vapor pressure of the organic developer, at 20° C., is preferably 5 kPa or less, more preferably 3 kPa or less and still more preferably 2 kPa or less. By setting the vapor pressure of the organic developer to 5 kPa or less, evaporation of the developer on a substrate or in a development cup is suppressed and the temperature uniformity in the wafer plane is enhanced. As a result, the dimensional uniformity in the wafer plane is improved.

If necessary, a surfactant may be added in an appropriate amount to the organic developer.

As a surfactant, although not specifically limited, ionic or non-ionic fluorine-based and/or silicon-based surfactants may be used. Examples of these fluorine-based and/or silicon-based surfactants may include the surfactants disclosed in Japanese Patent Application Laid-Open Nos. Sho 62-36663, Sho 61-226746, Sho 61-226745, Sho 62-17095, Sho 63-34540, Hei 7-230165, Hei 8-62834, Hei 9-54432 and Hei 9-5988, U.S. Pat. Nos. 5,405,720, 5,360,692, 5,529,881, 5,296,330, 5,436,098, 5,576,143, 5,294,511 and 5,824,451 and preferably include non-ionic surfactants. As a non-ionic surfactant, although not specifically limited, a fluorine-based surfactant or a silicon-based surfactant is preferably used.

The amount of a surfactant used is generally 0.001 to 5% by mass, preferably 0.005 to 2% by mass, and more preferably 0.01 to 0.5% by mass based on the total content of the developer.

As a developing method, for example, a method of dipping a substrate in a bath filled with a developer for a predetermined time (a dipping method), a method of raising a developer on a substrate surface sufficiently by the effect of a surface tension and keeping the substrate still for a predetermined time, thereby performing development (a puddle method), a method of spraying a developer on a substrate surface (a spray method), a method of continuously ejecting a developer on a substrate spinning at a constant speed while scanning a developer ejecting nozzle at a constant rate (a dynamic dispense method) and the like.

When the above-described various developing methods include a process of ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and even more preferably 1 mL/sec/mm² or less. The flow velocity has no particular lower limit, but is preferably 0.2 mL/sec/mm² or more in consideration of throughput.

By setting the ejection pressure of the ejected developer to the aforementioned range, pattern defects resulting from the resist scum after development may be significantly reduced.

Details on the mechanism are not clear, but it is thought that it is because the pressure imposed on the resist film by the developer is decreased by setting the ejection pressure to the above-described range, so that the resist film resist pattern is suppressed from being inadvertently cut or collapsing.

Meanwhile, the ejection pressure (mL/sec/mm²) of the developer is the value at the outlet of the development nozzle in the developing apparatus.

Examples of the method for adjusting the ejection pressure of the developer include a method of adjusting the ejection pressure by a pump or the like, a method of supplying a developer from a pressurized tank and adjusting the pressure to change the ejection pressure and the like.

In addition, after the process of performing development using an organic solvent-containing developer, a process of stopping the development while replacing the solvent with another solvent may be performed.

It is preferred that a process of rinsing the resist using a rinse liquid is included after the process of performing development using an organic solvent-containing developer.

The rinse liquid used in the rinsing process after the process of performing development using an organic solvent-containing developer is not particularly limited as long as the rinse liquid does not dissolve the resist pattern, and a solution including a general organic solvent may be used. As for the rinse liquid, a rinse liquid containing at least one of the organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those listed for the organic solvent-containing developer.

After the process of performing development using an organic solvent-containing developer, a process of performing rinsing using a rinse liquid containing at least one of organic solvents selected from the group consisting of a ketone-based solvent, an ester-based solvent, an alcohol-based solvent and an amide-based solvent is more preferably performed, a process of performing rinsing using a rinse liquid containing an alcohol-based solvent or an ester-based solvent is even more preferably performed, a process of performing rinsing using a rinse liquid containing a monohydric alcohol is particularly preferably performed, and a process of performing rinsing using a rinse liquid containing a monohydric alcohol having 5 or more carbon atoms is most preferably performed.

Here, examples of the monohydric alcohol used in the rinsing process may include a straight, branched or cyclic monohydric alcohol, and specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like, and as the particularly preferred monohydric alcohol having 5 or more carbon atoms, it is possible to use 1-hexanol, 2-hexanol, 4-methyl-2-pentanol, 1-pentanol, 3-methyl-1-butanol and the like.

A plurality of the components may be mixed, or the components may be used by being mixed with an organic solvent other than those described above.

The water content ratio in the rinse liquid is preferably 10% by mass or less, more preferably 5% by mass or less, and particularly preferably 3% by mass or less. By setting the water content ratio to 10% by mass or less, good development characteristics may be obtained.

The vapor pressure of the rinse liquid used after the process of performing development using an organic solvent-containing developer is preferably 0.05 kPa to 5 kPa, more preferably 0.1 kPa to 5 kPa, and most preferably 0.12 kPa to 3 kPa, at 20° C. By setting the vapor pressure of the rinse liquid to 0.05 kPa to 5 kPa, the temperature uniformity in the wafer plane is enhanced, and furthermore, swelling caused by permeation of the rinse liquid is suppressed, and as a result, the dimensional uniformity in the wafer plane is improved.

The rinse liquid may also be used by adding an appropriate amount of a surfactant thereto.

In the rinsing process, the wafer subjected to development using an organic solvent-containing developer is rinsed by using the aforementioned rinse liquid including an organic solvent. The method of rinse processing is not particularly limited, but it is possible to apply, for example, a method of continuously ejecting a rinse liquid on a substrate spinning at a constant speed (spin coating method), a method of dipping a substrate in a bath filled with a rinse liquid for a predetermined time (dipping method), a method of spraying a rinse liquid on a substrate surface (spraying method), and the like, and among them, it is preferred that the rinse processing is performed by the spin coating method and after the rinsing, the substrate is spun at a rotational speed of 2,000 rpm to 4,000 rpm to remove the rinse liquid from the substrate. Furthermore, it is also preferred that a heating process (post bake) is included after the rinsing process. The developer and the rinse liquid remaining between patterns and the inside of the pattern are removed by the bake. The heating process after the rinsing process is performed at usually 40 to 160° C., and preferably 70 to 95° C., for usually 10 seconds to 3 minutes, and preferably 30 to 90 seconds.

The developer and/or rinse liquid used in the present invention (hereinafter, collectively and simply referred to as a “chemical liquid”) preferably contains various particles, metallic atoms and the like in a small amount. In order to obtain a chemical liquid having a small amount of such impurities, the liquid is preferably prepared in clean room and filtered off by using an ion exchange filter or subject to metallic atom reduction. For metallic atoms, the concentration of the metallic atoms Na, K, Ca, Fe, Cu, Mg, Mn, Li, Al, Cr, Ni and Zn is preferably 10 ppm or less and more preferably 5 ppm or less.

Also, as a storage vessel for the chemical liquid, although not specifically limited, a vessel, such as a polyethylene resin, a polypropylene resin, a polyethylene-polypropylene resin and the like may be used. However, in order to reduce the amount of impurities eluted from the vessel, a vessel that has a small amount of components eluted as a chemical liquid from its inner wall may preferably be selected. Such a vessel includes a vessel whose inner wall is a perfluoro resin [e.g., Fluoro Pure PFA composite drum prepared by Entegris (inner wall in contact with the liquid: PFA resin lining) and a steel drum can prepared by JFE (inner wall in contact with the liquid: zinc phosphate coating).

Further, the present invention relates to a method for manufacturing an electronic device, including the pattern forming method according to the present invention above, and an electronic device manufactured according to the same method.

The electronic device according to the present invention is appropriately installed in electric and electronic devices (consumer appliances, OA/media-related devices, optical systems, communications devices etc.).

### EXAMPLES

Hereinafter, the present invention will be described by way of examples, but is not limited thereto. Hereinafter, repeating units in the resin used in the examples will be illustrated.

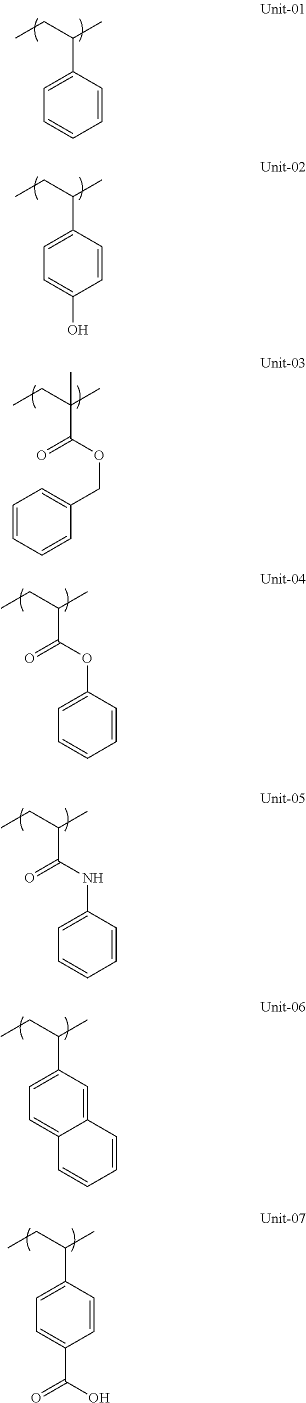

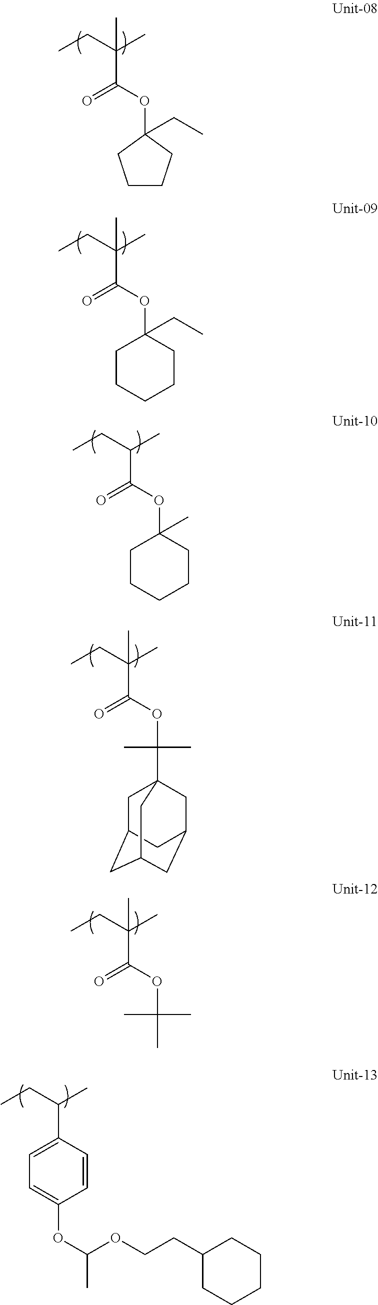

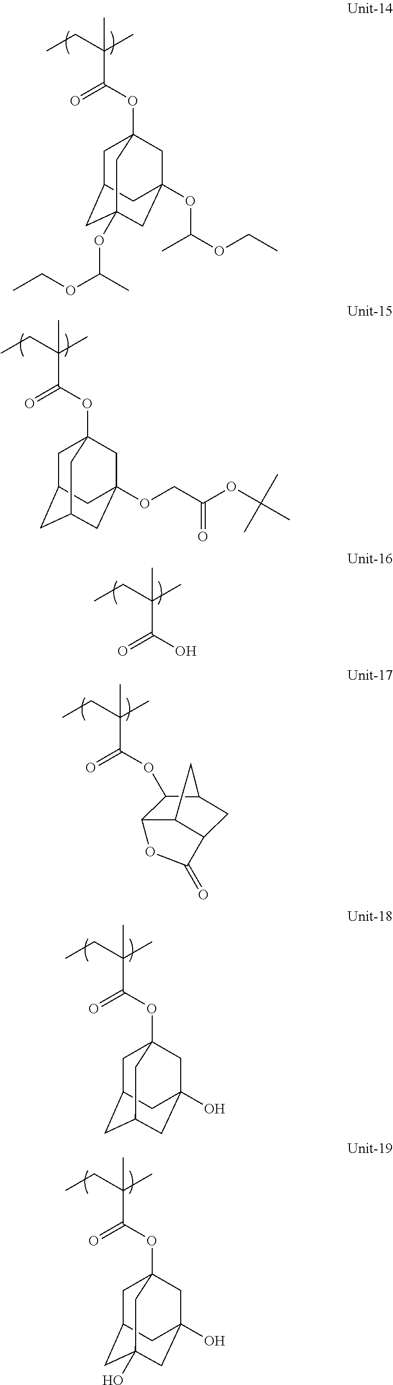

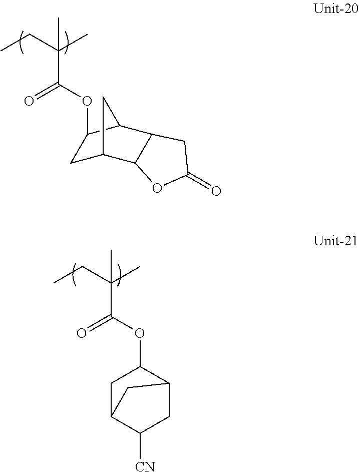

### Synthesis Example 1

### Synthesis of Resin (Pol-01)

Under a nitrogen atmosphere, 90.2 g of cyclohexanone was put in a three-necked flask and then was heated to 75° C. Then, a monomer (54.2 g) corresponding to the Unit-01 above, a monomer (92.4 g) corresponding to the Unit-12 above and a monomer (28.9 g) corresponding to the Unit-17 above were dissolved in cyclohexanon (361 g) to prepare a monomer solution. Also, a polymerization initiator V-601 (manufactured by Waco Chemical & Supply Co.) was added in an amount of 5.99 g (2 mol % based on the total amount of the monomers), and the dissolved solution was dropped over 4 hours into the flask. After the dropping was completed, the solution was reacted for 2 hours at 75° C. The reaction solution was allowed to be cooled and then dropped into a mixed solvent of 7,408 g of heptane/82 3 g of ethyl acetate, and the precipitated powder was collected by filtration and dried to obtain 109 g of resin (Pol-01). The weight average molecular amount of the resulting resin (Pol-01) was 30,000 in terms of standard polystyrene, the dispersity (Mw/Mn) was 1.7, and the composition ratio measured by ¹³C-NMR was 40/50/10.

The same operations as in Synthesis Example 1 were performed and the resins (Pol-02) to (Pol-10) were synthesized.

Table 1 below shows the repeating units, the composition ratio (molar ratio), the weight average molecular weight (Mw), and the dispersity with respect to the resins (Pol-01) to (Pol-10). The composition ratio corresponds to each repeating unit sequentially from left. Also, the composition ratio (molar ratio), weight average molecular weight (Mw), and dispersity of each repeating unit were calculated in the same method as the resin (Pol-01).

TABLE 1

| | Repeating | Composition | Repeating | Composition | Repeating | Composition | Repeating | Composition | | |
|---|---|---|---|---|---|---|---|---|---|---|
| Resin | Unit 1 | Ratio | Unit 2 | Ratio | Unit 3 | Ratio | Unit 4 | Ratio | Mw | Dispersity |
| Pol-01 | Unit-01 | 40 | Unit-12 | 50 | Unit-17 | 10 | — | — | 30000 | 1.7 |
| Pol-02 | Unit-03 | 40 | Unit-08 | 40 | Unit-16 | 20 | — | — | 10000 | 1.6 |
| Pol-03 | Unit-06 | 20 | Unit-14 | 80 | — | — | — | — | 12000 | 1.6 |
| Pol-04 | Unit-06 | 10 | Unit-07 | 10 | Unit-09 | 60 | Unit-18 | 20 | 21000 | 1.7 |
| Pol-05 | Unit-04 | 10 | Unit-10 | 50 | Unit-20 | 40 | — | — | 16000 | 1.6 |
| Pol-06 | Unit-03 | 30 | Unit-15 | 60 | Unit-16 | 10 | — | — | 20000 | 1.7 |
| Pol-07 | Unit-02 | 45 | Unit-11 | 35 | Unit-19 | 20 | — | — | 15000 | 1.6 |
| Pol-08 | Unit-06 | 10 | Unit-12 | 60 | Unit-21 | 30 | — | — | 21000 | 1.6 |
| Pol-09 | Unit-01 | 40 | Unit-13 | 40 | Unit-16 | 20 | — | — | 11000 | 1.6 |
| Pol-10 | Unit-01 | 65 | Unit-13 | 35 | — | — | — | — | 20000 | 1.7 |

### Examples 1-9 and Comparative Example 1

### Preparation of Actinic Ray-Sensitive or Radiation-Sensitive Resin Composition

The components shown in Table 2 below were dissolved in a solvent to prepare respective resist solutions, and each resist solution was filtered off through a polyethylene filter having a pore size of 0.03 μm to prepare an actinic ray-sensitive or radiation-sensitive resin composition (resist composition) containing a solid concentration of 6.0% by mass.

TABLE 2

| | | | Acid | Acid | Basic | | Compound | |
|---|---|---|---|---|---|---|---|---|
| Resist | Resin-A | Resin-B | Generator-A | Generator-B | Compound | Surfactant | (D) | Solvent |
| Composition | Conc. in Solid* | Conc. in Solid | Conc. in Solid | Conc. in Solid | Conc. in Solid | Conc. in Solid | Conc. in Solid | Molar Ratio |
| Res-1 | Pol-01 | — | PAG-1 | — | N-1 | W-6 | — | SL-1/SL-2 |
| | 92.1% by mass | | 6.8% by mass | | 0.8% by mass | 0.3% by mass | | 90/10 |
| Res-2 | Pol-02 | — | PAG-8 | — | N-2 | W-6 | Ad-2 | SL-1/SL-5 |
| | 90.6% by mass | | 6.2% by mass | | 0.9% by mass | 0.3% by mass | 2.0% by mass | 70/30 |
| Res-3 | Pol-03 | Po1-01 | PAG-5 | PAG-4 | N-3 | W-3 | Ad-1 | SL-1 |
| | 71.9% by mass | 18.0% by mass | 3.2% by mass | 3.3% by mass | 1.3% by mass | 0.3% by mass | 2.0% by mass | 100 |
| Res-4 | Pol-04 | — | PAG-6 | — | N-1 | W-4 | — | SL-1/SL-4 |
| | 92.0% by mass | | 6.9% by mass | | 0.8% by mass | 0.3% by mass | | 80/20 |
| Res-5 | Pol-05 | — | PAG-3 | — | N-2 | W-5 | Ad-2 | SL-1/SL-6 |
| | 90.2% by mass | | 6.6% by mass | | 0.9% by mass | 0.3% by mass | 2.0% by mass | 95/5 |
| Res-6 | Pol-06 | — | PAG-2 | PAG-7 | N-4 | W-6 | — | SL-1/SL-3 |
| | 92.1% by mass | | 3.8% by mass | 2.8% by mass | 1.0% by mass | 0.3% by mass | | 95/5 |
| Res-7 | Pol-07 | — | PAG-2 | — | N-3 | W-1 | Ad-2 | SL-1/SL-7 |
| | 88.3% by mass | | 7.6% by mass | | 1.3% by mass | 0.3% by mass | 2.5% by mass | 98/2 |
| Res-8 | Pol-08 | — | PAG-1 | — | N-2 | W-2 | — | SL-1/SL-4 |
| | 92.0% by mass | | 6.8% by mass | | 0.9% by mass | 0.3% by mass | | 90/10 |
| Res-9 | Pol-09 | — | PAG-6 | — | N-1 | W-6 | — | SL-1/SL-5 |
| | 92.0% by mass | | 6.9% by mass | | 0.8% by mass | 0.3% by mass | | 60/40 |
| Res 10 | Pol-10 | — | PAG-3 | — | N-1 | W-6 | — | SL-1/SL-4 |
| | 92.3% by mass | | 6.6% by mass | | 0.8% by mass | 0.3% by mass | | 60/40 |

*In the table, conc. in solid is a content (% by mass) in the total solid of the resist composition.

The components and abbreviated symbols listed in Table 2 are as follows:

[Acid Generator]

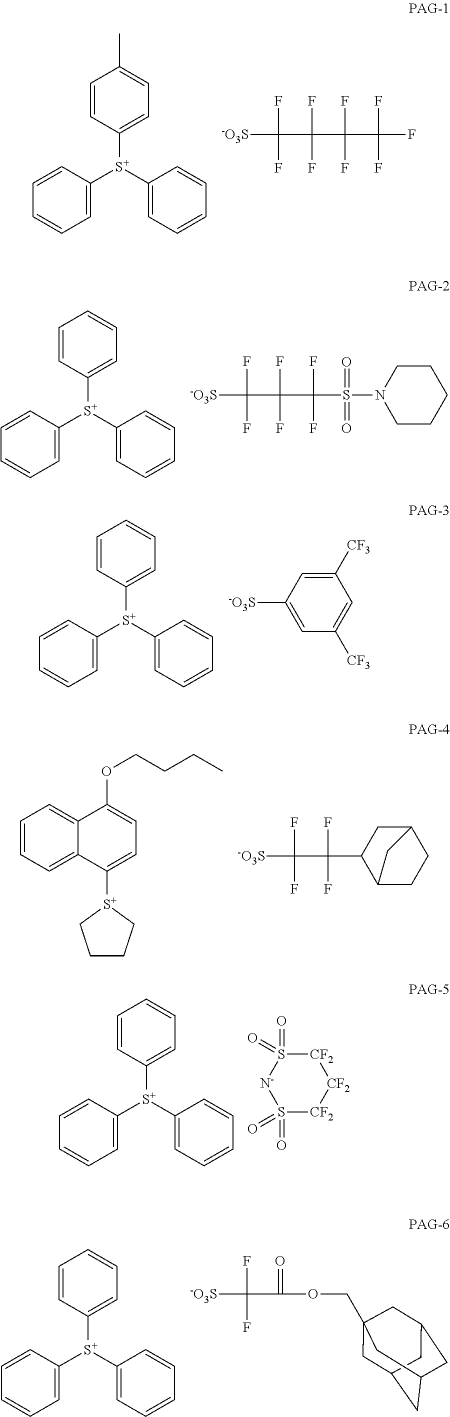

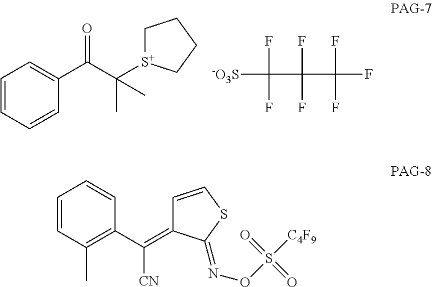

[Basic Compound]

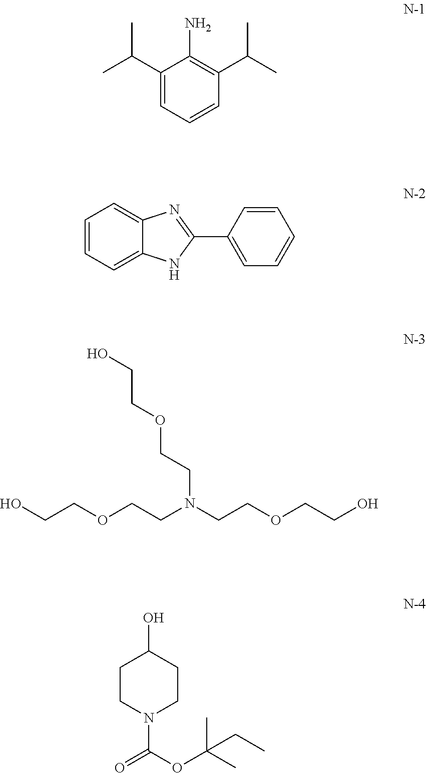 [SMILES: CC(C)c1cccc(C(C)C)c1N ; c1ccc(-c2nc3ccccc3[nH]2)cc1 ; OCCOCCN(CCOCCO)CCOCCO ; CCC(C)(C)OC(=O)N1CCC(O)CC1]

[Compound (D) Having a Naphthalene Ring, a Biphenyl Ring or an Anthracene Ring]

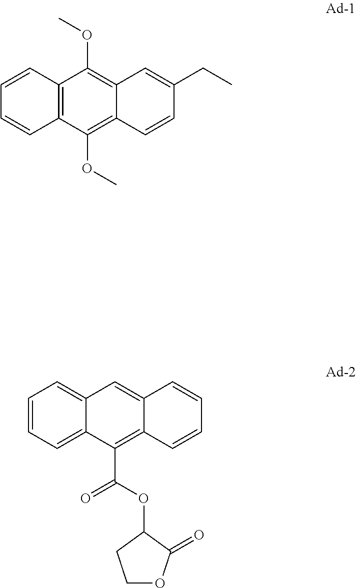 [SMILES: CCc1ccc2c(OC)c3ccccc3c(OC)c2c1 ; O=C(OC1CCOC1=O)c1c2ccccc2cc2ccccc12]

[Surfactant]

W-1: Megafac F176 (manufactured by DIC Corporation; fluorine-based)

W-2: Megafac R08 (manufactured by DIC Corporation; fluorine- and silicone-based)

W-3: Polysiloxane Polymer KP-341 (manufactured by Shin-Etsu Chemical Co., Ltd.; silicone-based)

W-4: Troysol S-366 (manufactured by Troy Chemical Corp.)

W-5: KH-20 (manufactured by Asahi Glass Co., Ltd.)

W-6: PolyFox PF-6320 (manufactured by OMNOVA Solutions Inc.; fluorine-based)

[Solvent]

SL-1: Propylene glycol monomethyl ether acetate (PGMEA)

SL-2: Propylene glycol monomethyl ether propionate

SL-3: Ethyl lactate

SL-4: Propylene glycol monomethyl ether (PGME)

SL-5: Cyclohexanone

SL-7: γ-butyrolactone

SL-8: Propylene carbonate

The prepared actinic ray-sensitive or radiation-sensitive resin composition was evaluated in the method described below.

[Evaluation of Exposure Latitude (EL)/Line Width Roughness (LWR)]

An organic antireflection film DUV44 (manufactured by Brewer Science Inc.) was applied onto a silicon wafer, thereby forming a 60 nm-thick antireflection film. Each of resist compositions listed in Table 3 below was applied thereonto and baked (prebaked, PB) at a temperature listed in Table 3 below for the period of time shown in Table 3 below (50 or 60 seconds), thereby forming a 200 nm-thick resist film. The obtained wafer was subject to pattern exposure by means of a KrF excimer laser scanner (NA 0.80) through a mask with a pitch of 400 nm and a light shielding portion width of 170 nm. Thereafter, the exposed wafer was baked (post-exposure baked, PEB) for a period of time shown in Table 3 below (50 or 60 seconds), was puddled in an organic developer listed in Table 3 below to develop 30 seconds, was puddled in a rinse liquid listed on Table 3 below, and was spun at a rotational speed of 4000 rpm for 30 seconds, thereby resulting in line and space patterns.

The resulting line and space patterns were observed using a critical dimension scanning electron microscope (SEM) (manufactured by Hitachi, Ltd., S-9380 II). Based on the optimum exposure amount by which the width of the space portion in the line and space pattern reaches 170 nm and the exposure amount by which the width of the space portion reaches ±10%, exposure latitude was obtained in the following formula.

EL(%)=((exposure amount by which the width of the space area reaches 153 nm)−(exposure amount by which the width of the space area reaches 187 nm)÷(optimum exposure amount)

The larger value of EL means larger EL and thus indicates that EL is superior.

Also, the space width was measured at 50 points at equal intervals over a range of 2 μm along the length direction of the space patterns and 3δ was calculated from the standard deviation, thereby measuring the line width roughness (LWR). The smaller the measured value is, the more superior the performance is.

[Evaluation of Collapse on Stepped Substrate]

The prepared resist composition was applied onto a substrate in which a stepped portion with a space of 100 nm, a pitch of 500 nm and a height of 100 nm is repeated with an equal space therebetween to form a film with a film thickness of 200 nm, and line and space patterns were formed in the same method as in the evaluation method of the EL/LWR to perform the evaluation of collapse. Also, the film thickness of the formed film is equal to the height from the bottom of the stepped portion (i.e., the bottom of the stepped substrate) to the surface of the resist film (i.e., top of the film).

The resulting line and space patterns were observed using a critical dimension scanning electron microscope (SEM) (manufactured by Hitachi, Ltd., S-9380 II). A pattern in which no residue appears was regarded as good and classified as A, and a pattern in which a little residue appears was classified as B and a pattern whose collapse obviously deteriorates (a significant amount of residue appears) was classified as C.

The results are shown in Table 3 below.

Also, the abbreviated symbols of the developers and rinse liquids are as follows.

[Developer/Rinse Liquid]

D-1: Butyl acetate

D-2: Pentyl acetate

D-3: 2-Heptanon

D-4: 1-Hexanol

D-5: 4-methyl-2-pentanol

TABLE 3

| | Resist | | | | Rinse | | LWR | Collapse on |
|---|---|---|---|---|---|---|---|---|
| | Composition | PB | PEB | Developer | Liquid | EL | (nm) | Stepped Portion |
| Ex. 1 | Res-1 | 105° C./50 sec. | 105° C./60 sec. | D-1 | D-5 | 26% | 5.1 | A |
| Ex. 2 | Res-2 | 95° C/60 sec. | 110° C./50 sec. | D-2 | — | 27% | 5.3 | A |
| Ex. 3 | Res-3 | 105° C./50 sec. | 105° C./60 sec. | D-1 | — | 25% | 5.4 | A |
| Ex. 4 | Res-4 | 95° C./60 sec. | 110° C/50 sec. | D-3 | — | 27% | 5.2 | A |
| Ex. 5 | Res-5 | 90° C./50 sec. | 120° C./60 sec. | D-1 | D-4 | 26% | 5.3 | A |
| Ex. 6 | Res-6 | 100° C./60 sec. | 120° C./60 sec. | D-2 | — | 24% | 5.4 | A |
| Ex. 7 | Res-7 | 90° C./50 sec. | 100° C./60 sec. | D-1 | — | 21% | 5.6 | A |
| Ex. 8 | Res-8 | 100° C./60 sec. | 120° C./60 sec. | D-1 | D-5 | 26% | 5.1 | A |
| Ex. 9 | Res-9 | 90° C./50 sec. | 100° C./60 sec. | D-3 | — | 18% | 5.9 | B |
| Comp. | Res-10 | 100° C./50 sec. | 110° C./60 sec. | D-2 | — | 13% | 6.5 | C |
| Ex. 1 | | | | | | | | |

As clearly shown in Table 3, Comparative Example 1, which uses a resin in which the content of (i) the repeating unit having an acid-decomposable group and (ii) the repeating unit having a polar group other than a phenolic hydroxyl group is less than 51 mol % based on the entire repeating units in the resin, has a small EL and a large LWR, and is thus inferior in terms of EL and LWR and also in terms of collapse performance on the stepped portion.

Further, Examples 1-9, which use the resin (A) in which the content of (i) the repeating unit having an acid-decomposable group and (ii) the repeating unit having a polar group other than a phenolic hydroxyl group is 51 mol % or more based on the entire repeating units in the resin, has a large EL and a small LWR, and is thus excellent in EL and LWR and also in terms of collapse performance on the stepped portion.

### INDUSTRIAL APPLICABILITY

According to the present invention, it is possible is to provide an actinic ray-sensitive or radiation-sensitive resin composition exhibiting superior exposure latitude (EL), line width roughness (LWR) and also exhibiting good space pattern collapse performance on a stepped substrate and particularly suitable for use in a negative pattern forming method using organic solvent-based development and more particularly suitable for use in KrF lithography, a pattern forming method using the resin composition, a resist film, a method for fabrication of an electronic device, and an electronic device.

Although the present invention has been described in detail with reference to specific aspects, it is obvious to those skilled in the art that various changes or modifications can be made without departing from the spirit and scope of the present invention.

The present application is based on a Japanese patent application (Japanese Patent Application No. 2012-257846) filed on Nov. 26, 2012, the disclosure of which is incorporated herein by reference.

What is claimed is:

1. An actinic ray-sensitive or radiation-sensitive resin composition comprising:
a resin (A) having an weight average molecular weight of 2,000 to 100,000 and containing a phenyl group and (i) a repeating unit having a group capable of decomposing by an action of an acid to generate a carboxyl group, which is represented by Formula (I),
wherein the resin (A) optionally contains (ii) a repeating unit having a polar group other than a phenolic hydroxyl group,
a total content of the repeating units (i) and (ii) is 51 mol % or more based on an entire repeating units in the resin (A),
the polar group other than a phenolic hydroxyl group in the repeating unit (ii) is a carboxyl group, an alcoholic hydroxyl group, an imide group, a carbonyl group, a nitro group or a sulfonamide group, provided that the alcoholic hydroxyl group does not include an aliphatic alcohol substituted by, at α-position, an electron withdrawn group and the carbonyl group as a polar group does not include a carbonyl group contained in an ester group: 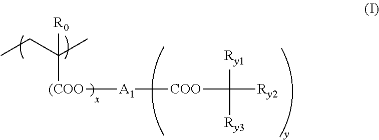
wherein, in Formula (I),
R₀ represents a hydrogen atom or an alkyl group,
each of R_{y1} to R_{y3} independently represents an alkyl group or a cycloalkyl group, the alkyl group or the cycloalkyl group optionally contains a substituent having no hetero atom, and R_{y2} and R_{y3} may be combined to each other to form a monocyclic or polycyclic structure,
A₁ represents a single bond, an alkylene group, —CO—, —O—, —SO₂—, or a (y+1)-valent organic group of combination thereof,
x represents 0 or 1, y represents an integer of 1 to 3, and
when y is 2 or 3, R_{y1}'s, R_{y2}'s and R_{y3}'s may be same as or different.

2. The actinic ray-sensitive or radiation-sensitive resin composition according to claim 1,
wherein A₁ represents a single bond.

3. The actinic ray-sensitive or radiation-sensitive resin composition according to claim 1,
wherein x represents 0.

4. The actinic ray-sensitive or radiation-sensitive resin composition according to claim 1,
wherein R_{y1} to R_{y3} each independently represent an alkyl group.

5. The actinic ray-sensitive or radiation-sensitive resin composition according to claim 1,
further comprising a compound (B) capable of generating an acid upon irradiation with an actinic-ray or radiation,
wherein the compound (B) is an ionic compound.

6. The actinic ray-sensitive or radiation-sensitive resin composition according to claim 1, for use in organic solvent-based development.

7. The actinic ray-sensitive or radiation-sensitive resin composition according to claim 1, for use in exposure by a KrF excimer laser.

8. A resist film formed from the actinic ray-sensitive or radiation-sensitive resin composition according to claim 1.

9. A pattern forming method comprising:
(a) forming a film by using an actinic ray-sensitive or radiation-sensitive resin composition containing a resin (A) having an weight average molecular weight of 2,000 to 100,000 and containing a phenyl group and (i) a repeating unit having a group capable of decomposing by an action of an acid to generate a carboxyl group, which is represented by Formula (I), wherein the resin (A) optionally contains (ii) a repeating unit having a polar group other than a phenolic hydroxyl group;
(b) exposing the film; and
(c) developing the film exposed in an organic solvent-containing developer to form negative patterns,
wherein a total content of the repeating units (i) and (ii) is 51 mol % or more based on an entire repeating units in the resin (A),
the polar group other than a phenolic hydroxyl group in the repeating unit (ii) is a carboxyl group, an alcoholic hydroxyl group, an imide group, a carbonyl group, a nitro group or a sulfonamide group, provided that the alcoholic hydroxyl group does not include an aliphatic alcohol substituted by, at α-position, an electron withdrawn group and the carbonyl group as a polar group does not include a carbonyl group contained in an ester group: 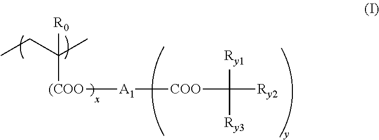
wherein, in Formula (I),
R₀ represents a hydrogen atom or an alkyl group,
each of R_{y1} to R_{y3} independently represents an alkyl group or a cycloalkyl group, and R_{y2} and R_{y3} may be combined to each other to form a monocyclic or polycyclic structure,
A₁ represents a single bond or a (y+1)-valent organic group,
x represents 0 or 1, y represents an integer of 1 to 3, and
when y is 2 or 3, R_{y1}'s, R_{y2}'s and R_{y3}'s may be same as or different.

10. The pattern forming method according to claim 9,
wherein A₁ represents a single bond.

11. The pattern forming method according to claim 9,
wherein x represents 0.

12. The pattern forming method according to claim 9,
wherein R_{y1} to R_{y3} each independently represent an alkyl group.

13. The pattern forming method according to claim 9,
wherein the exposing is performed by a KrF excimer laser.

14. The pattern forming method according to claim 9,
wherein the organic-solvent containing developer is a developer containing at least one kind of solvent selected from a ketone-based solvent, an ester-based solvent, an alcohol-based solvent, an amide-based solvent and an ether-based solvent.

15. A method for manufacturing an electronic device, comprising the pattern forming method according to claim 9.
